(19) United States
(12) Patent Application Publication
(10) Pub. No.: US 2024/0334735 A1
(43) Pub. Date: Oct. 3, 2024

(54) LIGHT-EMITTING DEVICE

(71) Applicant: SEMICONDUCTOR ENERGY LABORATORY CO., LTD., Atsugi-shi (JP)

(72) Inventors: Hiromi Seo, Sagamihara (JP); Takeyoshi Watabe, Atsugi (JP); Nobuharu Ohsawa, Zama (JP); Shinya Fukuzaki, Atsugi (JP)

(21) Appl. No.: 18/617,866

(22) Filed: Mar. 27, 2024

(30) Foreign Application Priority Data
Mar. 31, 2023 (JP) 2023-059114

(51) Int. Cl. H10K 50/19; H10K 50/11; H10K 50/16; H10K 85/30; H10K 85/60

(52) U.S. Cl. CPC H10K 50/19; H10K 50/11; H10K 50/16; H10K 85/342; H10K 85/633; H10K 85/6572

(57) ABSTRACT

A tandem light-emitting device that can be suitably used for a high-resolution display device is provided. The light-emitting device includes a first electrode, a second electrode facing the first electrode, a first light-emitting layer, a second light-emitting layer, and a first layer. The first light-emitting layer and the second light-emitting layer are between the first electrode and the second electrode. The first layer is between the first light-emitting layer and the second light-emitting layer. GSP_slope (mV/nm) of the first layer and GSP_slope (mV/nm) of the first light-emitting layer are denoted by signs of opposite polarities. Note that the GSP_slope (mV/nm) is a parameter represented by V/d when a surface potential and a thickness of a film are represented by V (mV) and d (nm), respectively.

### BACKGROUND OF THE INVENTION

### 1. Field of the Invention

One embodiment of the present invention relates to a light-emitting device.

One embodiment of the present invention is not limited to the above technical field. Examples of the technical field of one embodiment of the present invention include a semiconductor device, a display device, a light-emitting apparatus, a power storage device, a memory device, an electronic appliance, a lighting device, an input device (e.g., a touch sensor), an input/output device (e.g., a touch panel), driving methods thereof, and manufacturing methods thereof.

### 2. Description of the Related Art

Display devices are being developed into a variety of applications. For example, a television device for home use (also referred to as TV or television receiver), digital signage, and a public information display (PID) are being developed as large-sized display devices, and a smartphone and a tablet terminal each provided with a touch panel are being developed as small-sized display devices.

At the same time, an increase in the resolution of a display device is also proceeding. For example, devices for virtual reality (VR), augmented reality (AR), substitutional reality (SR), or mixed reality (MR) are given as devices requiring high-resolution display devices and are being developed.

Development is extensively conducted on light-emitting devices (also referred to as light-emitting elements) as display elements used in display devices. Light-emitting devices utilizing electroluminescence (hereinafter referred to as EL; such devices are also referred to as EL devices or EL elements), particularly organic EL devices that mainly use organic compounds, are suitable for display devices because of having features such as ease of reduction in thickness and weight, high-speed response to input signals, and driving with a constant DC voltage power source.

In order to obtain a higher-resolution light-emitting apparatus using an organic EL device, patterning an organic layer by a photolithography technique using a photoresist or the like, instead of an evaporation method using a metal mask, has been studied. By using the photolithography technique, a high-resolution display device in which the distance between EL layers is several micrometers can be obtained (see Patent Document 1, for example).

### REFERENCES

### Patent Documents

[Patent Document 1] Japanese Translation of PCT International Application No. 2018-521459
[Patent Document 2] PCT International Publication No. 2021/045178

### SUMMARY OF THE INVENTION

It has been known that EL layers in an organic EL device exposed to atmospheric components such as water and oxygen have affected initial characteristics or reliability, and thus it has been common knowledge that the EL layers are treated in a near-vacuum atmosphere. In particular, an electron-injection layer or a charge-generation layer in an intermediate layer of a tandem light-emitting device, which includes an alkali metal, an alkaline earth metal, or a compound thereof highly reactive with water or oxygen, rapidly deteriorates and loses the function of the electron-injection layer or the charge-generation layer when the surface of the EL layer is exposed to the atmosphere.

However, processing steps with the aforementioned photolithography technique inevitably expose the surface of the EL layer to the atmosphere.

Here, instead of the alkali metal, the alkaline earth metal, or the compound thereof described above, 1,1′-pyridine-2,6-diyl-bis(1,3,4,6,7,8-hexahydro-2H-pyrimido[1,2-a]pyrimidine) (abbreviation: hpp2Py) is known as an organic compound that can be used in the electron-injection layer. Since hpp2Py is less likely to deteriorate even when being exposed to the atmosphere unlike the alkali metal, the alkaline earth metal, or the compound thereof, a light-emitting device including hpp2Py formed through a processing step by a photolithography technique involving exposure to the atmosphere does not easily deteriorate.

However, the contact of hpp2Py with a metal such as aluminum induces the electron-injection property; thus, hpp2Py has been hard to use for an intermediate layer of a tandem light-emitting device because of a problem of metal contamination or light transmission.

In view of the above, an object of one embodiment of the present invention is to provide a novel light-emitting device having a tandem structure. An object of another embodiment of the present invention is to provide a highly efficient novel light-emitting device having a tandem structure. An object of another embodiment of the present invention is to provide a highly reliable novel light-emitting device having a tandem structure. An object of another embodiment of the present invention is to provide a highly efficient and highly reliable novel light-emitting device having a tandem structure.

An object of another embodiment of the present invention is to provide a novel light-emitting device having a tandem structure and manufactured through a photolithography process. An object of another embodiment of the present invention is to provide a highly efficient novel light-emitting device having a tandem structure and manufactured through a photolithography process. An object of another embodiment of the present invention is to provide a highly reliable novel light-emitting device having a tandem structure and manufactured through a photolithography process. An object of another embodiment of the present invention is to provide a high-emission-efficiency and highly reliable novel light-emitting device having a tandem structure and manufactured through a photolithography process.

An object of another embodiment of the present invention is to provide a novel light-emitting device that has a tandem structure and can be used in a high-resolution display device. An object of another embodiment of the present invention is to provide a highly efficient novel light-emitting device that has a tandem structure and can be used in a high-resolution display device. An object of another embodiment of the present invention is to provide a highly reliable novel light-emitting device that has a tandem structure and can be used in a high-resolution display device. An object of another embodiment of the present invention is to provide a high-emission-efficiency and highly reliable novel light-emitting device that has a tandem structure and can be used in a high-resolution display device.

An object of another embodiment of the present invention is to provide a highly reliable display device. An object of another embodiment of the present invention is to provide a high-resolution display device. An object of another embodiment of the present invention is to provide a highly reliable and high-resolution display device.

Other objects are to provide a novel organic compound, a novel light-emitting device, a novel display device, a novel display module, and a novel electronic appliance.

Note that the description of these objects does not preclude the existence of other objects. One embodiment of the present invention does not necessarily achieve all of these objects. Other objects can be derived from the description of the specification, the drawings, the claims, and the like.

One embodiment of the present invention is a light-emitting device including a first electrode, a second electrode facing the first electrode, a first light-emitting layer, a second light-emitting layer, and a first layer. The first light-emitting layer and the second light-emitting layer are between the first electrode and the second electrode. The first layer is between the first light-emitting layer and the second light-emitting layer. GSP_slope (mV/nm) of the first layer and GSP_slope (mV/nm) of the first light-emitting layer are denoted by signs of opposite polarities.

Another embodiment of the present invention is a light-emitting device including a first electrode over a substrate, a second electrode facing the first electrode, a first light-emitting layer, a second light-emitting layer, and a first layer. The first light-emitting layer and the second light-emitting layer are between the first electrode and the second electrode. The first layer is between the first light-emitting layer and the second light-emitting layer. The first layer has negative GSP_slope (mV/nm).

Another embodiment of the present invention is a light-emitting device including a first electrode, a second electrode facing the first electrode, a first light-emitting layer, a second light-emitting layer, an electron-transport layer, and a first layer. The first light-emitting layer and the second light-emitting layer are between the first electrode and the second electrode. The electron-transport layer and the first layer are between the first light-emitting layer and the second light-emitting layer. GSP_slope (mV/nm) of the first layer and GSP_slope (mV/nm) of the electron-transport layer are denoted by signs of opposite polarities.

Another embodiment of the present invention is a light-emitting device including a first electrode over a substrate, a second electrode facing the first electrode, a first light-emitting layer, a second light-emitting layer, an electron-transport layer, and a first layer. The first light-emitting layer and the second light-emitting layer are between the first electrode and the second electrode. The electron-transport layer and the first layer are between the first light-emitting layer and the second light-emitting layer. The electron-transport layer has positive GSP_slope (mV/nm). The first layer has negative GSP_slope (mV/nm).

Another embodiment of the present invention is a light-emitting device including a first electrode over a substrate, a second electrode facing the first electrode, a first light-emitting layer, a second light-emitting layer, an electron-transport layer, and an intermediate layer. The first light-emitting layer, the electron-transport layer, the intermediate layer, and the second light-emitting layer are provided between the first electrode and the second electrode in this order from the first electrode side. The intermediate layer comprises a first layer and a second layer in this order from the first electrode side. The electron-transport layer and the first layer are in contact with each other. The electron-transport layer has positive GSP_slope (mV/nm). The first layer has negative GSP_slope (mV/nm).

Another embodiment of the present invention is the light-emitting device having the above-described structure, in which the second layer is a charge-generation layer.

Another embodiment of the present invention is the light-emitting device having the above-described structure, in which the second layer includes a hole-transport organic compound and a substance exhibiting an acceptor property with respect to the hole-transport organic compound.

Another embodiment of the present invention is the light-emitting device having the above-described structure, in which the substance exhibiting an acceptor property with respect to the hole-transport organic compound included in the second layer is an organic compound.

Another embodiment of the present invention is the light-emitting device having the above-described structure, in which the first layer is configured to block holes.

Another embodiment of the present invention is the light-emitting device having the above-described structure, in which the first layer has a lower hole mobility than the electron-transport layer.

Another embodiment of the present invention is the light-emitting device having the above-described structure, in which the first layer has a hole mobility lower than or equal to 1×10⁻⁸ cm²/Vs when the square root of electric field strength [V/cm] is 600.

Another embodiment of the present invention is the light-emitting device having the above-described structure, in which the first layer has an electron mobility higher than or equal to 1×10⁻⁸ cm²/Vs when the square root of electric field strength [V/cm] is 600.

Another embodiment of the present invention is the light-emitting device having the above-described structure, in which the first layer includes a first substance having any one of a pyrrolidine skeleton, a piperidine skeleton, and a hexahydropyrimidopyrimidine skeleton.

Another embodiment of the present invention is the light-emitting device having the above-described structure, in which the first layer includes a first substance and a second substance; the first substance is an organic compound having any one of a pyrrolidine skeleton, a piperidine skeleton, and a hexahydropyrimidopyrimidine skeleton; and the second substance is an electron-transport organic compound.

Another embodiment of the present invention is the light-emitting device having the above-described structure, in which the first substance is an organic compound having a 1,3,4,6,7,8-hexahydro-2H-pyrimido[1,2-a ]pyrimidine skeleton.

Another embodiment of the present invention is the light-emitting device having the above-described structure, in which a difference between the GSP_slope (mV/nm) of the electron-transport layer and the GSP_slope (mV/nm) of the first layer is greater than or equal to 20 (mV/nm).

Another embodiment of the present invention is the light-emitting device having the above-described structure, in which spin density of the first layer is lower than or equal to 1×10¹⁷ spins/cm³.

Another embodiment of the present invention is the light-emitting device having the above-described structure, in which the first electrode is electrically connected to a transistor.

Another embodiment of the present invention is a display module including the above-described light-emitting device and at least one of a connector and an integrated circuit.

Another embodiment of the present invention is an electronic appliance including the above-described light-emitting device and at least one of a housing, a battery, a camera, a speaker, and a microphone.

Note that in any of the above structures, the GSP_slope (mV/nm) is a parameter represented by V/d when a surface potential and a thickness of a film are represented by V (mV) and d (nm), respectively.

With one embodiment of the present invention, a novel light-emitting device having a tandem structure can be provided. With another embodiment of the present invention, a highly efficient novel light-emitting device having a tandem structure can be provided. With another embodiment of the present invention, a highly reliable novel light-emitting device having a tandem structure can be provided. With another embodiment of the present invention, a highly efficient and highly reliable novel light-emitting device having a tandem structure can be provided.

With another embodiment of the present invention, a novel light-emitting device having a tandem structure and manufactured through a photolithography process can be provided. With another embodiment of the present invention, a highly efficient novel light-emitting device having a tandem structure and manufactured through a photolithography process can be provided. With another embodiment of the present invention, a highly reliable novel light-emitting device having a tandem structure and manufactured through a photolithography process can be provided. With another embodiment of the present invention, a high-emission-efficiency and highly reliable novel light-emitting device having a tandem structure and manufactured through a photolithography process can be provided.

With another embodiment of the present invention, a novel light-emitting device that has a tandem structure and can be used in a high-resolution display device can be provided. With another embodiment of the present invention, a highly efficient novel light-emitting device that has a tandem structure and can be used in a high-resolution display device can be provided. With another embodiment of the present invention, a highly reliable novel light-emitting device that has a tandem structure and can be used in a high-resolution display device can be provided. With another embodiment of the present invention, a highly efficient and highly reliable novel light-emitting device that has a tandem structure and can be used in a high-resolution display device can be provided.

With one embodiment of the present invention, a high-resolution and high-emission-efficiency display device can be provided. With one embodiment of the present invention, a high-definition display device with favorable display performance can be provided. With one embodiment of the present invention, a display device with favorable display quality and performance can be provided. With one embodiment of the present invention, a high-resolution, high-emission-efficiency, and highly reliable display device can be provided. With one embodiment of the present invention, a high-definition and highly reliable display device with favorable display performance can be provided. With one embodiment of the present invention, a highly reliable display device with favorable display quality and performance can be provided.

A novel display device, a novel display module, or a novel electronic appliance can be provided.

Note that the description of these effects does not preclude the existence of other effects. One embodiment of the present invention does not necessarily have all of these effects. Other effects can be derived from the description of the specification, the drawings, the claims, and the like.

### BRIEF DESCRIPTION OF THE DRAWINGS

In the accompanying drawings:

FIGS. 1A and 1B illustrate light-emitting devices;

FIGS. 2A and 2B illustrate measurement devices;

FIG. 3 shows capacity-voltage characteristics of an element 10;

FIG. 4 shows capacity-voltage characteristics of an element 11;

FIG. 5 shows measurement results using measurement devices;

FIG. 6 illustrates a light-emitting device;

FIG. 7 illustrates light-emitting devices;

FIGS. 8A and 8B are a top view and a cross-sectional view, respectively, of a display device;

FIGS. 9A to 9E are cross-sectional views illustrating an example of a method for manufacturing a display device;

FIGS. 10A to 10D are cross-sectional views illustrating an example of a method for manufacturing a display device;

FIGS. 11A to 11D are cross-sectional views illustrating an example of a method for manufacturing a display device;

FIGS. 12A to 12C are cross-sectional views illustrating an example of a method for manufacturing a display device;

FIGS. 13A to 13C are cross-sectional views illustrating an example of a method for manufacturing a display device;

FIGS. 14A to 14C are cross-sectional views illustrating an example of a method for manufacturing a display device;

FIGS. 15A and 15B are perspective views illustrating a structure example of a display module;

FIGS. 16A and 16B are cross-sectional views illustrating structure examples of a display device;

FIG. 17 is a perspective view illustrating a structure example of a display device;

FIG. 18 is a cross-sectional view illustrating a structure example of a display device;

FIG. 19 is a cross-sectional view illustrating a structure example of a display device;

FIG. 20 is a cross-sectional view illustrating a structure example of a display device;

FIGS. 21A to 21D illustrate examples of electronic appliances;

FIGS. 22A to 22F illustrate examples of electronic appliances;

FIGS. 23A to 23G illustrate examples of electronic appliances;

FIG. 24 shows luminance-current density characteristics of a light-emitting device 1;

FIG. 25 shows luminance-voltage characteristics of the light-emitting device 1;

FIG. 26 shows current efficiency-luminance characteristics of the light-emitting device 1;

FIG. 27 shows current density-voltage characteristics of the light-emitting device 1;

FIG. 28 shows an electroluminescence spectrum of the light-emitting device 1;

FIG. 29 shows changes in luminance of the light-emitting device 1 over driving time in constant current driving at a current density of 50 mA/cm²;

FIG. 30 shows capacity-voltage characteristics of a measurement device;

FIG. 31 shows luminance-current density characteristics of a light-emitting device 2;

FIG. 32 shows current efficiency-luminance characteristics of the light-emitting device 2;

FIG. 33 shows luminance-voltage characteristics of the light-emitting device 2;

FIG. 34 shows current density-voltage characteristics of the light-emitting device 2;

FIG. 35 shows an electroluminescence spectrum of the light-emitting device 2;

FIG. 36 shows changes in luminance of the light-emitting device 2 over driving time in constant current driving at a current density of 50 mA/cm²;

FIGS. 37A and 37B show capacity-voltage characteristics of a measurement device L21 and a measurement device L22; and

FIG. 38 shows capacity-voltage characteristics of a measurement device 3.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

### Embodiment 1

A tandem organic EL device includes, between electrodes, a plurality of light-emitting units each including a light-emitting layer, and an intermediate layer sandwiched between the light-emitting units. The intermediate layer includes a charge-generation layer (CGL).

The CGL refers to a layer where electrons and holes are generated by charge separation caused by application of voltage. As the CGL, a layer (P-type CGL) in which a hole-transport material and a material having an acceptor property with respect to the hole-transport material are stacked or mixed and a layer (N-type CGL) in which an electron-transport material and a material having a donor property with respect to the electron-transport material are stacked or mixed are generally used.

The intermediate layer preferably includes both the P-type CGL and the N-type CGL so that the P-type CGL is on the anode side and the N-type CGL is on the cathode side, which facilitates injection of holes and electrons to the light-emitting units and thus reduces driving voltage. This is because injecting holes generated in the P-type CGL to the light-emitting unit in contact with a surface of the intermediate layer on the cathode side through the hole-transport material included in the P-type CGL and injecting electrons generated in the N-type CGL to the light-emitting unit in contact with a surface of the intermediate layer on the anode side through the electron-transport material included in the N-type CGL can lower a carrier injection barrier.

The N-type CGL may be a single film of a material having a donor property. In that case, charge separation occurs between the material having a donor property and the electron-transport material in the light-emitting unit on the anode side; therefore, electrons can be regarded as being injected to the light-emitting unit at the time of charge separation. Similarly, the P-type CGL may be a single film of a material having an acceptor property. In that case, charge separation occurs between the material having an acceptor property and the hole-transport material in the light-emitting unit on the cathode side; therefore, holes can be regarded as being injected to the light-emitting unit at the time of charge separation.

As a method for forming an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. Thus, an organic semiconductor device having a finer pattern is expected to be achieved by shape processing of an organic semiconductor film by a photolithography technique. Moreover, since a photolithography technique achieves large-area processing more easily than mask vapor deposition, processing of an organic semiconductor film by the photolithography technique is being researched.

However, processing steps with the aforementioned photolithography technique inevitably expose the surface of an organic compound layer to be processed (specifically, an EL layer or the like) to the atmosphere.

It has been known that EL layers in an organic EL device exposed to atmospheric components such as water and oxygen have affected initial characteristics or reliability, and thus it has been common knowledge that the EL layers are treated in a near-vacuum atmosphere.

In particular, an electron-injection layer in a light-emitting device and an N-type CGL in an intermediate layer used in a tandem light-emitting device each often include an alkali metal, an alkaline earth metal, or a compound thereof (hereinafter also referred to as a Li compound or the like), and thus are significantly affected when exposed to an atmospheric component such as water or oxygen. This is because the Li compound or the like is highly reactive with water or oxygen, and thus rapidly deteriorates not only when the Li compound or the like is directly exposed to the atmosphere but also when instead of the Li compound itself, the surface of the EL layer including the Li compound or the like is exposed to the atmosphere, which leads to eliminating the function of the electron-injection layer or the N-type CGL.

Processing steps with the aforementioned photolithography technique inevitably expose the surface of the EL layer to the atmosphere. Thus, the electron-injection properties of the electron-injection layer and the N-type CGL each including a Li compound or the like are significantly lowered through a photolithography process. The electron-transport layer can be formed after processing by a photolithography technique, so that degradation of such a property can be prevented. However, in a tandem light-emitting device, when a light-emitting layer on the cathode side of an intermediate layer is processed by a photolithography technique, the intermediate layer is always exposed to the atmosphere during the processing. Therefore, it has been difficult to perform processing by a photolithography technique for a tandem light-emitting device that uses an intermediate layer including a Li compound or the like (i.e., an intermediate layer provided with an N-type CGL).

Since both an N-type CGL and a P-type CGL generate charges, it can be assumed that an intermediate layer generating charges formed only with a P-type CGL not including an N-type CGL that might deteriorate in a photolithography process. However, in this case, electrons generated in the P-type CGL are less likely to be injected into a light-emitting unit in contact with the surface of the intermediate layer on the anode side, which significantly increases the driving voltage. This is because there is a large difference between the lowest unoccupied molecular orbital (LUMO) level of a material having an acceptor property of the P-type CGL and the LUMO level of an electron-transport material of an electron-transport layer in the light-emitting unit on the anode side.

As described above, photolithography processing performed on a tandem light-emitting device causes the following dilemma: when an N-type CGL is used, the driving voltage increases due to deterioration of the N-type CGL subjected to photolithography processing, and when an intermediate layer does not include an N-type CGL, the driving voltage increases due to a difference in LUMO level.

In view of the above, the present inventors found that by forming, instead of an N-type CGL, a layer with negative giant surface potential (GSP) slope in an intermediate layer for what is called an ordered stacked tandem light-emitting device whose anode is formed first, a tandem light-emitting device in which an increase in the driving voltage is suppressed can be obtained without using an N-type CGL.

Note that GSP is a phenomenon due to spontaneous orientation polarization (SOP) caused by deviation of permanent dipole moment orientation of an evaporated film to the thickness direction.

The surface potential of an evaporated film with such GSP changes linearly with increasing thickness without saturation. For example, the surface potential of an evaporated film of tris(8-quinolinolato)aluminum (abbreviation: Alq₃) reaches approximately 28 V at a thickness of 560 nm. The electric field strength reaches 5×10′ V/cm, which is approximately the same level as electric field strength during driving of a general organic thin film device.

When GSP changes in proportion to the thickness of a film whose surface potential and thickness are represented by V (mV) and d (nm), respectively, a parameter represented by V/d is GSP_slope (mV/nm). Note that GSP_slope of a film whose surface potential increases with increasing thickness is positive GSP_slope and GSP_slope of a film whose surface potential decreases with increasing thickness is negative GSP_slope, and Alq₃ described above is a material with positive GSP_slope. Note that the potential of a layer with negative GSP_slope (hereinafter also referred to as a negative layer) is higher on the substrate side, and the potential of a layer with positive GSP_slope (hereinafter also referred to as a positive layer) is lower on the substrate side.

As described above, GSP is a phenomenon due to SOP caused by deviation of permanent dipole moment orientation to the thickness direction. That is, the following phenomena can be regarded as occurring: a positive polarization charge is induced on the side where evaporation starts (the substrate side) and a negative polarization charge is induced on the side where evaporation ends (the second electrode side) in a layer with negative GSP_slope, and in a similar manner, a negative polarization charge is induced on the side where evaporation starts (the substrate side), and a positive polarization charge is induced on the side where evaporation ends (the second electrode side) in a layer with positive GSP_slope. Thus, GSP originates in such phenomena.

In an organic semiconductor device having a stacked-layer structure, the polarization charge is one of factors that significantly influence the injection voltage of electrons or holes to an EL layer. One embodiment of the present invention achieves a reduction in driving voltage of a tandem light-emitting device by utilizing the polarization charge and an interface charge in a stacked-layer film, which is derived from the polarization charge.

Most organic compounds normally have positive GSP_slope; thus, in the case where a first layer is deposited on and in contact with a second layer, for example, GSP_slope of the first layer and GSP_slope of the second layer are denoted by the same positive sign. In this case, a polarization charge in the first layer is canceled out by a polarization charge in the second layer serving as a base of the first layer, and only a remaining charge serves as an interface charge (fixed charge). Thus, the density of the interface charges existing at the interface between the two different layers is lower than that of the polarization charges.

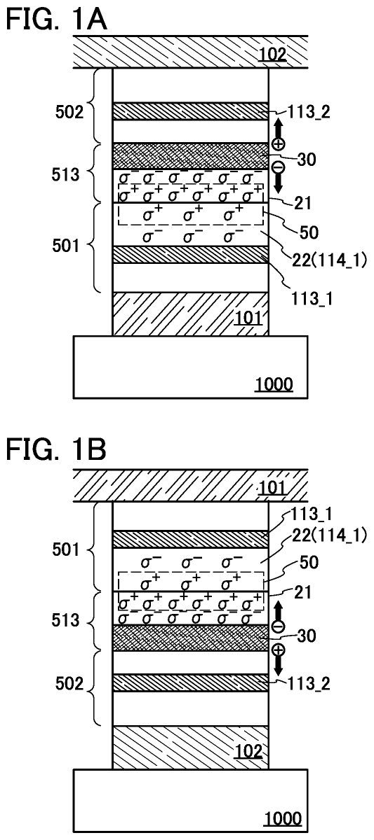

Meanwhile, a light-emitting device of one embodiment of the present invention is provided with, instead of an N-type CGL, a first layer 21 with negative GSP_slope as illustrated in FIGS. 1A and 1B. As a second layer 22 serving as a base, a general layer with positive GSP_slope can be used. In the first layer 21 with negative GSP_slope, a positive polarization charge is induced to the vicinity of an interface on the substrate 1000 side, and a negative polarization charge is induced to the vicinity of an opposite interface. In the second layer 22 with positive GSP_slope, a negative polarization charge is induced to the vicinity of an interface on the substrate 1000 side, and a positive polarization charge is induced to the vicinity of an opposite interface. Thus, a positive polarization charge appears at the interface on the first layer 21 side of the second layer 22.

Thus, in the light-emitting device of one embodiment of the present invention, the polarization charge in the vicinity of the interface on the substrate 1000 side of the first layer 21 is not canceled out and serves as an interface charge 50 by itself. Moreover, the positive polarization charge in the vicinity of the interface on the first layer 21 side of the second layer 22 also serves as the interface charge 50. That is, in the case where the first layer 21 with negative GSP_slope is formed instead of an N-type CGL, positive fixed charges having high charge density exist in the vicinity of the interface between the first layer 21 and the second layer 22 serving as a base of the first layer 21.

In the light-emitting device of one embodiment of the present invention, electrons that are generated in a P-type CGL 20 can be easily injected into the first layer 21 owing to the high-density positive interface charges 50 in the vicinity of the interface between the first layer 21 and the second layer 22. As a result, even when an intermediate layer 513 does not include an N-type CGL, electrons generated in the P-type CGL 20 can be injected into a first light-emitting unit 501 on the anode 101 side without a large increase in driving voltage. Thus, a tandem light-emitting device in which an increase in driving voltage is suppressed can be obtained without an N-type CGL.

Note that the light-emitting device of one embodiment of the present invention does not include an N-type CGL in the intermediate layer 513, i.e., does not include a Li compound or the like that easily deteriorates. Therefore, even when fabricated through a photolithography process, a tandem light-emitting device can have no characteristics degradation such as an increase in driving voltage and can maintain favorable characteristics.

As described above, a tandem light-emitting device provided with the first layer 21 with negative GSP_slope instead of an N-type CGL can have suppressed characteristics degradation such as an increase in driving voltage and can maintain favorable characteristics even when fabricated through a photolithography process. Note that in FIGS. 1A and 1B, 102 denotes a cathode, 502 denotes a second light-emitting unit, 113_1 denotes a light-emitting layer of the first light-emitting unit 501, 113_2 denotes a light-emitting layer of the second light-emitting unit 502, and 114_1 denotes an electron-transport layer of the first light-emitting unit 501.

Here, a method for obtaining GSP_slope of an organic compound will be described.

As described above, GSP is a phenomenon due to SOP caused by deviation of permanent dipole moment orientation of an evaporated film to the thickness direction. The amount of GSP change proportional to a thickness is called GSP_slope (mV/nm). It is typically known that GSP_slope is observed as a slope of a plot of a surface potential of an evaporated film in the thickness direction by Kelvin probe measurement. In the case where measurement is performed in such a manner, the influences of a base film and measurement environment need to be considered. Meanwhile, in the case where two films with different kinds of SOP are stacked, the density of interface charges (mC/m²) accumulated at the interface and GSP_slope of one of the films can be utilized to estimate GSP_slope of the other of the films. The density of interface charges can be calculated by CV measurement (IS measurement) on an element structure in which charges are accumulated in one of the two stacked films different from each other.

The following formulae hold when current is made to flow through a stack of films (a thin film 1 positioned on the anode side and a thin film 2 positioned on the cathode side) with different kinds of SOP and electrons serve as carriers.

$$[ Formula 1 ]$$

$${σ}_{if \_ e} = \frac{{Q}_{if}}{S} = ( {V}_{i} - {V}_{bi} ) \frac{{ε}_{1}}{{d}_{1}} \qquad ( 1 )$$

$$[ Formula 2 ]$$

$${σ}_{if \_ e} = - ( {P}_{1} - {P}_{2} ) = - ( \frac{{ε}_{1} {V}_{1}}{{d}_{1}} - \frac{{ε}_{2} {V}_{2}}{{d}_{2}} ) \qquad ( 2 )$$

In Formula (1), σ_{if_e} is an interface charge density, Vᵢ is an electron-injection voltage, V_{bi} is a threshold voltage, d₁ is a thickness of the thin film 1, and ε₁ is a dielectric constant of the thin film 1. Note that Vᵢ and V_{bi} can be estimated from the capacity-voltage characteristics of a device. The square of an ordinary refractive index nₒ(633 nm) can be used as the dielectric constant. As described above, according to Formula (1), the interface charge density σ_{if_e} can be calculated using Vᵢ and V_{bi} estimated from the capacity-voltage characteristics, the dielectric constant si of the thin film 1 calculated from the refractive index, and the thickness d₁ of the thin film 1.

In Formula (2), P₁ and P₂ are SOP of the thin film 1 and SOP of the thin film 2, respectively, ε₂ is a dielectric constant of the thin film 2, and d₂ is a thickness of the thin film 2. Since the interface charge density σ_{if_e} can be obtained from Formula (1), the use of a substance with known GSP_slope for the thin film 1 enables GSP_slope of the thin film 2 to be estimated.

Thus, Alq₃ whose GSP_slope is known to be 48 (mV/nm) is used for the thin film 1, elements 10 and 11 are fabricated as measurement elements, and GSP_slope of NBPhen in the element 10 and GSP_slope of mPPhen2P in the element 11 are calculated below, for example.

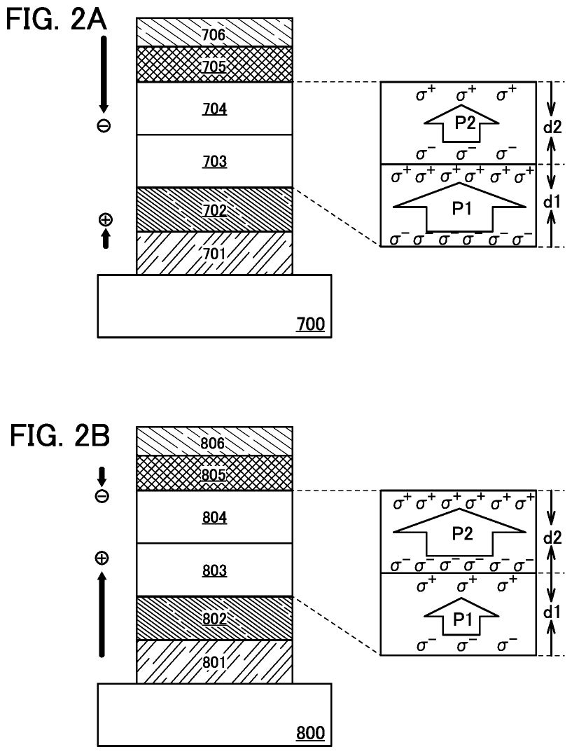

The following table and FIG. 2A show device structures of the elements 10 and 11. Note that an anode 701 is formed over a substrate 700, and a hole-injection layer 702, a first electron-transport layer 703, a second electron-transport layer 704, an electron-injection layer 705, and a cathode 706 are sequentially formed from the anode 701 (the substrate 700) side by a vacuum evaporation method. The elements 10 and 11 are formed under the conditions where the substrate temperature is set to room temperature and the deposition rate is within the range from 0.2 nm/see to 0.4 nm/sec. One layer is formed without interruption of evaporation. In each of the elements 10 and 11, the first electron-transport layer 703 corresponds to the thin film 1 and the second electron-transport layer 704 corresponds to the thin film 2.

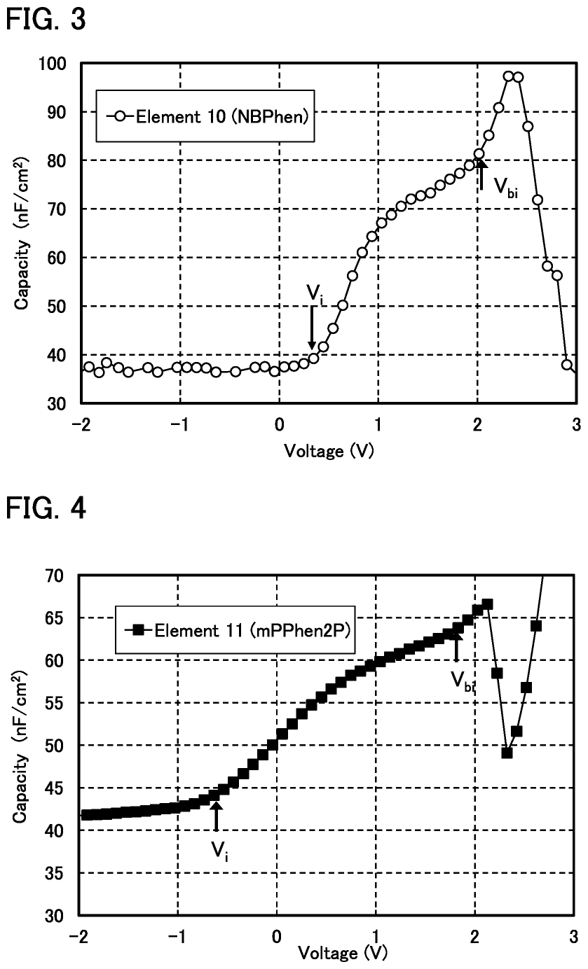

FIG. 3 and FIG. 4 show the capacity-voltage characteristics of the elements 10 and 11.

TABLE 1

| | thickness | | |
|---|---|---|---|
| | (nm) | element 10 | element 11 |
| cathode 706 | 200 | Al | |
| electron-injection layer 705 | 1 | LiF | |
| second electron- | 80 | NBPhen | mPPhen2P |
| transport layer 704 | | | |

| | | |
|---|---|---|
| first electron- | 60 | Alq₃ |
| transport layer 703 | | |
| hole-injection layer 702 | 10 | PCBBiF:p-dopant (1:0.1) |
| anode 701 | 70 | ITSO |

Table 2 shows the refractive indices nₒ of the materials, the electron-injection voltage Vᵢ and the threshold voltage V_{bi}, of the element 10 (NBPhen) and the element 11 (mPPhen2P) obtained from FIG. 3 and FIG. 4, the interface charge density σ_{if_e} obtained from Formula (1), and GSP_slope obtained from Formula (2).

TABLE 2

| | element 10 | element 11 |
|---|---|---|
| | (NBPhen) | (mPPhen2P) |
| electron-injection voltage Vᵢ | 0.35 | −0.63 |
| (V) | | |
| threshold voltage V_{bi} | 2.02 | 1.83 |
| (V) | | |
| interface charge density σ_{if}_{_{—}}ₑ | −0.82 | −1.21 |
| (mC/m²) | | |
| ordinary refractive index nₒ | 1.85 | 1.80 |
| (@633 nm) | | |
| GSP_slope | 14.0 | 1.3 |
| (mV/nm) | | |

In this manner, a device in which Alq₃ with known GSP_slope and an organic compound whose GSP_slope is to be obtained are stacked is fabricated and the capacity-voltage characteristics are measured, so that GSP_slope of the organic compound can be estimated.

In the above, the method for calculating GSP_slope of the organic compound used for the electron-transport layer in which electrons serve as carriers is described. In the case where holes serve as carriers and GSP_slope of an organic compound is used, GSP_slope can be calculated in a similar manner using a measurement element illustrated in FIG. 2B and using Formulae (3) and (4) shown below. In the measurement element illustrated in FIG. 2B, an anode 801 is formed over a substrate 800, and a hole-injection layer 802, a first hole-transport layer 803, a second hole-transport layer 804, an electron-injection layer 805, and a cathode 806 are sequentially formed from the anode 801 (the substrate 800) side by a vacuum evaporation method. In Formulae (3) and (4) shown below, σ_{if_e} is an interface charge density.

$$[ Formula 3 ]$$

$${σ}_{if \_ h} = \frac{{Q}_{if}}{S} = ( {V}_{i} - {V}_{bi} ) \frac{{ε}_{2}}{{d}_{2}} \qquad ( 3 )$$

$$[ Formula 4 ]$$

$${σ}_{if \_ h} = {P}_{1} - {P}_{2} = \frac{{ε}_{1} {V}_{1}}{{d}_{1}} - \frac{{ε}_{2} {V}_{2}}{{d}_{2}} \qquad ( 4 )$$

Note that “GSP_slope of a layer” can be calculated as GSP_slope of a film of a material in the layer. In the case where the thin film 1 or the thin film 2 includes a plurality of organic compounds, GSP_slope of the major organic compound (e.g., the material included in the largest proportion) can be regarded as “GSP_slope of the layer”. Alternatively, in the case where the thin film 1 or the thin film 2 includes a plurality of organic compounds, GSP_slope and contents of the organic compounds are calculated, and a weighted average (GSP_slope_ave) may be defined as “GSP_slope of an organic compound in a layer”.

In the above-described manner, GSP_slope can be calculated.

Examples of a substance for an evaporated film to be a layer with negative GSP_slope include tris(7-propyl-8-hydroxyquinolinato)aluminum(III) (abbreviation: Al(7-Prq)₃), tris(2-phenylpyridinato-N,C^{2′})iridium(III) (abbreviation: [Ir(ppy)₃]), 2,2-bis[4-(4,6-diphenyl-1,3,5-triazin-2-yl)phenyl]hexafluoropropane (abbreviation: 6F-2TRZ), 2,2-bis[(4-diphenylamino)phenyl]hexafluoropropane (abbreviation: 6F-2TPA), 2,2-bis[9H-carbazole-9-(4-phenyl)]hexafluoropropane (abbreviation: 6F-2Cz), and 1-(9,9′-spirobi[9H-fluoren]-2-yl)-1,3,4,6,7,8-hexahydro-2H-pyrimido[1,2-a]pyrimidine (abbreviation: 2hppSF). The first layer preferably includes any of the above-described substances as a first substance.

The first layer may be a layer in which the first substance and another substance are mixed.

In one embodiment of the present invention, it is preferable that a first layer with negative GSP_slope have a lower hole mobility than a second layer serving as a base of the first layer, it is further preferable that the first layer have a hole mobility lower than or equal to 1×10⁻⁸ cm²/Vs in the case where the square root of electric field strength [V/cm] is 600, and it is still further preferable that the first layer have a hole-blocking property. In such cases, holes flowing from the anode are accumulated in the vicinity of the interface between the first layer and the second layer, and electrons can be easily injected from the P-type CGL into the first layer.

Here, by including a strongly basic material with an acid dissociation constant pKₐ of 8 or more, the first layer can have a low hole mobility or can block holes. Thus, the first layer preferably includes a strongly basic material with an acid dissociation constant pKₐ of 8 or more. That is, the first layer preferably includes the first substance and a strongly basic material with an acid dissociation constant pKₐ of 8 or more. Note that in the case where an evaporated film of a strongly basic material with an acid dissociation constant pKₐ of 8 or more has negative GSP_slope, the material can also be referred to as the first substance; thus, the first layer including the material can be regarded as including both the first substance and the strongly basic material with an acid dissociation constant pKₐ of 8 or more.

By including a strongly basic material with an acid dissociation constant pKₐ of 8 or more, the first layer can block holes and holes can be efficiently accumulated in the vicinity of the interface between the first layer and the second layer; thus, a tandem light-emitting device with lower driving voltage can be obtained.

A material with a large acid dissociation constant pKₐ blocks holes because the material with a large acid dissociation constant pKₐ has a large dipole moment. The dipole moment mutually interacts with holes, whereby the first layer including the material with a large acid dissociation constant pKₐ can block holes.

Another reason for a significant reduction in the hole-transport property in the first layer is high nucleophilicity of the strongly basic material with a large acid dissociation constant pKₐ. A material with high nucleophilicity reacts with a molecule that has become a cation radical by receiving a hole to generate a new molecule or intermediate state, in some cases. This reaction consumes holes and can significantly reduce the hole-transport property in the first layer.

Note that the strongly basic material with an acid dissociation constant pKₐ of 8 or more is preferably an organic compound having a basic skeleton with an acid dissociation constant pKₐ of 10 or more. In the organic compound, the acid dissociation constant pKₐ of the basic skeleton is further preferably 12 or more.

As the acid dissociation constant pKₐ of the basic skeleton, the acid dissociation constant value of the organic compound formed by substituting hydrogen for part of the skeleton can be used. As an indicator of acidity of an organic compound having a basic skeleton, the acid dissociation constant pKₐ of the basic skeleton can be used. As for an organic compound having a plurality of basic skeletons, the acid dissociation constant pKₐ of the basic skeleton having the highest acid dissociation constant pKₐ can be used as the indicator of acidity of the organic compound. The acid dissociation constant pKₐ is preferably a value measured using water as a solvent.

Alternatively, the acid dissociation constant pKₐ of the organic compound may be calculated as follows.

First, as the initial molecular structure in each molecule that is a calculation model, the most stable structure (singlet ground state) obtained from the first-principles calculation is used.

For the first-principles calculation, Jaguar, which is the quantum chemical computational software produced by Schrodinger, Inc., is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by Schrodinger, Inc.

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value can be calculated using empirical correction for functional group(s). Note that for the molecule with one or more atoms designated as basic sites, the largest pKₐ value among the obtained results is employed.

The strongly basic material is preferably an organic compound having a pyrrolidine skeleton, a piperidine skeleton, or a hexahydropyrimidopyrimidine skeleton. Alternatively, an organic compound having a guanidine skeleton is preferably used. As specific examples, organic compounds having any of basic skeletons represented by Structural Formulae (120) to (123) below can be given.

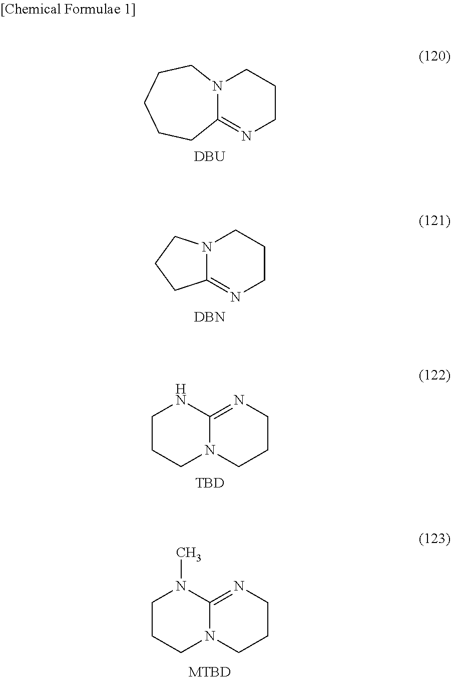

It is preferable that the organic compound with an acid dissociation constant pKₐ of 8 or more be specifically an organic compound which has a bicyclo ring structure having 2 or more nitrogen atoms in the bicyclo ring and a heteroaromatic hydrocarbon ring having 2 to 30 carbon atoms in the ring or an aromatic hydrocarbon ring having 6 to 30 carbon atoms in the ring, and more specifically be an organic compound which has a 1,3,4,6,7,8-hexahydro-2H-pyrimido[1,2-a]pyrimidine skeleton and a heteroaromatic hydrocarbon ring having 2 to 30 carbon atoms in the ring or an aromatic hydrocarbon ring having 6 to 30 carbon atoms in the ring. An organic compound which has a bicyclo ring structure having 2 or more nitrogen atoms in the bicyclo ring and a heteroaromatic hydrocarbon ring having 2 to 30 carbon atoms in the ring, more specifically an organic compound which has a 1,3,4,6,7,8-hexahydro-2H-pyrimido[1,2-a]pyrimidine skeleton and a heteroaromatic hydrocarbon ring having 2 to 30 carbon atoms in the ring is further preferred.

Further specifically, the organic compound with an acid dissociation constant pKₐ of 8 or more is preferably an organic compound represented by General Formula (G1) below.

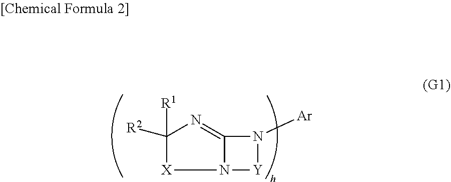

In the organic compound represented by General Formula (G1) above, X represents a group represented by General Formula (G1-1) below, and Y represents a group represented by General Formula (G1-2) below. R¹ and R² each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Ar is preferably the substituted or unsubstituted heteroaromatic hydrocarbon ring having 2 to 30 carbon atoms in the ring.

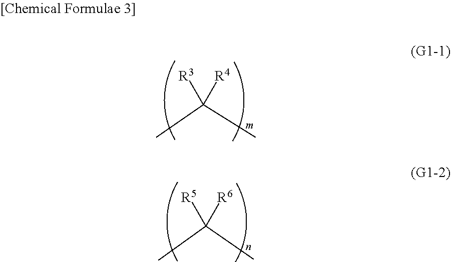

In General Formulae (G1-1) and (G1-2) above, R³ to R⁶ each independently represent hydrogen or deuterium, m represents an integer of 0 to 4, n represents an integer of 1 to 5, and m+1≥n (m+1 is larger than or equal to n) is satisfied. Note that in the case where m or n is 2 or more, R³s may be the same or different, and the same applies to R⁴s, R⁵s, and R⁶s.

The organic compound represented by General Formula (G1) above is preferably any one of compounds represented by General Formulae (G2-1) to (G2-6) below.

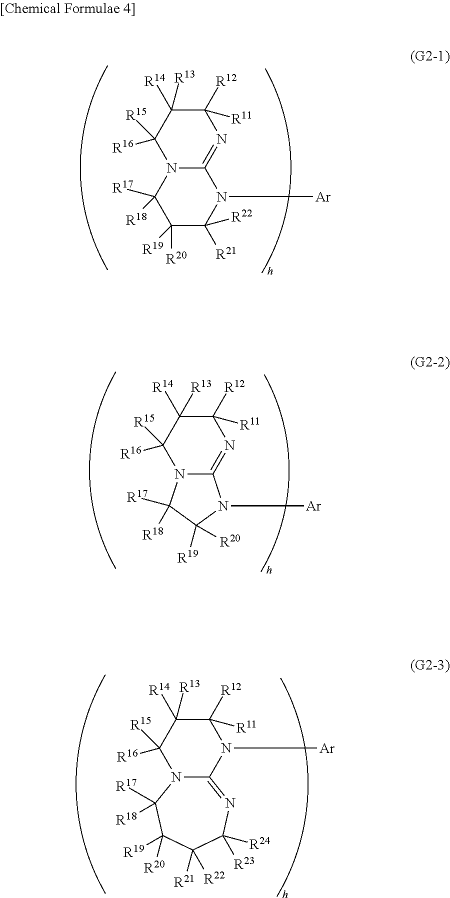

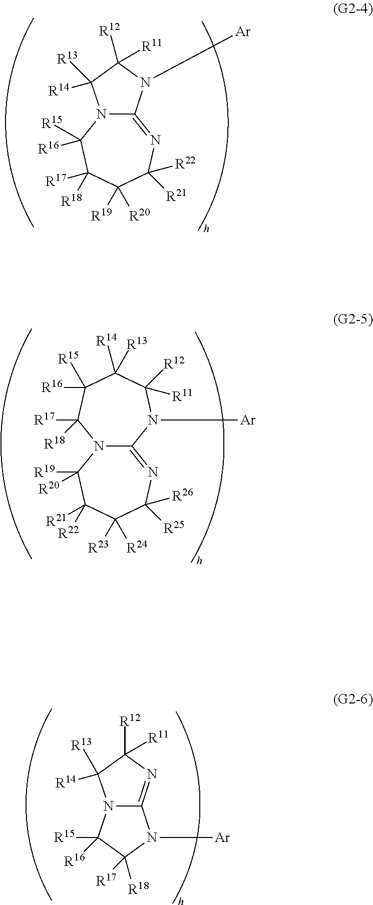

R¹¹ to R²⁶ each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Ar is preferably the substituted or unsubstituted heteroaromatic hydrocarbon ring having 2 to 30 carbon atoms in the ring.

In General Formula (G1) and General Formulae (G2-1) to (G2-6) above, the substituted or unsubstituted heteroaromatic hydrocarbon ring having 2 to 30 carbon atoms in the ring or the substituted or unsubstituted aromatic hydrocarbon ring having 6 to 30 carbon atoms in the ring that is represented by Ar is specifically a pyridine ring, a bipyridine ring, a pyrimidine ring, a bipyrimidine ring, a pyrazine ring, a bipyrazine ring, a triazine ring, a quinoline ring, an isoquinoline ring, a benzoquinoline ring, a phenanthroline ring, a quinoxaline ring, a benzoquinoxaline ring, a dibenzoquinoxaline ring, an azofluorene ring, a diazofluorene ring, a carbazole ring, a benzocarbazole ring, a dibenzocarbazole ring, a dibenzofuran ring, a benzonaphthofuran ring, a dinaphthofuran ring, a dibenzothiophene ring, a benzonaphthothiophene ring, a dinaphthothiophene ring, a benzofuropyridine ring, a benzofuropyrimidine ring, a benzothiopyridine ring, a benzothiopyrimidine ring, a naphthofuropyridine ring, a naphthofuropyrimidine ring, a naphthothiopyridine ring, a naphthothiopyrimidine ring, an acridine ring, a xanthene ring, a phenothiazine ring, a phenoxazine ring, a phenazine ring, a triazole ring, an oxazole ring, an oxadiazole ring, a thiazole ring, a thiadiazole ring, an imidazole ring, a benzimidazole ring, a pyrazole ring, a pyrrole ring, or the like. In General Formula (G1) and General Formulae (G2-1) to (G2-6) above, the substituted or unsubstituted heteroaromatic hydrocarbon ring having 6 to 30 carbon atoms in the ring that is represented by Ar is specifically a benzene ring, a naphthalene ring, a fluorene ring, a dimethylfluorene ring, a diphenylfluorene ring, a spirofluorene ring, an anthracene ring, a phenanthrene ring, a triphenylene ring, a pyrene ring, a tetracene ring, a chrysene ring, a benzo[a]anthracene ring, or the like. Ar is especially preferably represented by any one of Structural Formulae (Ar-1) to (Ar-27) below.

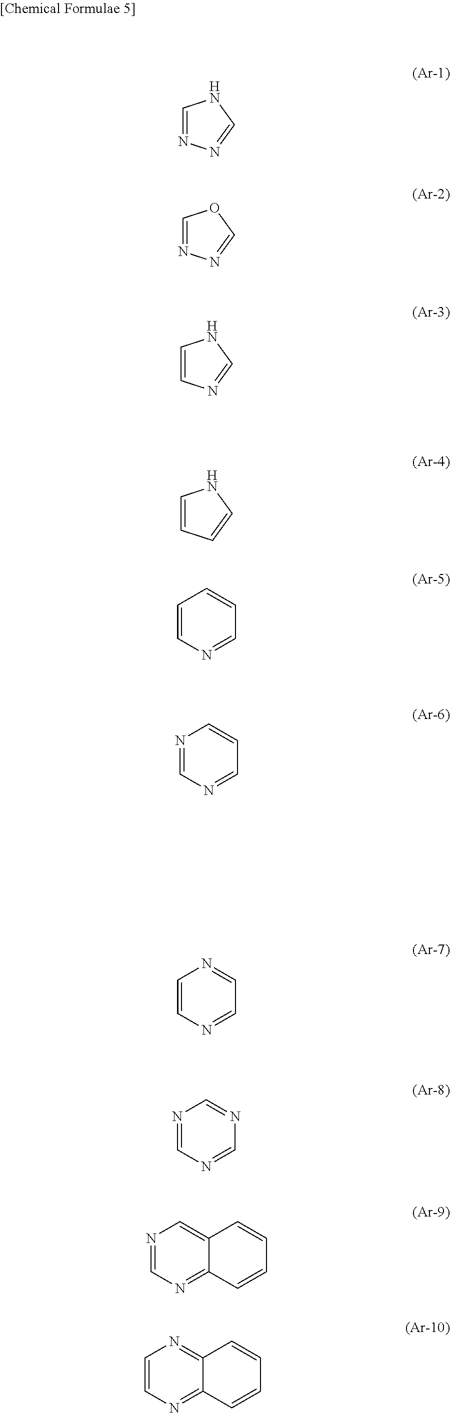

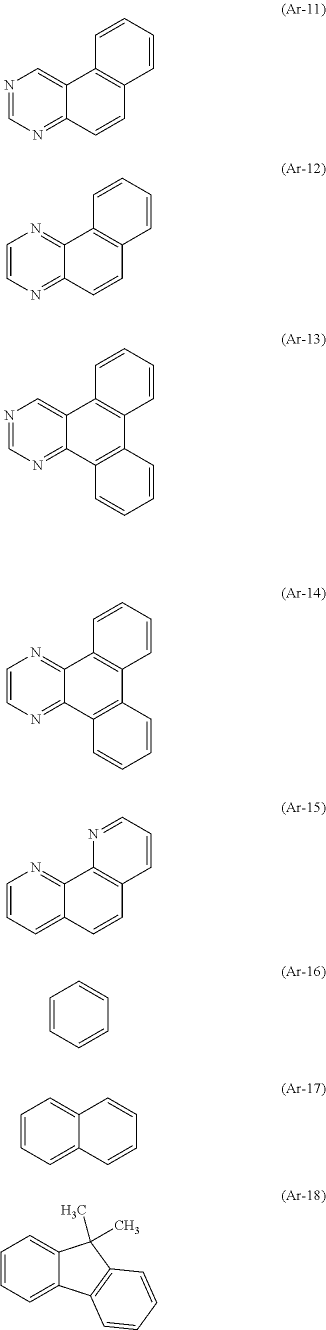

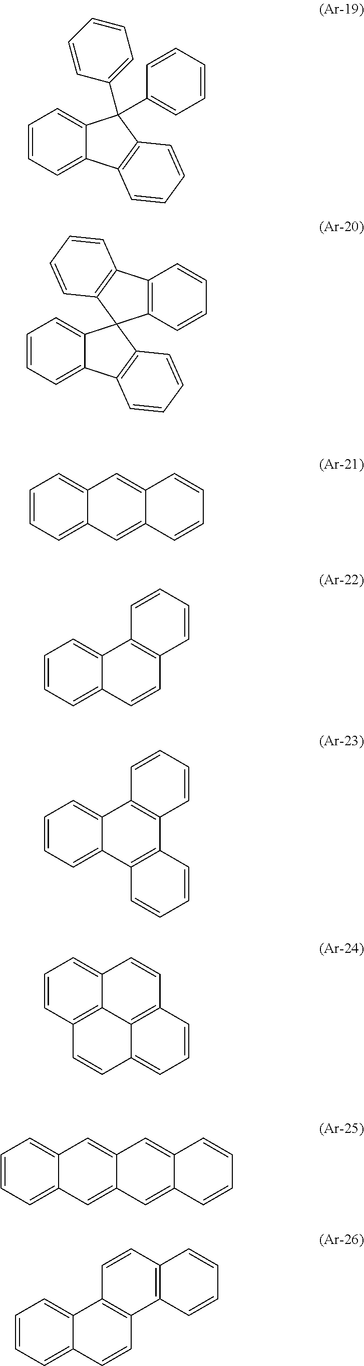

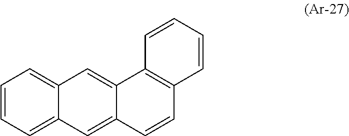 [SMILES: c1ccc2cc3c(ccc4ccccc43)cc2c1]

Note that Ar preferably has a nitrogen atom in its ring and is preferably bonded to the skeleton within parentheses in General Formula (G1) above by a bond of the nitrogen atom or a carbon atom adjacent to the nitrogen atom.

As specific examples of the organic compounds represented by General Formula (G1) and General Formulae (G2-1) to (G2-6) above, organic compounds represented by Structural Formulae (101) to (117) below, such as 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF) (Structural Formula 108) and 1-(9,9′-spirobi[9H-fluoren]-2-yl)-1,3,4,6,7,8-hexahydro-2H-pyrimido[1,2-a]pyrimidine (abbreviation: 2hppSF) (Structural Formula 109) can be given.

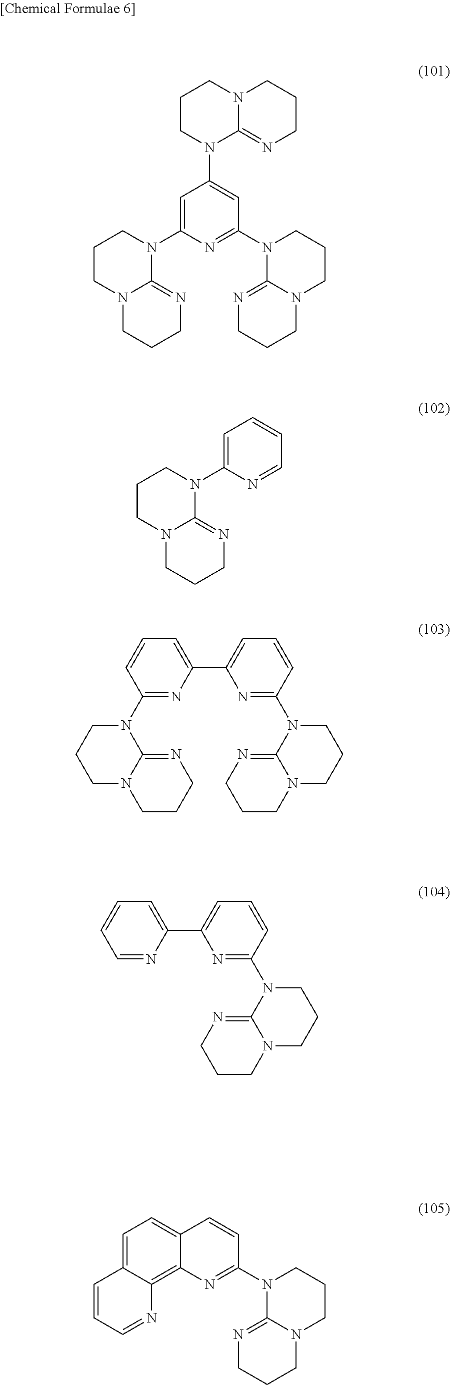 [SMILES: c1c(N2CCCN3CCCN=C32)cc(N2CCCN3CCCN=C32)nc1N1CCCN2CCCN=C21 ; c1ccc(N2CCCN3CCCN=C32)nc1 ; c1cc(-c2cccc(N3CCCN4CCCN=C43)n2)nc(N2CCCN3CCCN=C32)c1 ; c1ccc(-c2cccc(N3CCCN4CCCN=C43)n2)nc1 ; c1cnc2c(c1)ccc1ccc(N3CCCN4CCCN=C43)nc12]

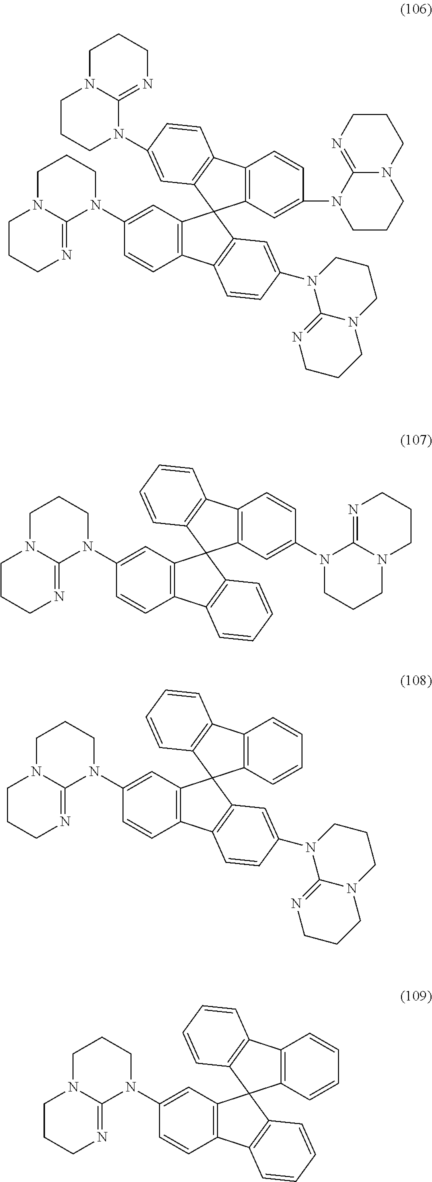 [SMILES: c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21 ; c1ccc2c(c1)-c1ccccc1C21c2ccccc2-c2ccc(N3CCCN4CCCN=C43)cc21]

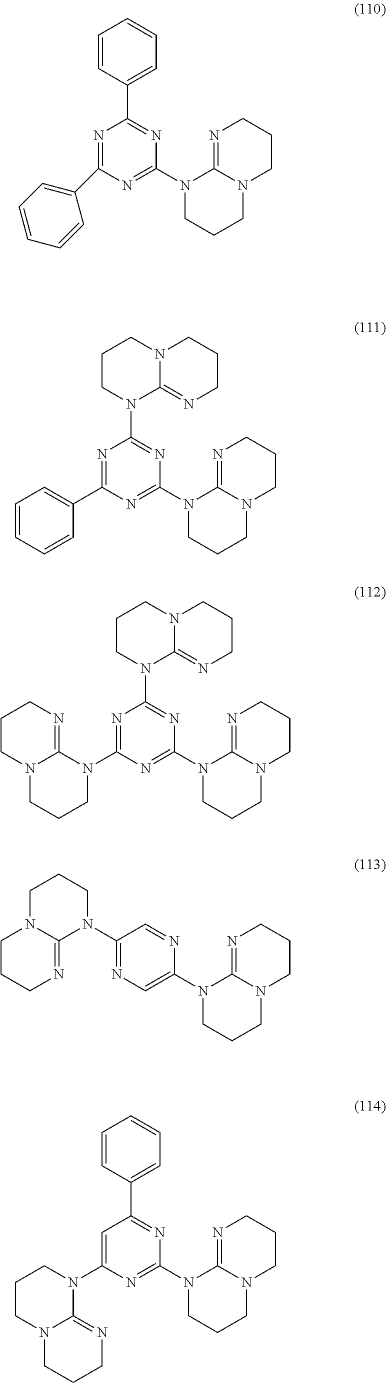 [SMILES: c1ccc(-c2nc(-c3ccccc3)nc(N3CCCN4CCCN=C43)n2)cc1 ; c1ccc(-c2nc(N3CCCN4CCCN=C43)nc(N3CCCN4CCCN=C43)n2)cc1 ; C1CN=C2N(C1)CCCN2c1nc(N2CCCN3CCCN=C32)nc(N2CCCN3CCCN=C32)n1 ; c1nc(N2CCCN3CCCN=C32)cnc1N1CCCN2CCCN=C21 ; c1ccc(-c2cc(N3CCCN4CCCN=C43)nc(N3CCCN4CCCN=C43)n2)cc1]

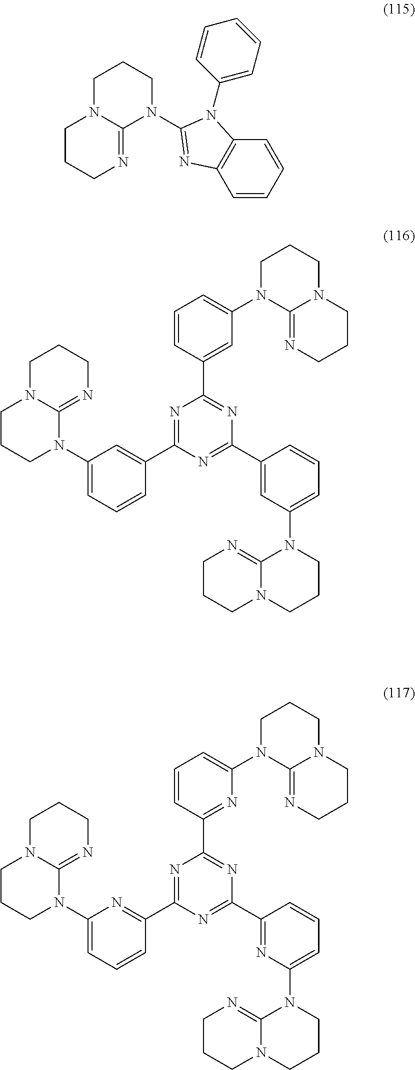 [SMILES: c1ccc(-n2c(N3CCCN4CCCN=C43)nc3ccccc32)cc1 ; c1cc(-c2nc(-c3cccc(N4CCCN5CCCN=C54)c3)nc(-c3cccc(N4CCCN5CCCN=C54)c3)n2)cc(N2CCCN3CCCN=C32)c1 ; c1cc(-c2nc(-c3cccc(N4CCCN5CCCN=C54)n3)nc(-c3cccc(N4CCCN5CCCN=C54)n3)n2)nc(N2CCCN3CCCN=C32)c1]

Unlike an alkali metal, an alkaline earth metal, or a compound thereof, these organic compounds do not have a concern about metal contamination in a production line and can be easily evaporated as well as being stable, for example, and thus can be favorably used particularly for light-emitting devices formed through a photolithography process. Needless to say, it is also effective to use these organic compounds for light-emitting devices formed not through a photolithography process.

Note that it is preferable that a strongly basic material with pKₐ of 8 or more do not have an electron-transport skeleton so that injected electrons and blocked holes are inhibited from recombining on the strongly basic material with pKₐ of 8 or more.

In particular, 2hppSF is a material with strong basicity of pKₐ of 8 or more and negative GSP_slope, and thus can be referred to as the first substance. The use of 2hppSF is preferable because a hole-block layer with negative GSP_slope can be formed using one material and thus a light-emitting device having low driving voltage can be provided.

Whether a layer formed of a certain material blocks holes can be judged by forming an electronic device that makes only holes flow (hereinafter referred to as a hole-only device) and measuring the relation between current density and voltage. For example, in the case where the current density of a hole-only device shown in Table 3, in which a target layer is sandwiched, is extremely low, the target layer can be regarded as a layer that blocks holes. Specifically, in the case where the current density at 10 V of the measurement device shown in Table 3 is lower than or equal to 0.01 mA/cm², a layer 3 can be regarded as a layer that blocks holes.

TABLE 3

| | thickness | |
|---|---|---|
| | (nm) | |
| second electrode | 100 | aluminum |
| layer 5 | 5 | molybdenum oxide |
| layer 4 | 50 | PCBBiF |
| layer 3 | 10 | measurement layer |
| layer 2 | 50 | PCBBiF |
| layer 1 | 10 | PCBBiF:OCHD003 |
| | | (1:0.15) |
| first electrode | 70 | ITSO |

In Table 3, ITSO represents indium tin oxide containing silicon oxide, PCBBiF represents N-(biphenyl-4-yl)-N-[4-(9-phenyl-9H-carbazol-3-yl)phenyl]-9,9-dimethyl-9H-fluoren-2-amine, and OCHD-003 represents a fluorine-containing electron-acceptor material having a molecular weight of 672.

The relation between current density and voltage is preferably compared between such a measurement device in which the layer 3 is not formed and the measurement device with the 10-nm-thick target layer as the layer 3. In the case where measurement is performed with the 10-nm-thick target layer serving as the layer 3 sandwiched, the target layer offering a current density at 10 V of lower than or equal to 0.01 mA/cm² can be regarded as a layer that blocks holes.

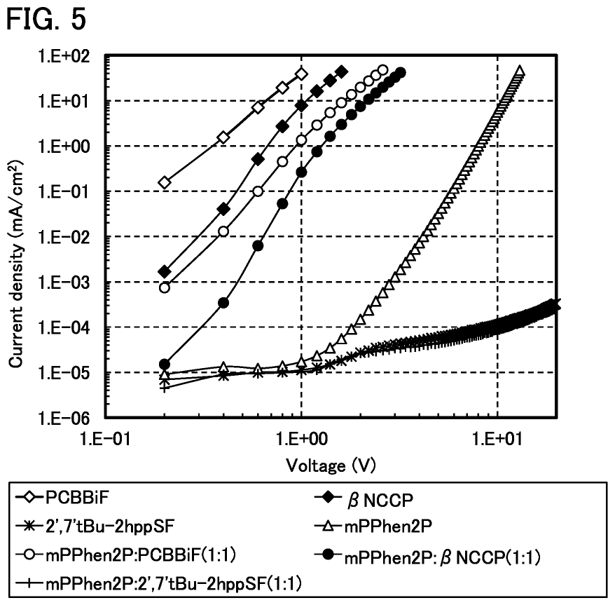

FIG. 5 shows measurement results using such devices. FIG. 5 shows results of hole-only measurement devices including, as the layers 3, a single film of N-(biphenyl-4-yl)-N-[4-(9-phenyl-9H-carbazol-3-yl)phenyl]-9,9-dimethyl-9H-fluoren-2-amine (abbreviation: PCBBiF), a single film of 9-(2-naphthyl)-9′-phenyl-9H,9′H-3,3′-bicarbazole (abbreviation: PNCCP), a single film of 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′,7′tBu-2hppSF), a single film of 2,2′-(1,3-phenylene)bis(9-phenyl-1,10-phenanthroline) (abbreviation: mPPhen2P), a film formed by co-evaporation of mPPhen2P and PCBBiF in a weight ratio of 1:1, a film formed by co-evaporation of mPPhen2P and PNCCP in a weight ratio of 1:1, and a film formed by co-evaporation of mPPhen2P:2′,7′tBu-2hppSF in a weight ratio of 1:1.

From the graph, the layers formed of PCBBiF, PNCCP, mPPhen2P, mPPhen2P and PCBBiF (in a weight ratio of 1:1), and mPPhen2P and PNCCP (in a weight ratio of 1:1) are layers that do not block holes, and the layers formed of mPPhen2P and 2′,7′tBu-2hppSF (in a weight ratio of 1:1) and 2′,7′tBu-2hppSF are layers that block holes.

In the case where the measurement target layer is a mixed layer of Material A and Material B, the hole-only device in which the mixed layer is provided as the measurement target layer (Device X) and the hole-only device in which a single layer of Material A or Material B, whichever has a deeper highest occupied molecular orbital (HOMO) level, is provided as the measurement target layer (Device Y) are fabricated. In the case where the voltage at 1 mA/cm² of Device X is higher than that of Device Y by 1 V or more, the mixed layer can be regarded as a layer that blocks holes.

The first layer preferably has an electron-transport property in order to transport injected electrons to the second layer. The first layer preferably has a hole mobility higher than or equal to 1×10⁻⁸ cm²/Vs in the case where the square root of electric field strength [V/cm] is 600. Thus, the first layer preferably includes an electron-transport material. As the electron-transport material, a material having an electron-transport skeleton is preferable. Note that the electron-transport skeleton is preferably a skeleton having a π-electron deficient heteroaromatic ring. As the skeleton having a π-electron deficient heteroaromatic ring, a skeleton having at least one of a polyazole skeleton, a pyridine skeleton, a diazine skeleton, and a triazine skeleton in the ring is preferably used, for example. Specifically, a pyrimidine skeleton, a pyrazine skeleton, a pyridazine skeleton, a pyridine skeleton, a triazine skeleton, a benzofuropyrimidine skeleton, a benzothienopyrimidine skeleton, a benzofuropyrazine skeleton, a benzothienopyrazine skeleton, or the like is preferable. Among them, a pyrimidine skeleton, a pyrazine skeleton, a triazine skeleton, or a benzofuropyrimidine skeleton is preferable.

Examples of the electron-transport material include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalene-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl)biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). The organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high reliability.

As the electron-transport material, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can also be used. Examples of the organic compound having a π-electron deficient heteroaromatic ring skeleton include an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

An organic compound having a phenanthroline skeleton such as mTpPPhen, PnNPhen, or mPPhen2P is especially preferable, and an organic compound having a phenanthroline dimer structure such as mPPhen2P is further preferable because of its excellent stability. Furthermore, a material having a pyridine skeleton or a phenanthroline skeleton, which has a large pKₐ and thus has a high hole-blocking property, is particularly preferable.

The LUMO level of the electron-transport material in the first layer is preferably greater than or equal to −3.00 eV and less than or equal to −2.00 eV in order to lower a barrier to electron injection to the light-emitting layer.

In the case where the first layer includes both an electron-transport material and a strongly basic material, it is preferable that the strongly basic material do not have a property of donating electrons to the electron-transport material. In the case where the strongly basic material does not have an electron-donating property, the material does not easily react with atmospheric components such as water and oxygen and the stability is improved. Accordingly, the intermediate layer and the tandem light-emitting device that are more stable with respect to atmospheric components such as water and oxygen can be formed. Thus, it is preferable that a signal observed by electron spin resonance (ESR) spectroscopy on the first layer be small or no signal be observed. For example, the spin density attributed to a signal observed at a g-factor of approximately 2.00 is preferably lower than or equal to 1×10¹⁷ spins/cm³, further preferably lower than 1×10¹⁶ spins/cm³.

The thickness of the first layer is preferably small; however, too large a thickness increases driving voltage and too small a thickness worsens characteristics, particularly reliability. Therefore, the thickness of the first layer is preferably greater than or equal to 2 nm and less than or equal to 13 nm, further preferably greater than or equal to 5 nm and less than or equal to 10 nm.

Note that most organic compounds have positive GSP_slope, but the first layer including a mixture of an organic compound and the first substance with negative GSP_slope can serve as a layer with negative GSP_slope. Here, the mixing ratio of the first substance and an electron-transport material, with which the first layer can be a layer with negative GSP_slope, depends on the GSP_slope values of the first substance and the electron-transport material. By increasing the proportion of the first substance as appropriate, the first layer can serve as a layer with negative GSP_slope.

The first layer is deposited on and in contact with the second layer. The second layer serving as a base of the first layer is positioned closer to the substrate than the first layer is. That is, the first layer is formed after the second layer is formed. The second layer also has a function of transporting electrons to the light-emitting layer and thus is preferably a layer having an electron-transport property. Specifically, the second layer is preferably an electron-transport layer included in the light-emitting unit in contact with the surface of the intermediate layer on the anode side. Note that the layer serving as a base may be a light-emitting layer or a hole-block layer.

The second layer preferably has a hole mobility higher than or equal to 1×10⁻⁸ cm²/Vs in the case where the square root of electric field strength [V/cm] is 600. Thus, the second layer preferably includes an electron-transport material. As the electron-transport material, a material having an electron-transport skeleton is preferable. Note that the electron-transport skeleton is preferably a skeleton having a π-electron deficient heteroaromatic ring. As the skeleton having a π-electron deficient heteroaromatic ring, a skeleton having at least one of a polyazole skeleton, a pyridine skeleton, a diazine skeleton, and a triazine skeleton in the ring is preferably used, for example. Specifically, a pyrimidine skeleton, a pyrazine skeleton, a pyridazine skeleton, a pyridine skeleton, a triazine skeleton, a benzofuropyrimidine skeleton, a benzothienopyrimidine skeleton, a benzofuropyrazine skeleton, a benzothienopyrazine skeleton, or the like is preferable. Among them, a pyrimidine skeleton, a pyrazine skeleton, a triazine skeleton, or a benzofuropyrimidine skeleton is preferable. Specifically, it is possible to use a material similar to the electron-transport material exemplified as a material that can be used for the first layer.

In the case where the first layer has a hole-blocking property, accumulating holes enables a light-emitting device having low driving voltage; thus, the second layer preferably has a bipolar property, that is, is preferably an electron-transport layer having a relatively high hole-transport property. Accordingly, the HOMO level of the organic compound included in the second layer is preferably greater than or equal to −5.90 eV and less than or equal to −5.00 eV, further preferably greater than or equal to −5.80 eV and less than or equal to −5.00 eV, still further preferably greater than or equal to −5.70 eV and less than or equal to −5.15 eV. Since the second layer also needs to have a high electron-transport property, the LUMO level of the organic compound included in the second layer is preferably greater than or equal to −3.15 eV and less than or equal to −2.50 eV, further preferably greater than or equal to −3.00 eV and less than or equal to −2.70 eV.

The second layer may be formed using a single material or a plurality of materials. In the case where a plurality of organic compounds are included in the second layer, the HOMO level of the organic compound having the highest HOMO level is preferably within the above-described range, and the LUMO level of the organic compound having the lowest LUMO level is preferably within the above-described range. Moreover, in the case where a plurality of organic compounds are included in the second layer, at least one of the organic compounds is preferably an electron-transport organic compound and at least one of the organic compounds is preferably a hole-transport organic compound.

The electron-transport organic compound and the hole-transport organic compound are preferably a single organic compound. In other words, it is preferable that the second layer include an organic compound having both an electron-transport property and a hole-transport property because of facilitating formation of a light-emitting device with favorable characteristics.

The electron-transport organic compound or the organic compound having both an electron-transport property and a hole-transport property, which is used for the second layer, is preferably a substance having an electron mobility higher than or equal to 1×10⁻⁷ cm²/Vs, preferably higher than or equal to 1×10⁻⁶ cm²/Vs in the case where the square root of the electric field strength [V/cm] is 600. The hole-transport organic compound or the organic compound having both an electron-transport property and a hole-transport property is preferably a substance having a hole mobility higher than or equal to 1×10⁻⁷ cm²/Vs, preferably higher than or equal to 1×10⁻⁶ cm²/Vs in the case where the square root of the electric field strength [V/cm] is 600.

The second layer preferably includes an electron-transport organic compound with an acid dissociation constant pKₐ of 4 or less.

The second layer preferably includes an organic compound having an electron-transport skeleton and an organic compound having a hole-transport skeleton. The organic compound having an electron-transport skeleton and the organic compound having a hole-transport skeleton are preferably a single organic compound. In other words, it is preferable that the second layer include an organic compound having both an electron-transport skeleton and a hole-transport skeleton because of facilitating formation of a light-emitting device with favorable characteristics.

Note that the electron-transport skeleton is preferably a skeleton having a π-electron deficient heteroaromatic ring. As the skeleton having a π-electron deficient heteroaromatic ring, a skeleton having at least one of a polyazole skeleton, a pyridine skeleton, a diazine skeleton, and a triazine skeleton in the ring is preferably used, for example. Specifically, a pyrimidine skeleton, a pyrazine skeleton, a pyridazine skeleton, a pyridine skeleton, a triazine skeleton, a benzofuropyrimidine skeleton, a benzothienopyrimidine skeleton, a benzofuropyrazine skeleton, a benzothienopyrazine skeleton, or the like is preferable. Among them, a pyrimidine skeleton, a pyrazine skeleton, a triazine skeleton, or a benzofuropyrimidine skeleton is preferable. Furthermore, the hole-transport skeleton is preferably a skeleton having a π-electron rich heteroaromatic ring. As the π-electron rich heteroaromatic ring, a condensed aromatic ring having at least one of a pyrrole skeleton, a furan skeleton, and a thiophene skeleton in the ring is preferably used, for example. Specifically, a carbazole skeleton, a dibenzothiophene skeleton, or a skeleton in which an aromatic ring or a heteroaromatic ring is further condensed to a carbazole skeleton or a dibenzothiophene skeleton is preferable. Among them, a carbazole skeleton, a biscarbazole skeleton, or an indolocarbazole skeleton is preferable. An amine skeleton, especially a triphenylamine skeleton is also preferable.

As described above, an organic compound having both an electron-transport skeleton and a hole-transport skeleton is preferable as the organic compound included in the second layer. Specific examples of the organic compound include 3,6-bis(diphenylamino)-9-[4-(4,6-diphenyl-1,3,5-triazin-2-yl)phenyl]-9H-carbazole (abbreviation: DACT-II), 2-{3-[3-(N-phenyl-9H-carbazol-3-yl)-9H-carbazol-9-yl]phenyl}dibenzo[f,h]quinoxaline (abbreviation: 2mPCCzPDBq), 9-[3-(4,6-diphenyl-1,3,5-triazin-2-yl)phenyl]-9′-phenyl-2,3′-bi-9H-carbazole (abbreviation: mPCCzPTzn-02), and 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn).

The organic compound included in the second layer preferably exhibits thermally activated delayed fluorescence (TADF) (a TADF property). The organic compound having a TADF property has a high HOMO level, a low LUMO level, and short singlet and triplet excitation lifetimes; thus, in the case where recombination occurs in the second layer, the excited state can be readily deactivated, providing a light-emitting device with high reliability. Among the preferable organic compounds included in the second layer, DACT-II is the organic compound having a TADF property.

In the case where the second layer is formed of a plurality of kinds of materials, a material having an electron-transport skeleton is preferably used as an electron-transport material. Note that the electron-transport skeleton is preferably a skeleton having a π-electron deficient heteroaromatic ring. As the skeleton having a π-electron deficient heteroaromatic ring, a skeleton having at least one of a polyazole skeleton, a pyridine skeleton, a diazine skeleton, and a triazine skeleton in the ring is preferably used, for example. Specifically, a pyrimidine skeleton, a pyrazine skeleton, a pyridazine skeleton, a pyridine skeleton, a triazine skeleton, a benzofuropyrimidine skeleton, a benzothienopyrimidine skeleton, a benzofuropyrazine skeleton, a benzothienopyrazine skeleton, or the like is preferable. Among them, a pyrimidine skeleton, a pyrazine skeleton, a triazine skeleton, or a benzofuropyrimidine skeleton is preferable. Specifically, it is possible to use a material similar to the electron-transport material exemplified as a material that can be used for the first layer.

Examples of the hole-transport organic compound in the case where the second layer is formed of a plurality of kinds of organic compounds include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yl)triphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), N-(9,9-diphenyl-9H-fluoren-2-yl)-N,9-diphenyl-9H-carbazol-3-amine (abbreviation: PCAFLP(2)), and N-(9,9-diphenyl-9H-fluoren-2-yl)-N,9-diphenyl-9H-carbazol-2-amine (abbreviation: PCAFLP(2)-02).

Although the thickness of the second layer is preferably small, a thickness of 5 nm to 10 nm is preferable in order to form a light-emitting device with high reliability.

The P-type CGL is preferably formed using a composite material containing a material having an electron-acceptor property and a hole-transport organic compound.

The material having an electron-acceptor property preferably has an electron-accepting property with respect to a hole-transport organic compound. When the material having an electron-acceptor property has an electron-accepting property, the P-type CGL can function as a charge-generation layer owing to charge separation in the P-type CGL and thus can function as an intermediate layer of a tandem light-emitting device. Furthermore, it is preferable that a signal be observed by electron spin resonance spectroscopy on the P-type CGL. For example, the spin density attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³.

Examples of the substance having an acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], a,α′,α″-1,2,3-cyclopropanetriylidenetris[2,6-dichloro-3,5-difluoro-4-(trifluoromethyl)benzeneacetonitrile], and a,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

As the hole-transport organic compound used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the hole-transport organic compound used in the composite material preferably has a hole mobility higher than or equal to 1×10⁻⁶ cm²/Vs. The hole-transport organic compound used in the composite material preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such a hole-transport organic compound further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the hole-transport organic compound preferably has an N,N-bis(4-biphenyl)amino group to enable fabricating a light-emitting device with a long lifetime.

As the above-described hole-transport organic compound, specifically, the material described as a material that can be used as a hole-transport organic compound in the case where the second layer is formed using a plurality of kinds of organic compounds can also be used.

Examples of the aromatic amine compounds that can be used as the hole-transport material include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

A third layer is preferably provided between the P-type CGL and the first layer. The third layer has at least an electron-transport property and has a function of preventing interaction between the P-type CGL and the first layer and smoothly transferring electrons. The LUMO level of an electron-transport substance included in the third layer is preferably positioned between the LUMO level of the acceptor substance in the P-type CGL and the lowest LUMO level of the material included in the first layer. Specifically, the LUMO level of the electron-transport substance included in the third layer is preferably higher than or equal to −5.00 eV, further preferably higher than or equal to −4.30 eV and preferably lower than or equal to −3.00 eV, further preferably lower than or equal to −3.25 eV. The LUMO level of the electron-transport substance included in the third layer is further preferably higher than or equal to −5.00 eV and lower than or equal to −3.00 eV, still further preferably higher than or equal to −4.30 eV and lower than or equal to −3.25 eV. The use of a layer formed of such a material as the third layer is preferable because the electron-injection property is improved, an increase in driving voltage is suppressed, and the reliability is improved. Examples of the electron-transport substance that is used for the third layer include a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI); (C₆₀—Iₕ) [5,6]fullerene (abbreviation: C60); (C₇₀-D₅ₕ) [5,6]fullerene (abbreviation: C70); an organic compound such as phthalocyanine (abbreviation: H2Pc); and a metal phthalocyanine containing copper, zinc, cobalt, iron, chromium, nickel, vanadium, titanium, tin, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). A phthalocyanine-based metal complex such as CuPc or ZnPc and 2,3,8,9,14,15-hexafluorodiquinoxalino[2,3-a:2′,3′-c]phenazine are especially preferable. Among these substances, CuPc and ZnPc are preferable because they are inexpensive and have favorable characteristics. Using ZnPc, which has a low diffusion coefficient with respect to silicon, reduces the probability that metal diffusion to a semiconductor adversely affects the semiconductor characteristics; accordingly, ZnPc is particularly suitable for a display device fabricated using a silicon semiconductor.

The thickness of the third layer is greater than or equal to 1 nm and less than or equal to 10 nm, preferably greater than or equal to 2 nm and less than or equal to 5 nm.

The light-emitting device of one embodiment of the present invention having the above-described structure can have high current efficiency and a suppressed increase in driving voltage.

One embodiment of the present invention is particularly suitably used in a light-emitting device formed through a photolithography process and also contributes to cost reduction in manufacturing of light-emitting devices not formed through a photolithography process because high stability in the atmosphere of one embodiment of the present invention increases yield and eliminates the need for too strictly managing the atmosphere in the manufacturing process.

### Embodiment 2

This embodiment describes a light-emitting device of one embodiment of the present invention having an inverted stacked structure (formed by a method in which a cathode is stacked first) whereas Embodiment 1 mainly describes an ordered stacked structure (formed by a method in which an anode is stacked first).

In a light-emitting device having an inverted stacked structure, a cathode is formed over a substrate, i.e., the stacking order in FIG. 1A is reversed, so that as illustrated in FIG. 1B, the second layer 22 is formed after the first layer 21 is formed. Here, in order to make the high-density positive interface charges 50 exist at the interface between the first layer 21 and the second layer 22, the first layer 21 and the second layer 22 are preferably formed using a material with positive GSP_slope and a material with negative GSP_slope, respectively. In such a manner, a tandem light-emitting device in which an increase in driving voltage is suppressed can be obtained without using an N-type CGL as the first layer 21. The tandem light-emitting device does not include a Li compound or the like in the first layer 21, and thus can be a light-emitting device in which an increase in driving voltage is suppressed even when fabricated through a photolithography process.

In this case, the second layer 22 can include the substance described as a material with negative GSP_slope in Embodiment 1. Note that in order to further reduce driving voltage by accumulating holes, which are injected from the anode 101, in the vicinity of the interface between the second layer 22 and the first layer 21, the second layer 22 preferably has a hole-transport property and thus preferably includes no strongly basic material with pKₐ of 8 or more.

The second layer 22 requires a function of transporting electrons, which are injected from the first layer 21, to the light-emitting layer 113_1 on the anode 101 side, so that the second layer 22 preferably has an electron-transport property, and preferably includes an electron-transport material. In addition, the second layer 22 preferably has a hole-transport property as described above, so that the second layer 22 is preferably formed using a material having both a hole-transport property and an electron-transport property, and preferably includes a material having a hole-transport skeleton and an electron-transport skeleton. The second layer 22 may include both an electron-transport material and a hole-transport material.

Meanwhile, since the first layer 21 preferably has a hole-blocking property, the first layer 21 preferably includes a strongly basic material with pKₐ of 8 or more.

### Embodiment 3

In this embodiment, a light-emitting device of one embodiment of the present invention will be described in detail.

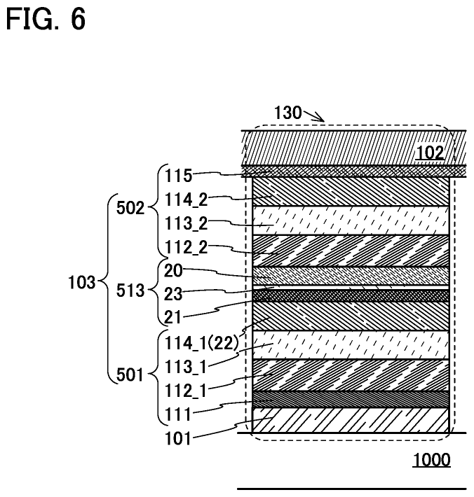

FIG. 6 is a schematic diagram of the light-emitting device of one embodiment of the present invention. The light-emitting device includes the anode 101 over the substrate 1000, and an organic compound layer 103 between the anode 101 and the cathode 102. As described in Embodiment 1, the organic compound layer 103 includes a plurality of light-emitting units (the first light-emitting unit 501 and the second light-emitting unit 502 in FIG. 6) and the intermediate layer 513.

The first light-emitting unit 501 includes at least the light-emitting layer 113_1, and the second light-emitting unit 502 includes at least the light-emitting layer 113_2. The light-emitting layer 113_1 and the light-emitting layer 113_2 are each a layer including a light-emitting substance and emit light when voltage is applied between the anode 101 and the cathode 102.

The first light-emitting unit 501 preferably includes, in addition to the above-described layers, functional layers such as a hole-injection layer 111, a first hole-transport layer 1121, and the electron-transport layer 1141 as illustrated in FIG. 6. The first light-emitting unit 501 may include functional layers other than the above-described functional layers, such as a hole-block layer, an electron-block layer, and an exciton-block layer. Alternatively, any of the above-described layers may be omitted.

The second light-emitting unit 502 preferably includes, in addition to the above-described layers, functional layers such as a hole-transport layer 112_2, an electron-transport layer 114_2, and an electron-injection layer 115 as illustrated in FIG. 6. The second light-emitting unit 502 may include functional layers other than the above-described functional layers, such as a hole-block layer, an electron-block layer, and an exciton-block layer. Alternatively, any of the above-described layers may be omitted.

Furthermore, the intermediate layer 513 includes at least the first layer 21 and the P-type CGL 20 from the anode 101 side and may also include a third layer 23 between the first layer 21 and the P-type CGL 20. The first layer 21 is a layer with negative GSP_slope described in Embodiment 1. The first layer 21 may further include an electron-transport organic compound and/or a strongly basic material with an acid dissociation constant pKₐ of 8 or more. The P-type CGL 20 is a layer which generates charges by voltage application. The P-type CGL 20 is preferably a layer including a hole-transport organic compound and a substance having an acceptor property with respect to the organic compound. The third layer 23 is a layer provided to prevent interaction between the first layer 21 and the P-type CGL 20 for improving the reliability.

Since the structures of the first layer 21, the P-type CGL 20, and the third layer 23 have been specifically described in detail in Embodiment 1, repetitive descriptions thereof are omitted.

The anode 101 and the cathode 102 may each have a single-layer structure or a stacked-layer structure. In the case of the stacked-layer structure, a layer in contact with the organic compound layer 103 substantially functions as an anode or a cathode. In the case where the electrodes each have the stacked-layer structure, there is no limitation on work functions of materials for layers other than the layer in contact with the organic compound layer 103, and the materials are preferably selected in accordance with required properties such as a resistance value, processing easiness, reflectivity, light-transmitting property, and stability.

The anode 101 is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by application of a sol-gel method or the like. In an example of the formation method, indium oxide-zinc oxide is formed by a sputtering method using a target in which 1 wt % to 20 wt % zinc oxide is added to indium oxide. Furthermore, indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium, (Ti), aluminum (Al), a nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111, which is described later, is used for a layer (typically, the hole-injection layer) in contact with the anode, an electrode material can be selected regardless of its work function.

The hole-injection layer 111 is provided in contact with the anode and has a function of facilitating injection of holes to the organic compound layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance having an electron-acceptor property. Examples of the substance having an acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include a,α′,α″-1,2,3-cyclopropanetriylidenetris[4-cyano-2,3,5,6-tetrafluorobenzeneacetonitrile], a,α′,α″-1,2,3-cyclopropanetriylidenetris[2,6-dichloro-3,5-difluoro-4-(trifluoromethyl)benzeneacetonitrile], and a,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an acceptor property and a hole-transport organic compound. It is possible to use a composite material similar to that exemplified in Embodiment 1 as a material with which the P-type CGL can be formed.

The formation of the hole-injection layer 111 can improve the hole-injection property, which allows the light-emitting device to be driven at a low voltage.

Among substances having an acceptor property, the organic compound having an acceptor property is easy to use because it is easily deposited by vapor deposition.

The hole-transport layer 112_1 and the hole-transport layer 112_2 are each formed using a hole-transport organic compound. The hole-transport organic compound preferably has a hole mobility of 1×10⁻⁶ cm²/Vs or higher.

Examples of the hole-transport material include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, and 9-[4-(9-phenyl-9H-carbazol-3-yl)-phenyl]phenanthrene (abbreviation: PCPPn); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the hole-transport material used for the composite material for the hole-injection layer 111 can also be suitably used as the material included in each of the hole-transport layer 112_1 and the hole-transport layer 112_2.

The light-emitting layer 113_1 and the light-emitting layer 113_2 are each a layer including a light-emitting substance and preferably includes a light-emitting substance and a host material. The light-emitting layer 113 may additionally include other materials. Alternatively, the light-emitting layer 113 may be a stack of two layers with different compositions.

As the light-emitting substance, fluorescent substances, phosphorescent substances, substances exhibiting thermally activated delayed fluorescence (TADF), or other light-emitting substances may be used.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties and high emission efficiency or reliability.

A condensed heteroaromatic compound containing nitrogen and boron, especially a compound having a diaza-boranaphtho-anthracene skeleton, exhibits a narrow emission spectrum, emits blue light with favorable color purity, and can thus be used suitably. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-kl]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC) (abbreviation: CNImIr); an organometallic complex having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and an organometallic iridium complex in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)). These compounds emit blue phosphorescent light and have an emission peak in the wavelength range of 450 nm to 520 nm.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²)iridium(III) (abbreviation: [Ir(pq)₃]), bis(2-phenylquinolinato-N,C^{2′})iridium(III) acetylacetonate (abbreviation: [Ir(pq)₂(acac)]); [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]); and a rare earth metal complex such as tris(acetylacetonato) (monophenanthroline)terbium(III) (abbreviation: [Tb(acac)₃(Phen)]). These compounds mainly emit green phosphorescent light and have an emission peak in the wavelength range of 500 nm to 600 nm. Note that organometallic iridium complexes including a pyrimidine skeleton have distinctively high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range of 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

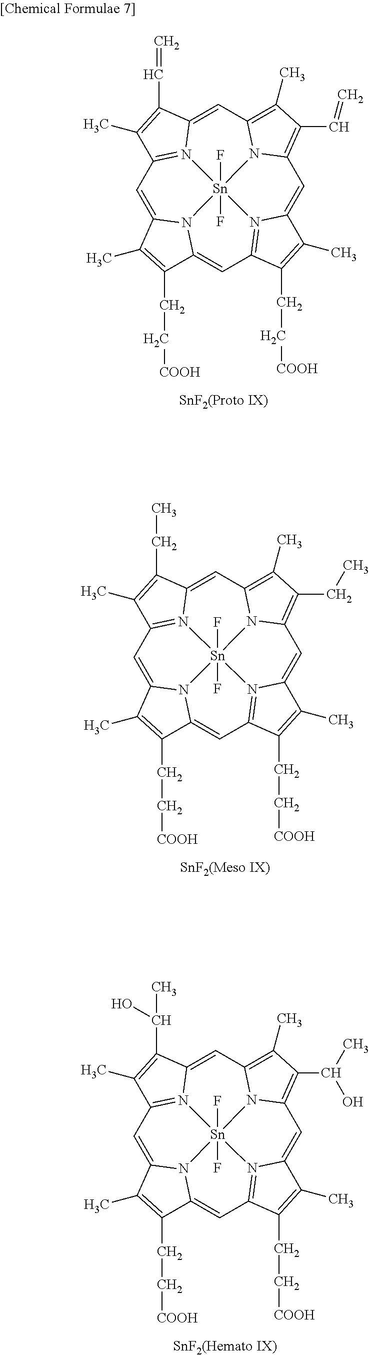

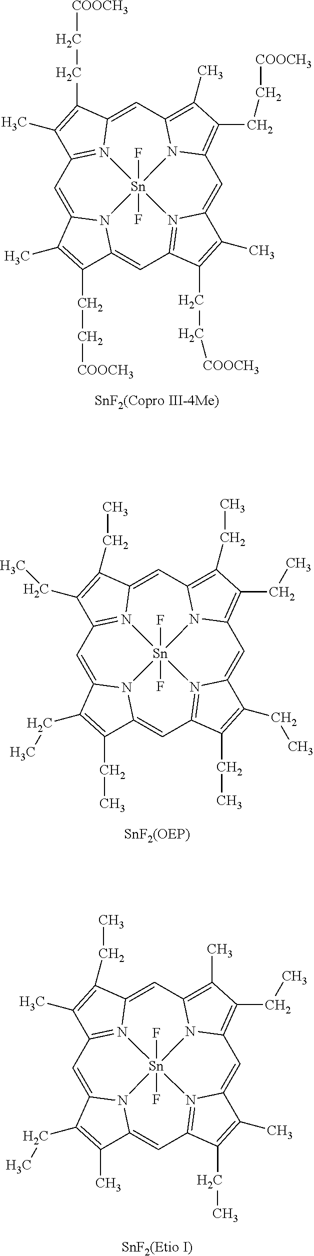

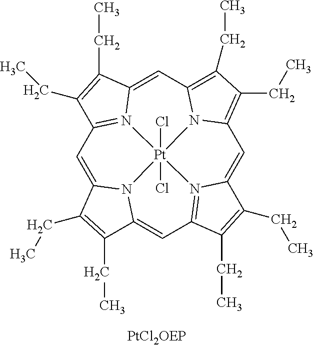

Alternatively, it is possible to use a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

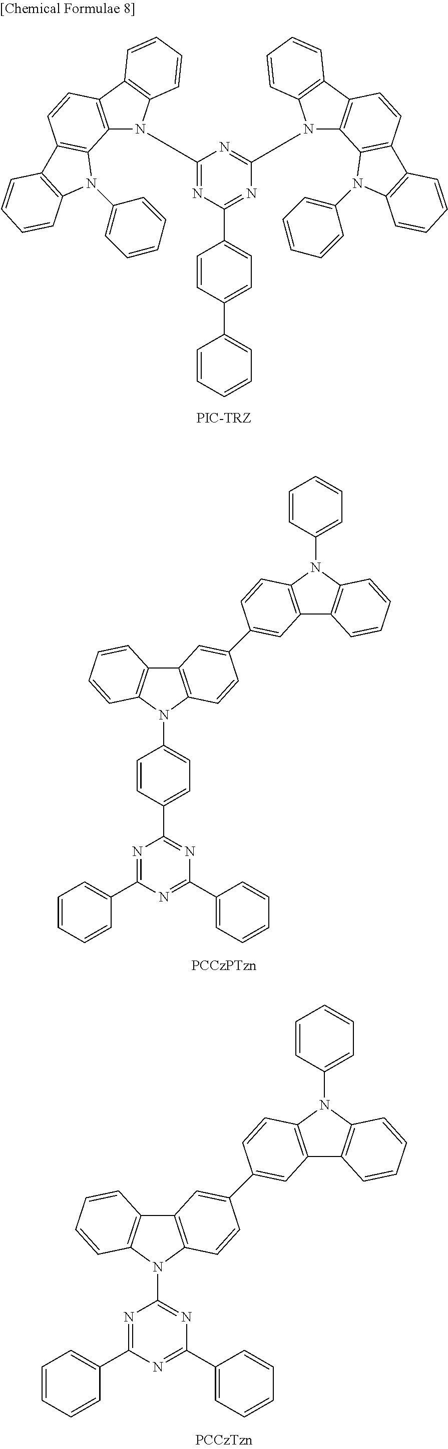 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

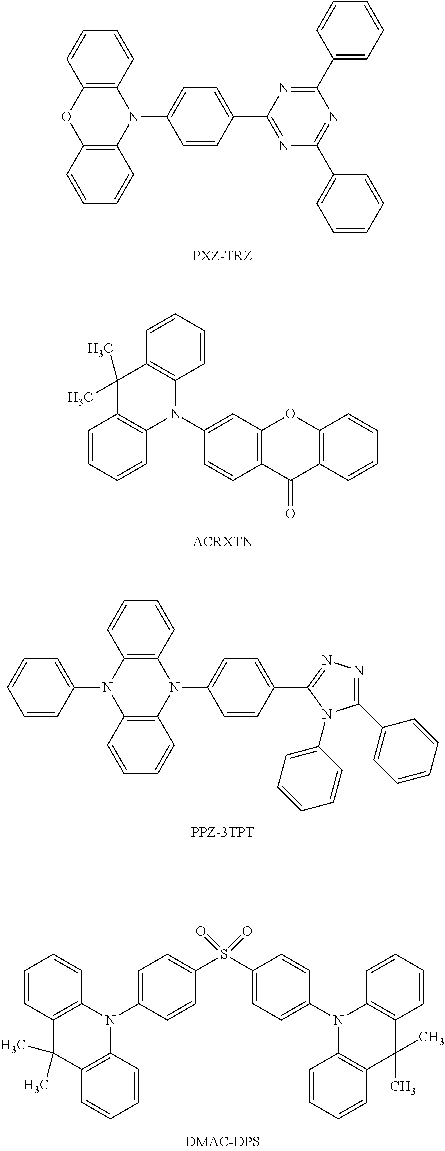 [SMILES: c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc(S(=O)(=O)c3ccc(N4c5ccccc5C(C)(C)c5ccccc54)cc3)cc2)c2ccccc21]

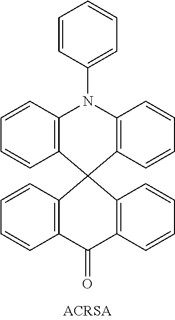 [SMILES: O=C1c2ccccc2C2(c3ccccc31)c1ccccc1N(c1ccccc1)c1ccccc12]

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, various carrier-transport materials such as electron-transport materials and/or hole-transport materials, and the TADF materials can be used.

The hole-transport material is preferably an organic compound having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such a hole-transport organic compound further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the hole-transport organic compound preferably has an N,N-bis(4-biphenyl)amino group to enable fabricating a light-emitting device with a long lifetime.

Specific examples of such an organic compound include the organic compound exemplified as the hole-transport material in the hole-transport layer. Among such materials, the compound having an aromatic amine skeleton and the compound having a carbazole skeleton are preferable because these compounds are highly reliable and have high hole-transport properties to contribute to a reduction in driving voltage. The use of a compound such as βNCCP, which has a bicarbazole skeleton and an aromatic hydrocarbon group, especially a naphthyl group, is preferable, in which case a light-emitting device with high reliability can be obtained. Note that the naphthyl group is preferably bonded to nitrogen at the 9-position of at least one of the two carbazole skeletons.

As the electron-transport material, a metal complex or an organic compound having a π-electron deficient heteroaromatic ring skeleton is preferably used, for example. Examples of the metal complex include bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ). Examples of the organic compound having a it-electron deficient heteroaromatic ring skeleton include an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the organic compounds each having a π-electron deficient heteroaromatic ring skeleton, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor property and high reliability.

Specific examples of the electron-transport material include the material exemplified as an electron-transport material that can be used for the first layer.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on a lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably includes an aromatic ring, and still further preferably includes a condensed aromatic ring or a condensed heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further condensed to a carbazole skeleton because the HOMO level thereof is shallower than that of the host material having a carbazole skeleton by approximately 0.1 eV and thus holes enter the host material easily. In particular, the host material preferably has a dibenzocarbazole skeleton because the HOMO level thereof is shallower than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix an electron-transport material with a hole-transport material. By mixing the electron-transport material with the hole-transport material, the transport property of the light-emitting layer 113 can be easily adjusted and a recombination region can be easily controlled. The weight ratio of the content of the hole-transport material to the content of the electron-transport material is preferably 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength on a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectrum of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

Since the electron-transport layer 1141 is the second layer 22 and thus has been described in detail in Embodiment 1, the repetitive description thereof is omitted.

The electron-transport layer 114_2 includes an electron-transport substance. The electron-transport material preferably has an electron mobility higher than or equal to 1×10⁻⁷ cm²/Vs, preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

As the electron-transport organic compound that can be used in the electron-transport layer 114_2, any of the aforementioned organic compounds that can be used as the electron-transport organic compound in the light-emitting layer 113_1 and the light-emitting layer 113_2 can also be used. Among the above-described materials, the organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. An organic compound having a phenanthroline skeleton such as mTpPPhen, PnNPhen, or mPPhen2P is especially preferable, and an organic compound having a phenanthroline dimer structure such as mPPhen2P is further preferable because of its excellent stability.

The electron-transport layer 114_1 and the electron-transport layer 114_2 may each have a stacked-layer structure. In the case where the electron-transport layer 114_1 has a stacked-layer structure, a layer in contact with the first layer 21 is the second layer 22 and has the structure as described in Embodiment 1. A layer on the light-emitting layer 113_1 side is preferably formed using any of the materials described as the materials with which the electron-transport layer 114_2 can be formed. In the case where the electron-transport layer 114_1 and the electron-transport layer 1142 each have a stacked-layer structure, layers in contact with the light-emitting layer 113_1 and the light-emitting layer 113_2 may each function as a hole-block layer. In the case where the electron-transport layer in contact with the light-emitting layer functions as a hole-block layer, the electron-transport layer is preferably formed using a material having a deeper HOMO level than a material included in the light-emitting layer by more than or equal to 0.5 eV.

A layer including an alkali metal, an alkaline earth metal, or a compound thereof such as lithium oxide (Li₂O), lithium fluoride (LiF), cesium fluoride (CsF), calcium fluoride (CaF₂), or 8-hydroxyquinolinato-lithium (Liq) may be provided as the electron-injection layer 115 between the electron-transport layer 1142 and the cathode 102. An electride or a layer that is formed using an electron-transport substance and includes an alkali metal, an alkaline earth metal, or a compound thereof can be used as the electron-injection layer 115. Examples of the electride include a substance in which electrons are added at high concentration to calcium oxide-aluminum oxide. Any of the organic compounds given as examples of the strongly basic organic compound in Embodiment 1 can be used.

The electron-injection layer 115 may be formed using any of the above substances alone, or any of the above substances included in a layer including an electron-transport substance.

Note that as the electron-injection layer 115, it is possible to use a layer including an electron-transport substance (preferably an organic compound having a bipyridine skeleton) that contains a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device including the layer can have favorable external quantum efficiency.

The cathode 102 may have a stacked-layer structure, in which case a layer in contact with the organic compound layer 103 substantially functions as a cathode. For the cathode, a metal, an alloy, an electrically conductive compound, or a mixture thereof each having a low work function (specifically, lower than or equal to 3.8 eV) or the like can be used. Specific examples of such a cathode material include elements belonging to Group 1 or 2 of the periodic table, such as alkali metals (e.g., lithium (Li) or cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the cathode 102 and the electron-transport layer, a variety of conductive materials such as Al, Ag, ITO, or indium oxide-tin oxide containing silicon or silicon oxide can be used for the cathode regardless of the work function.

When the cathode 102 is formed using a material that transmits visible light, the light-emitting device can emit light from the cathode 102 side. When the anode 101 is formed using a material that transmits visible light, the light-emitting device can emit light from the anode 101 side.

Films of these conductive materials can be deposited by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different deposition methods may be used to form the electrodes or the layers described above.

The light-emitting device having two light-emitting units is described with reference to FIG. 6; however, one embodiment of the present invention can also be applied to a light-emitting device in which three or more light-emitting units are stacked. With a plurality of light-emitting units partitioned by the intermediate layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as a whole.

The organic compound layer 103, the first light-emitting unit 501, the second light-emitting unit 502, the layers such as the intermediate layer 513, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

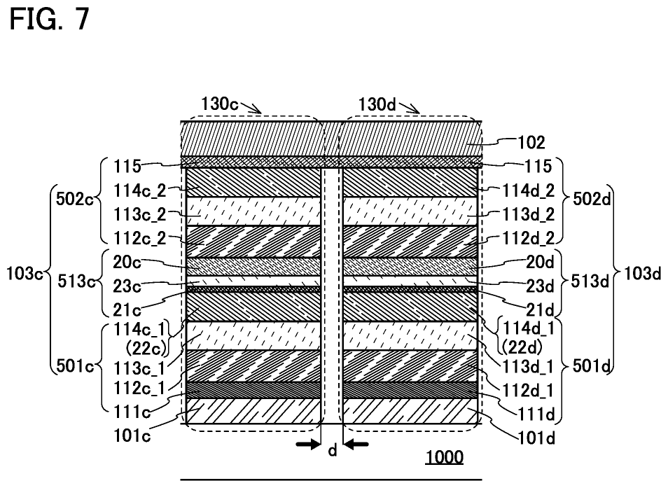

FIG. 7 illustrates two adjacent tandem light-emitting elements (a light-emitting device 130c and a light-emitting device 130d) fabricated by a photolithography technique.

The light-emitting device 130c includes an organic compound layer 103c between an anode 101c over the substrate 1000 and the cathode 102. The organic compound layer 103c has a structure in which a first light-emitting unit 501c and a second light-emitting unit 502c are stacked with an intermediate layer 513c therebetween. Although FIG. 7 illustrates an example in which the two light-emitting units are stacked, three or more light-emitting units may be stacked. The first light-emitting unit 501c includes a hole-injection layer 111c, a hole-transport layer 112c_1, a light-emitting layer 113c_1, and an electron-transport layer 114c_1 (a second layer 22c). The intermediate layer 513c includes a P-type CGL 20c, a third layer 23c, and a first layer 21c. The third layer 23c is not necessarily provided. The second light-emitting unit 502c includes a hole-transport layer 112c_2, a light-emitting layer 113c_2, an electron-transport layer 114c_2, and the electron-injection layer 115.

The light-emitting device 130d includes an organic compound layer 103d between an anode 101d over the substrate 1000 and the cathode 102. The organic compound layer 103d has a structure in which a first light-emitting unit 501d and a second light-emitting unit 502d are stacked with an intermediate layer 513d therebetween. Although FIG. 7 illustrates an example in which the two light-emitting units are stacked, three or more light-emitting units may be stacked. The first light-emitting unit 501d includes a hole-injection layer 111d, a hole-transport layer 112d_1, a light-emitting layer 113d_1, and an electron-transport layer 114d_1 (a second layer 22d). The intermediate layer 513d includes a P-type CGL 20d, a third layer 23d, and a first layer 21d. The third layer 23d is not necessarily provided. The second light-emitting unit 502d includes a hole-transport layer 112d_2, a light-emitting layer 113d_2, an electron-transport layer 114d_2, and the electron-injection layer 115.

In the light-emitting devices 130c and 130d, the intermediate layers 513c and 513d and the second layers 22c and 22d preferably have the structures described in Embodiment 1.

Note that each of the electron-injection layer 115 and the cathode 102 is preferably one continuous layer shared by the light-emitting device 130c and the light-emitting device 130d. The layers other than the electron-injection layer 115 included in the organic compound layer 103c are independent from the layers other than the electron-injection layer 115 included in the organic compound layer 103d because processing by a photolithography technique is performed after the electron-transport layer 114c_2 is formed and after the electron-transport layer 114d_2 is formed. End portions (contours) of the layers other than the electron-injection layer 115 in the organic compound layer 103c are processed by a photolithography technique and thus are substantially aligned in the direction perpendicular to the substrate. End portions (contours) of the layers other than the electron-injection layer 115 in the organic compound layer 103d are processed by a photolithography technique and thus are substantially aligned with each other in the direction perpendicular to the substrate.

The space d is present between the organic compound layer 103c and the organic compound layer 103d because of processing by a photolithography technique. Since the organic compound layers are processed by a photolithography technique, the distance between the anode 101c and the anode 101d can be made small, greater than or equal to 2 μm and less than or equal to 5 μm, compared with the case where mask vapor deposition is performed.

### Embodiment 4

Described in this embodiment is a mode in which the light-emitting device of one embodiment of the present invention is used as a display element of a display device.

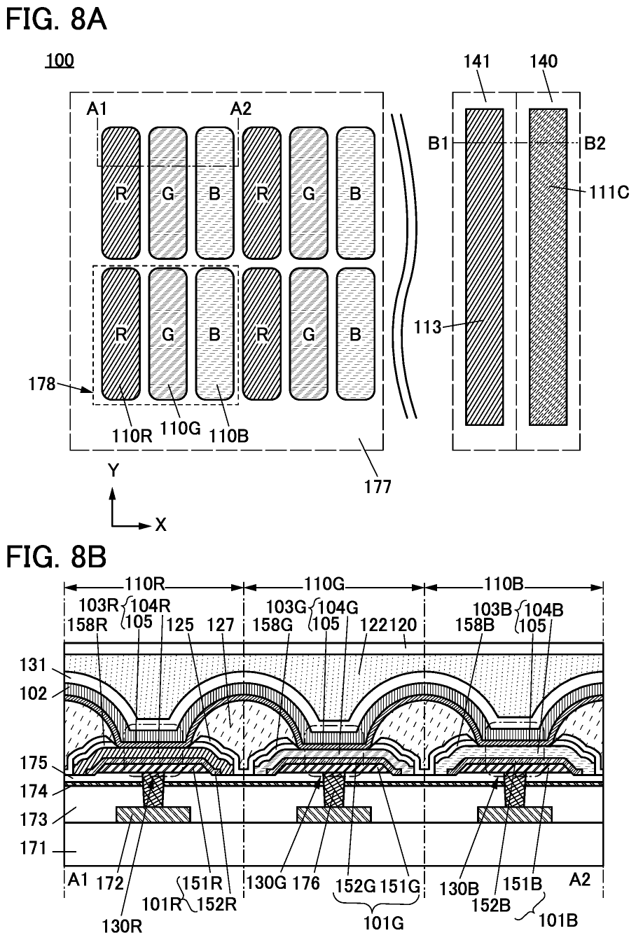

As exemplified in FIGS. 8A and 8B, a plurality of light-emitting devices 130 are formed over an insulating layer 175 to constitute a display device.

A display device includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 8A illustrates an example in which subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a region 141 is provided and a connection portion 140 may also be provided. The region 141 is provided between the pixel portion 177 and the connection portion 140. The organic compound layer 103 is provided in the region 141. A conductive layer 151C is provided in the connection portion 140.

Although FIG. 8A illustrates an example in which the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 8B is an example of a cross-sectional view along the dashed-dotted line A1-A2 in FIG. 8A. As illustrated in FIG. 8B, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 8B shows cross sections of a plurality of the inorganic insulating layers 125 and a plurality of the insulating layers 127, the inorganic insulating layers 125 are preferably connected to each other and the insulating layers 127 are preferably connected to each other when the display device is seen from above. In other words, the inorganic insulating layer 125 and the insulating layer 127 each preferably have an opening over a first electrode.

In FIG. 8B, a light-emitting device 130R, a light-emitting device 130G, and a light-emitting device 130B are shown as the light-emitting devices 130. The light-emitting devices 130R, 130G, and 130B emit light of the respective colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R has a structure as described in Embodiments 1 to 3. The light-emitting device 130R includes an anode 101R (pixel electrode) including a conductive layer 151R and a conductive layer 152R, a first EL layer 104R over the anode 101R, a second EL layer 105 over the first EL layer 104R, and the cathode 102 (common electrode) over the second EL layer 105. The second EL layer 105 is preferably positioned closer to the cathode 102 (common electrode) side than the light-emitting layer closest to the cathode side is, and is preferably a hole-block layer, a second electron-transport layer, an electron-injection layer, or stacked layers thereof. Note that in the light-emitting device 130R, a layer in which the first EL layer 104R and the second EL layer 105 are combined serves as an organic compound layer 103R, which corresponds to the organic compound layer 103 in Embodiments 1 to 3.

The light-emitting device 130G has a structure as described in Embodiments 1 to 3. The light-emitting device 130G includes an anode 101G (pixel electrode) including a conductive layer 151G and a conductive layer 152G, a first EL layer 104G over the anode 101G, the second EL layer 105 over the first EL layer 104G, and the cathode 102 (common electrode) over the second EL layer 105. The second EL layer 105 is preferably positioned closer to the cathode 102 (common electrode) side than the light-emitting layer closest to the cathode side is, and is preferably a hole-block layer, a second electron-transport layer, an electron-injection layer, or stacked layers thereof. Note that in the light-emitting device 130G, a layer in which the first EL layer 104G and the second EL layer 105 are combined serves as an organic compound layer 103G, which corresponds to the organic compound layer 103 in Embodiments 1 to 3.

The light-emitting device 130B has a structure as described in Embodiments 1 to 3. The light-emitting device 130B includes an anode 101B (pixel electrode) including a conductive layer 151B and a conductive layer 152B, a first EL layer 104B over the anode 101B, the second EL layer 105 over the first EL layer 104B, and the cathode 102 (common electrode) over the second EL layer 105. The second EL layer 105 is preferably positioned closer to the cathode 102 (common electrode) side than the light-emitting layer closest to the cathode side is, and is preferably a hole-block layer, a second electron-transport layer, an electron-injection layer, or stacked layers thereof. Note that in the light-emitting device 130B, a layer in which the first EL layer 104B and the second EL layer 105 are combined serves as an organic compound layer 103B, which corresponds to the organic compound layer 103 in Embodiments 1 to 3.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified.

The first EL layers 104R, 104G, and 104B are island-shaped layers that are independent of each other for the respective colors. It is preferable that the first EL layers 104R, 104G, and 104B not overlap with one another. Providing the island-shaped first EL layer 104 in each of the light-emitting devices 130 can suppress leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped first EL layer 104 is formed by forming an EL film and processing the EL film by a photolithography technique. The light-emitting device of one embodiment of the present invention includes no Li compound or the like in the intermediate layer, and thus can have favorable characteristics even when processing is performed by a photolithography technique.

The first EL layer 104 is preferably provided to cover the top surface and the side surface of the anode 101 (pixel electrode) of the light-emitting device 130. In this case, the aperture ratio of the display device can be easily increased as compared to the structure where an end portion of the first EL layer 104 is positioned inward from an end portion of the pixel electrode. Covering the side surface of the pixel electrode of the light-emitting device 130 with the first EL layer 104 can inhibit the pixel electrode from being in contact with the cathode 102; hence, a short circuit of the light-emitting device 130 can be inhibited.

In the display device of one embodiment of the present invention, the anode 101 (pixel electrode) of the light-emitting device preferably has a stacked-layer structure. For example, in the example illustrated in FIG. 8B, the anode 101 of the light-emitting device 130 is a stack of the conductive layer 151 on the insulating layer 171 side and the conductive layer 152 on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers including different materials. In that case, the conductive layer 151 may include a layer formed using a material that can be used for the conductive layer 152, such as a conductive oxide, and the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The conductive layer 151 preferably has a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the first EL layer 104 provided along the side surface of the conductive layer 152 can be improved.

Since the light-emitting device 130 has the structure as described in Embodiments 1 to 3, the display device of one embodiment of the present invention can be a display device having favorable characteristics in which an increase in the driving voltage is inhibited.

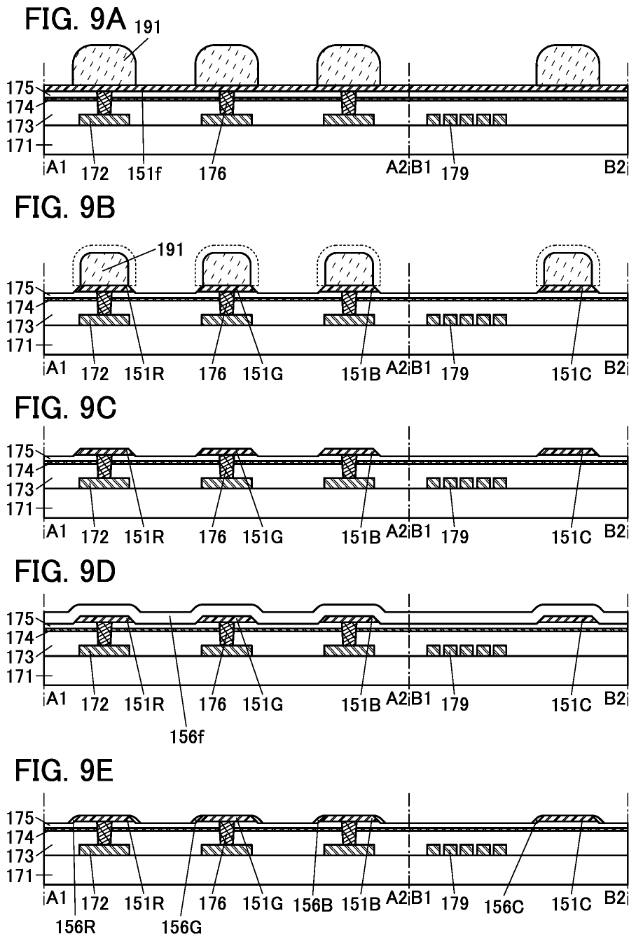

Next, an example of a method for manufacturing the display device having the structure illustrated in FIG. 8A is described with reference to FIGS. 9A to 9E, FIGS. 10A to 10D, FIGS. 11A to 11D, FIGS. 12A to 12C, FIGS. 13A to 13C, and FIGS. 14A to 14C.

### Manufacturing Method Example 1

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography technique, for example.

As light used for exposure in the photolithography technique, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used.

For etching of thin films, a dry etching method, a wet etching method, a sandblast method, or the like can be used.

First, as illustrated in FIG. 9A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 9A, openings reaching the conductive layer 172 are formed in the insulating layers 175, 174, and 173. Then, the plugs 176 are formed to fill the openings.

Next, as illustrated in FIG. 9A, a conductive film 151f to be the conductive layers 151R, 151G, 151B, and 151C is formed over the plugs 176 and the insulating layer 175. A metal material can be used for the conductive film 151f, for example.

Then, a resist mask 191 is formed over the conductive film 151f as illustrated in FIG. 9A. The resist mask 191 can be formed by application of a photosensitive material (photoresist), light exposure, and development.

Subsequently, as illustrated in FIG. 9B, the conductive film 151f in a region not overlapping with the resist mask 191 is removed, for example. In this manner, the conductive layer 151 is formed.

Next, the resist mask 191 is removed as illustrated in FIG. 9C. The resist mask 191 can be removed by ashing using oxygen plasma, for example.

Then, as illustrated in FIG. 9D, an insulating film 156f to be an insulating layer 156R, an insulating layer 156G, an insulating layer 156B, and an insulating layer 156C is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 9E, the insulating film 156f is processed to form the insulating layers 156R, 156G, 156B, and 156C.

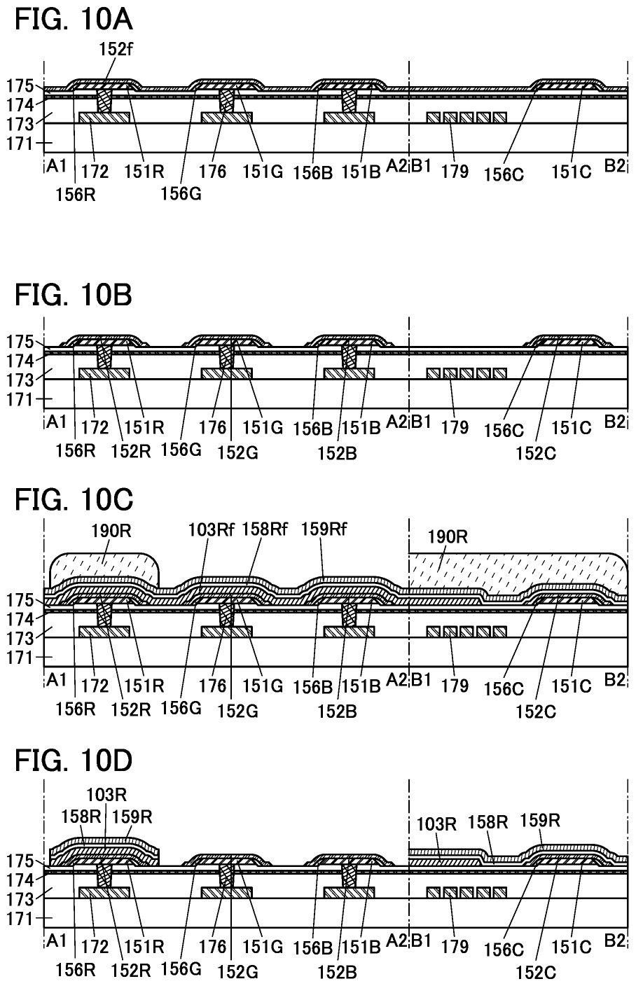

Next, as illustrated in FIG. 10A, a conductive film 152f is formed over the conductive layers 151R, 151G, 151B, and 151C and the insulating layers 156R, 156G, 156B, 156C, and 175.

A conductive oxide can be used for the conductive film 152f, for example. The conductive film 152f may have a stacked-layer structure.

Then, as illustrated in FIG. 10B, the conductive film 152f is processed, so that the conductive layers 152R, 152G, 152B, and 152C are formed.

Next, as illustrated in FIG. 10C, an organic compound film 103Rf is formed over the conductive layers 152R, 152G, and 152B and the insulating layer 175. As illustrated in FIG. 10C, the organic compound film 103Rf is not formed over the conductive layer 152C.

Then, as illustrated in FIG. 10C, a sacrificial film 158Rf and a mask film 159Rf are formed.

Providing the sacrificial film 158Rf over the organic compound film 103Rf can reduce damage to the organic compound film 103Rf in the manufacturing process of the display device, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., and further preferably higher than or equal to 100° C. and lower than or equal to 120° C.

The sacrificial film 158Rf and the mask film 159Rf are preferably films that can be removed by a wet etching method or a dry etching method.

Note that the sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in patterning light exposure, and deterioration of the organic compound film 103Rf can be suppressed.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 10C. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device.

Next, as illustrated in FIG. 10D, part of the mask film 159Rf is removed using the resist mask 190R, so that a mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an alkaline aqueous solution such as a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be suppressed by not using a gas containing oxygen as the etching gas.

The resist mask 190R can be removed by a method similar to that for the resist mask 191.

Next, as illustrated in FIG. 10D, the organic compound film 103Rf is processed to form the organic compound layer 103R. For example, part of the organic compound film 103Rf is removed using the mask layer 159R and the sacrificial layer 158R as a hard mask, whereby the organic compound layer 103R is formed.

Accordingly, as illustrated in FIG. 10D, the stacked-layer structure of the organic compound layer 103R, the sacrificial layer 158R, and the mask layer 159R remains over the conductive layer 152R. The conductive layers 152G and 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be suppressed by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

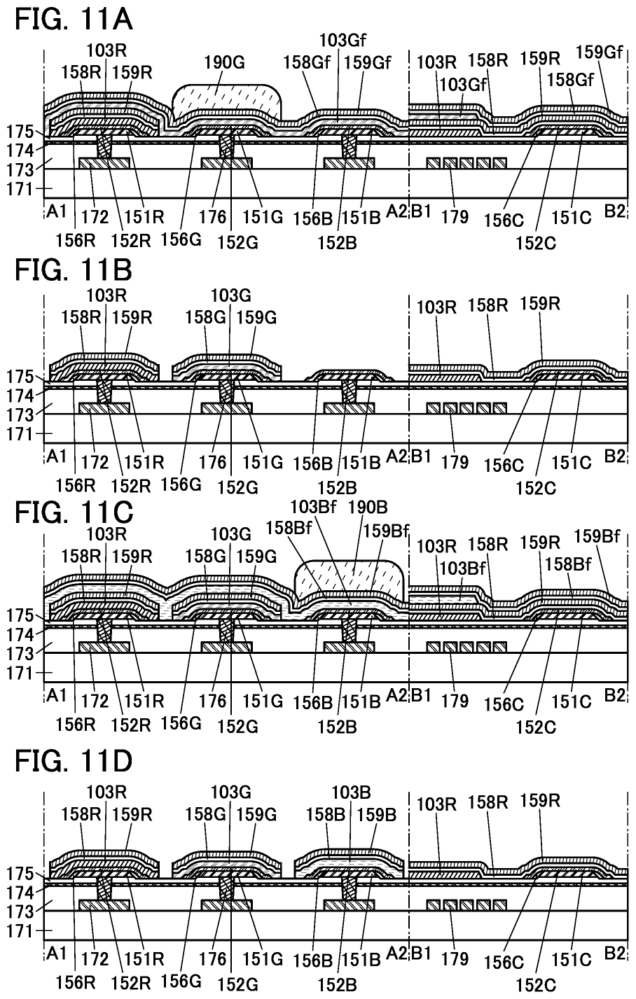

Then, as illustrated in FIG. 11A, an organic compound film 103Gf to be the organic compound layer 103G is formed.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 11A, a sacrificial film 158Gf and a mask film 159Gf are formed in this order. After that, a resist mask 190G is formed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 11B, part of the mask film 159Gf is removed using the resist mask 190G, so that a mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the organic compound film 103Gf is processed to form the organic compound layer 103G. Accordingly, as illustrated in FIG. 11B, the stacked-layer structure of the organic compound layer 103G, the sacrificial layer 158G, and the mask layer 159G remains over the conductive layer 152G. The mask layer 159R and the conductive layer 152B are exposed.

Then, an organic compound film 103Bf is formed as illustrated in FIG. 11C.

The organic compound film 103Bf can be formed by a method similar to that for forming the organic compound film 103Rf. The organic compound film 103Bf can have a structure similar to that of the organic compound film 103Rf.

Subsequently, as illustrated in FIG. 11C, a sacrificial film 158Bf and a mask film 159Bf are formed in this order. After that, a resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 11D, part of the mask film 159Bf is removed using the resist mask 190B, so that a mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask, whereby the organic compound layer 103B is formed.

Accordingly, the stacked-layer structure of the organic compound layer 103B, the sacrificial layer 158B, and the mask layer 159B remains over the conductive layer 152B as illustrated in FIG. 11D. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 600 and less than or equal to 90°.

The distance between two adjacent layers among the organic compound layers 103R, 103G, and 103B, which are formed by a photolithography technique as described above, can be reduced to less than or equal to 8 μm, less than or equal to 5 μm, less than or equal to 3 μm, less than or equal to 2 μm, or less than or equal to 1 μm. Here, the distance can be specified, for example, by the distance between opposite end portions of two adjacent layers among the organic compound layers 103R, 103G, and 103B. Reducing the distance between the island-shaped organic compound layers makes it possible to provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

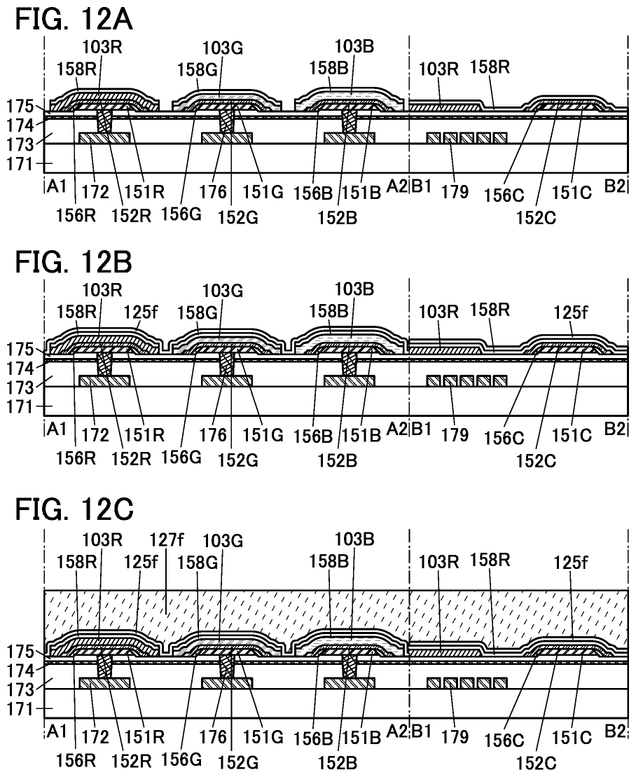

Next, the mask layers 159R, 159G, and 159B are preferably removed as illustrated in FIG. 12A.

The step of removing the mask layers can be performed by a method similar to that for the step of processing the mask layers. Specifically, by using a wet etching method, damage caused to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 12B.

Then, as illustrated in FIG. 12C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness of 3 nm or more, 5 nm or more, or 10 nm or more and 200 nm or less, 150 nm or less, 100 nm or less, or 50 nm or less is preferably formed at a substrate temperature in the above-described range.

The inorganic insulating film 125f is preferably formed by an ALD method, for example. An ALD method is preferably used, in which case deposition damage is reduced and a film with good coverage can be formed. As the inorganic insulating film 125f, an aluminum oxide film is preferably formed by an ALD method, for example.

The insulating film 127f is preferably formed by the aforementioned wet process. For example, the insulating film 127f is preferably formed by spin coating using a photosensitive material, and specifically preferably formed using a photosensitive resin composition containing an acrylic resin.

Then, part of the insulating film 127f is exposed to visible light or ultraviolet rays. The insulating layer 127 is formed in regions that are sandwiched between any two of the conductive layers 152R, 152G, and 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

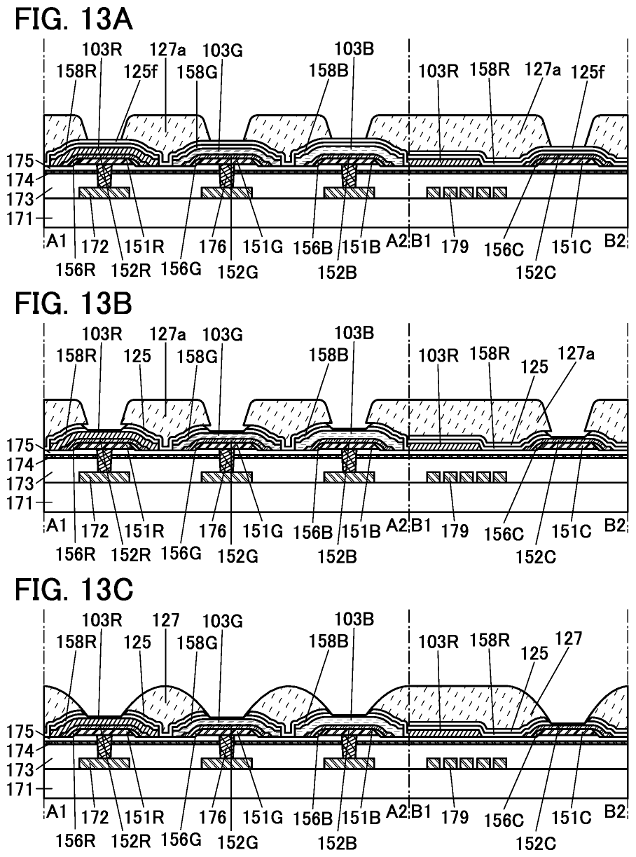

Next, the region of the insulating film 127f exposed to light is removed by development as illustrated in FIG. 13A, so that an insulating layer 127a is formed.

Next, as illustrated in FIG. 13B, etching treatment is performed with the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the organic compound layers 103R, 103G, and 103B, as compared to the case of using a dry etching method. Wet etching can be performed using an alkaline solution, for example. For instance, a TMAH aqueous solution, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that of the sacrificial layers 158R, 158G, and 158B, in which case the above etching treatment can be performed concurrently.

The sacrificial layers 158R, 158G, and 158B are not completely removed by the first etching treatment, and the etching treatment is stopped when the thickness of the sacrificial layers 158R, 158G, and 158B is reduced. The corresponding sacrificial layers 158R, 158G, and 158B remain over the organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen into the organic compound layers 103R, 103G, and 103B can be suppressed.

Then, heat treatment (also referred to as post-baking) is performed. The heat treatment can change the insulating layer 127a into the insulating layer 127 having a tapered side surface (FIG. 13C). The heat treatment is conducted at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting device.

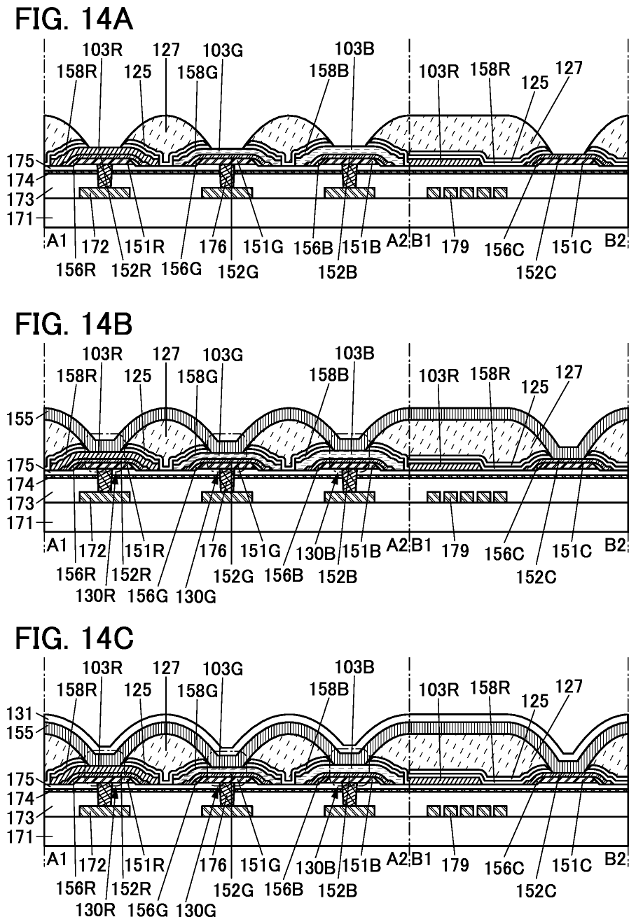

Next, as illustrated in FIG. 14A, etching treatment is performed with the insulating layer 127 as a mask to remove part of the sacrificial layers 158R, 158G, and 158B. Thus, openings are formed in the sacrificial layers 158R, 158G, and 158B, and the top surfaces of the organic compound layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 14A illustrates an example in which part of an end portion of the sacrificial layer 158G (specifically, a tapered portion formed by the first etching treatment) is covered with the insulating layer 127 and a tapered portion formed by the second etching treatment is exposed.

The second etching treatment is performed by wet etching. The use of a wet etching method can reduce damage to the organic compound layers 103R, 103G, and 103B, as compared to the case of using a dry etching method. Wet etching can be performed using an alkaline solution or an acidic solution, for example. An aqueous solution is preferably used in order that the organic compound layer 103 is not dissolved.

Next, as illustrated in FIG. 14B, a common electrode 155 is formed over the organic compound layers 103R, 103G, and 103B, the conductive layer 152C, and the insulating layer 127. The common electrode 155 can be formed by a sputtering method, a vacuum evaporation method, or the like. In this case, a stacked layer structure of the first EL layer 104 and the second EL layer 105 may be employed as the organic compound layer 103 as illustrated in FIG. 8B, and the common electrode 155 may be formed thereover.

Next, as illustrated in FIG. 14C, the protective layer 131 is formed over the common electrode 155. The protective layer 131 can be formed by a vacuum evaporation method, a sputtering method, a CVD method, an ALD method, or the like.

Then, the substrate 120 is bonded over the protective layer 131 using the resin layer 122, so that the display device can be manufactured. In the method for manufacturing the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for manufacturing the display device in one embodiment of the present invention, the island-shaped organic compound layers 103R, 103G, and 103B are formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices formed by a photolithography technique can have favorable characteristics.

### Embodiment 5

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

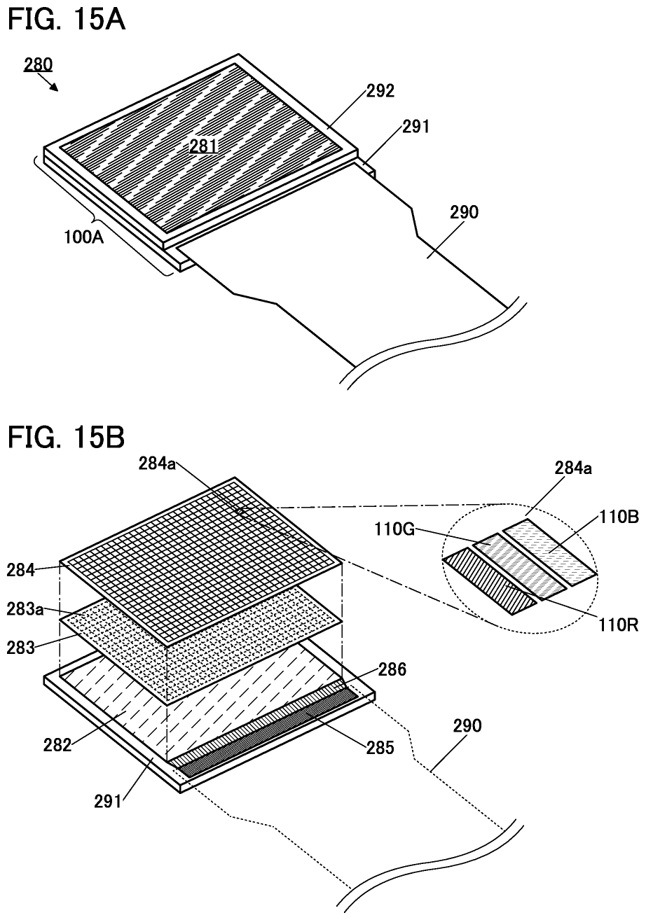

FIG. 15A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 15B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 15B. The pixels 284a can employ any of the structures described in the above embodiments. FIG. 15B illustrates an example in which the pixel 284a has a structure similar to that of the pixel 178 illustrated in FIGS. 8A and 8B.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An integrated circuit (IC) may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

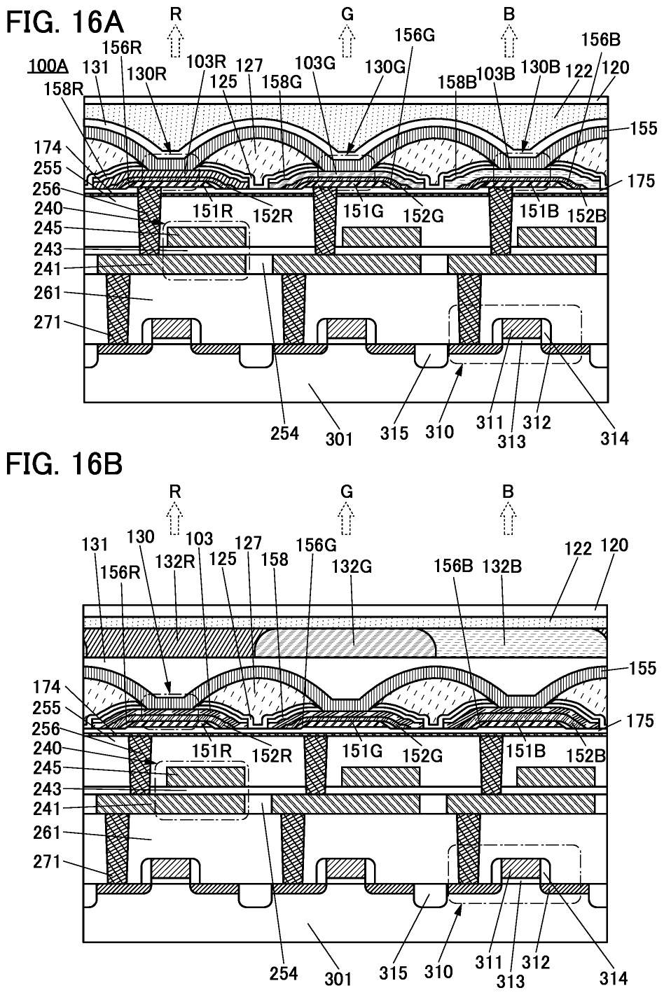

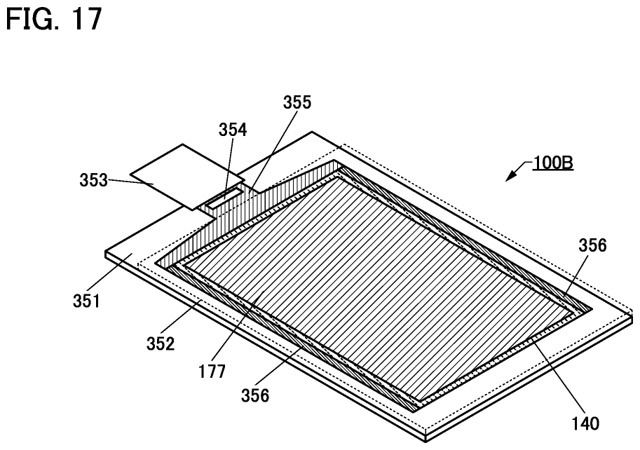

The display device 100A illustrated in FIG. 16A includes a substrate 301, the light-emitting devices 130R, 130G, and 130B, a capacitor 240, and a transistor 310.

The substrate 301 corresponds to the substrate 291 in FIGS. 15A and 15B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 4 can be referred to for the details of the light-emitting device 130 and the components thereover up to the substrate 120. The substrate 120 corresponds to the substrate 292 in FIG. 15A.

FIG. 16B illustrates a variation example of the display device 100A illustrated in FIG. 16A. The display device illustrated in FIG. 16B includes the coloring layers 132R, 132G, and 132B, and each of the light-emitting devices 130 includes a region overlapping with one of the coloring layers 132R, 132G, and 132B. In the display device illustrated in FIG. 16B, the light-emitting device 130 can emit white light, for example. The coloring layer 132R, the coloring layer 132G, and the coloring layer 132B can transmit red light, green light, and blue light, respectively, for example.

### [Display Device 100B]

FIG. 17 is a perspective view of the display device 100B.

In the display device 100B, a substrate 352 and a substrate 351 are bonded to each other. In FIG. 17, the substrate 352 is denoted by a dashed line.

The display device 100B includes the pixel portion 177, the connection portion 140, a circuit 356, a wiring 355, and the like. FIG. 17 illustrates an example in which an IC 354 and an FPC 353 are mounted on the display device 100B. Thus, the structure illustrated in FIG. 17 can be regarded as a display module including the display device 100B, the IC, and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and electric power to the pixel portion 177 and the circuit 356. The signal and electric power are input to the wiring 355 from the outside through the FPC 353 or from the IC 354.

FIG. 17 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

### [Display Device 100C]

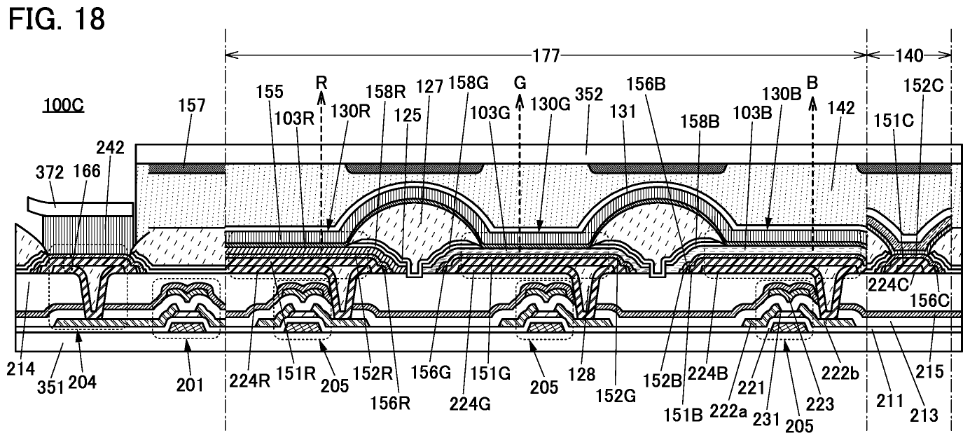

FIG. 18 illustrates an example of cross sections of part of a region including an FPC 372, part of the pixel portion 177, part of the connection portion 140, and part of a region including an end portion of a display device 100C.

The display device 100C illustrated in FIG. 18 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 to Embodiment 4 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering the opening provided in the insulating layer 214. A layer 128 is embedded in the depression portion.

The layer 128 has a function of filling the depression portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-block layer 157. A solid sealing structure, a hollow sealing structure, or the like can be employed to seal the light-emitting device 130. In FIG. 18, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-like adhesive layer 142.

FIG. 18 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 18, the insulating layer 156C is provided to include a region overlapping with the side surface of the conductive layer 151C.

The display device 100B has a top-emission structure. Light from the light-emitting device is emitted toward the substrate 352. For the substrate 352, a material having a high visible-light-transmitting property is preferably used. In the case where the light-emitting element emits infrared or near-infrared light, a material having a high transmitting property with respect to infrared or near-infrared light is preferably used. The pixel electrode includes a material that reflects visible light, and the counter electrode (the common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable for the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the source electrode or the drain electrode of the transistor 201 is electrically connected to the FPC 372 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

A light-block layer 157 is preferably provided on the surface of the substrate 352 on the substrate 351 side. The light-block layer 157 can be provided over a region between adjacent light-emitting devices, in the connection portion 140, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

[Display device 100D]

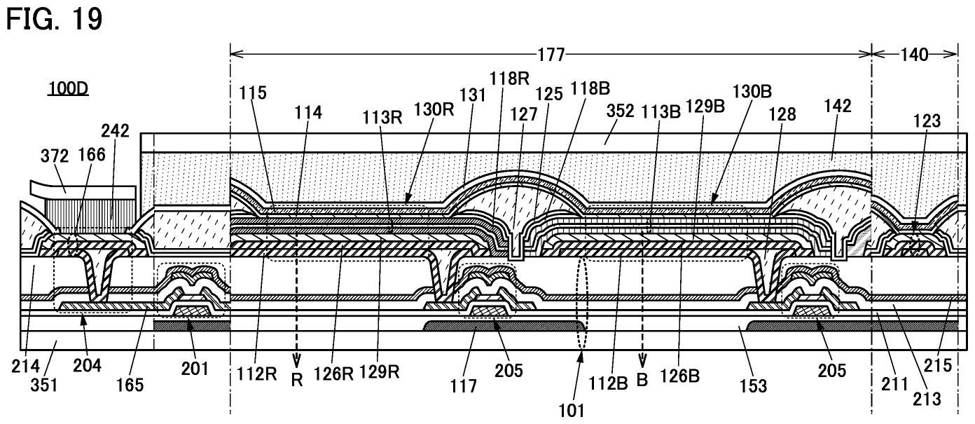

The display device 100D in FIG. 19 differs from the display device 100C in FIG. 18 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

The light-block layer is preferably formed between the substrate 351 and the transistor 201 and between the substrate 351 and the transistor 205. FIG. 19 illustrates an example in which a light-block layer 117 is provided over the substrate 351, an insulating layer 153 is provided over the light-block layer 117, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although not illustrated in FIG. 19, the light-emitting device 130G is also provided.

Although FIG. 19 and the like illustrate an example in which the top surface of the layer 128 includes a flat portion, the shape of the layer 128 is not particularly limited.

[Display device 100E]

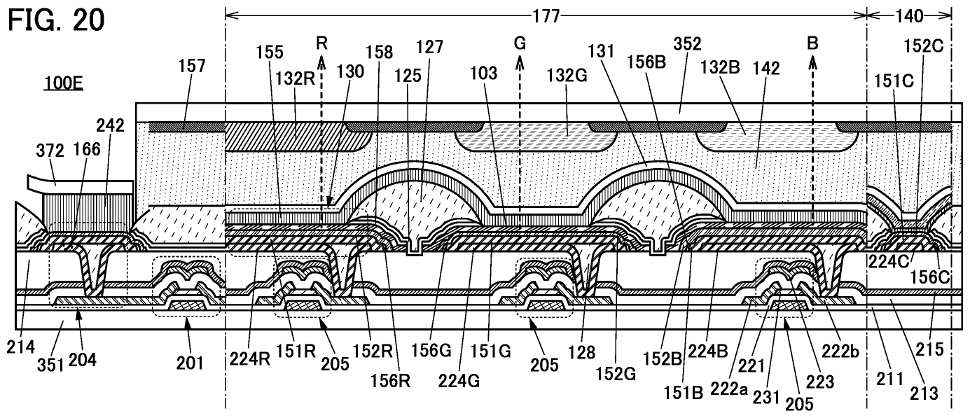

The display device 100E illustrated in FIG. 20 is a variation example of the display device 100C illustrated in FIG. 18 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-block layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

Although FIG. 18, FIG. 20, and the like each illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances of this embodiment include the display device of one embodiment of the present invention in their display portions. The display device of one embodiment of the present invention has high display performance and can be easily increased in resolution and definition. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention can have high resolution, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

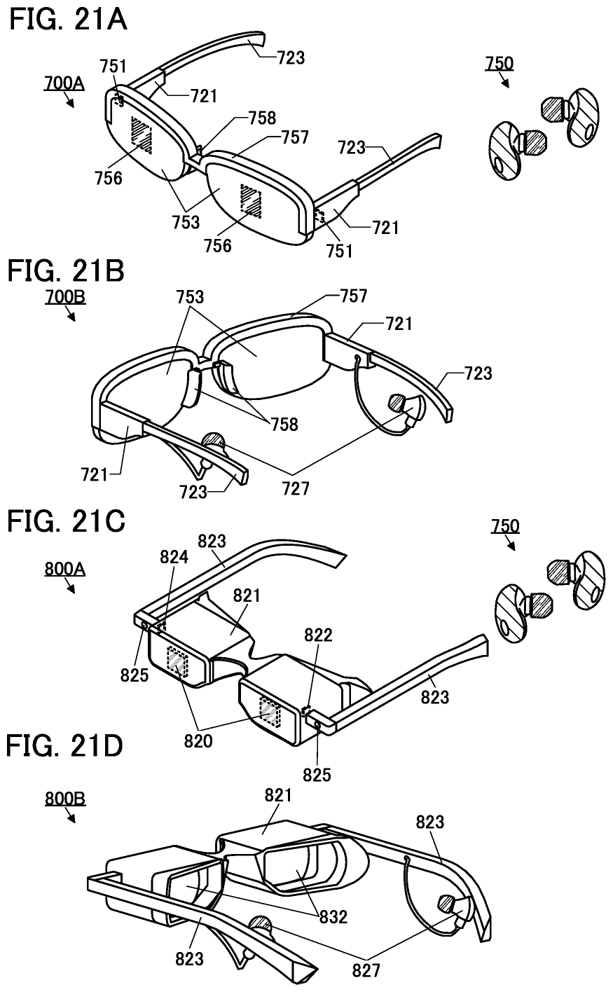

Examples of head-mounted wearable devices are described with reference to FIGS. 21A to 21D.

An electronic appliance 700A illustrated in FIG. 21A and an electronic appliance 700B illustrated in FIG. 21B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 21C and an electronic appliance 800B illustrated in FIG. 21D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, electric power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B in FIG. 21B includes earphone portions 727. Part of a wiring that connects the earphone portion 727 and the control portion may be positioned inside the housing 721 or the wearing portion 723.

Similarly, the electronic appliance 800B in FIG. 21D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

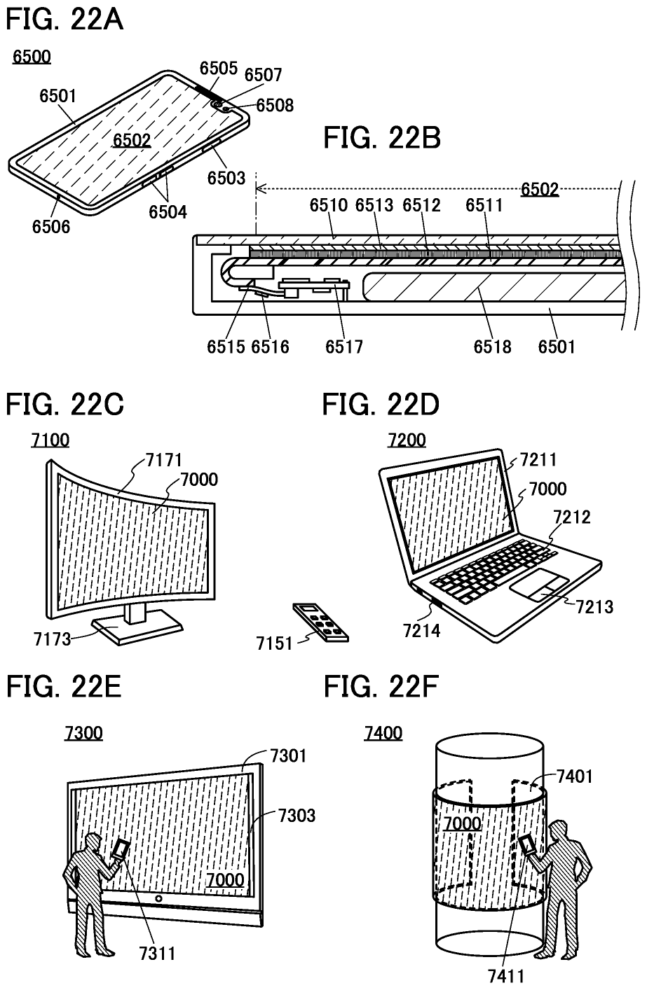

An electronic appliance 6500 illustrated in FIG. 22A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic appliance is obtained.

FIG. 22B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be obtained when part of the display panel 6511 is folded back so that the portion connected to the FPC 6515 is provided on the back side of a pixel portion.

FIG. 22C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic appliance is obtained.

Operation of the television device 7100 illustrated in FIG. 22C can be performed with an operation switch provided in the housing 7171 and a separate remote controller 7151.

FIG. 22D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic appliance is obtained.

FIGS. 22E and 22F illustrate examples of digital signage.

Digital signage 7300 illustrated in FIG. 22E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 22F shows digital signage 7400 attached to a cylindrical pillar 7401. The digital signage 7400 includes the display portion 7000 provided along a curved surface of the pillar 7401.

In FIGS. 22E and 22F, the display device of one embodiment of the present invention can be used in the display portion 7000. Thus, a highly reliable electronic appliance is obtained.

A larger area of the display portion 7000 can increase the amount of information that can be provided at a time. The display portion 7000 having a larger area attracts more attention, so that the effectiveness of the advertisement can be increased, for example.

As illustrated in FIGS. 22E and 22F, it is preferable that the digital signage 7300 or the digital signage 7400 can work with an information terminal 7311 or an information terminal 7411, such as a smartphone that a user has, through wireless communication.

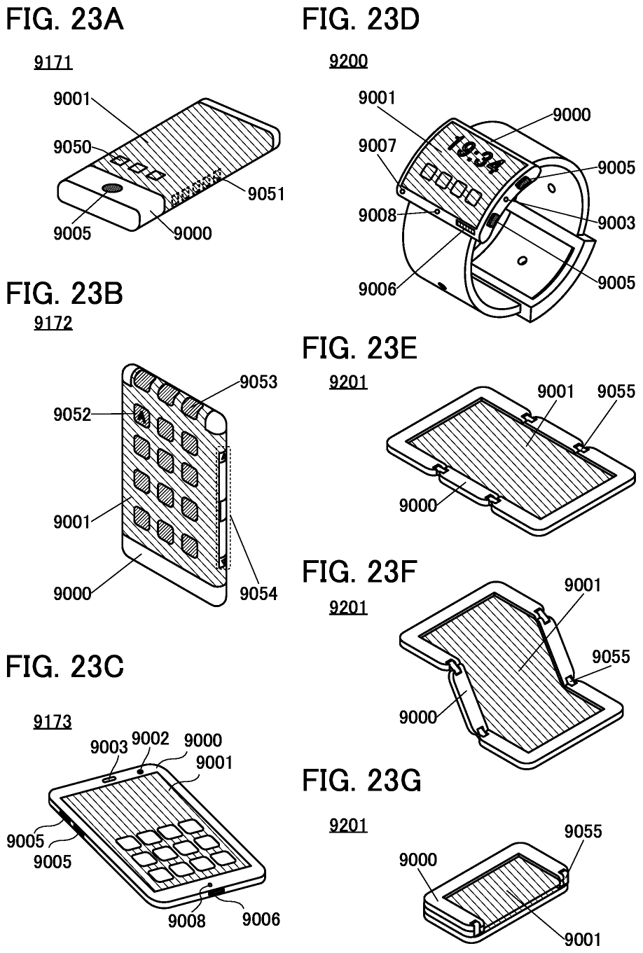

Electronic appliances illustrated in FIGS. 23A to 23G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 23A to 23G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic appliances in FIGS. 23A to 23G are described in detail below.

FIG. 23A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 23A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 23B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed such that it can be seen from above the portable information terminal 9172, with the portable information terminal 9172 put in a breast pocket of his/her clothes.

FIG. 23C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 23D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 23E to 23G are perspective views of a foldable portable information terminal 9201. FIG. 23E is a perspective view showing the portable information terminal 9201 that is opened. FIG. 23G is a perspective view showing the portable information terminal 9201 that is folded. FIG. 23F is a perspective view showing the portable information terminal 9201 that is shifted from one of the states in FIGS. 23E and 23G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Described in this example are a specific method for fabricating a light-emitting device 1 of one embodiment of the present invention, and characteristics of the light-emitting device. Structural formulae of main compounds used in this example are shown below.

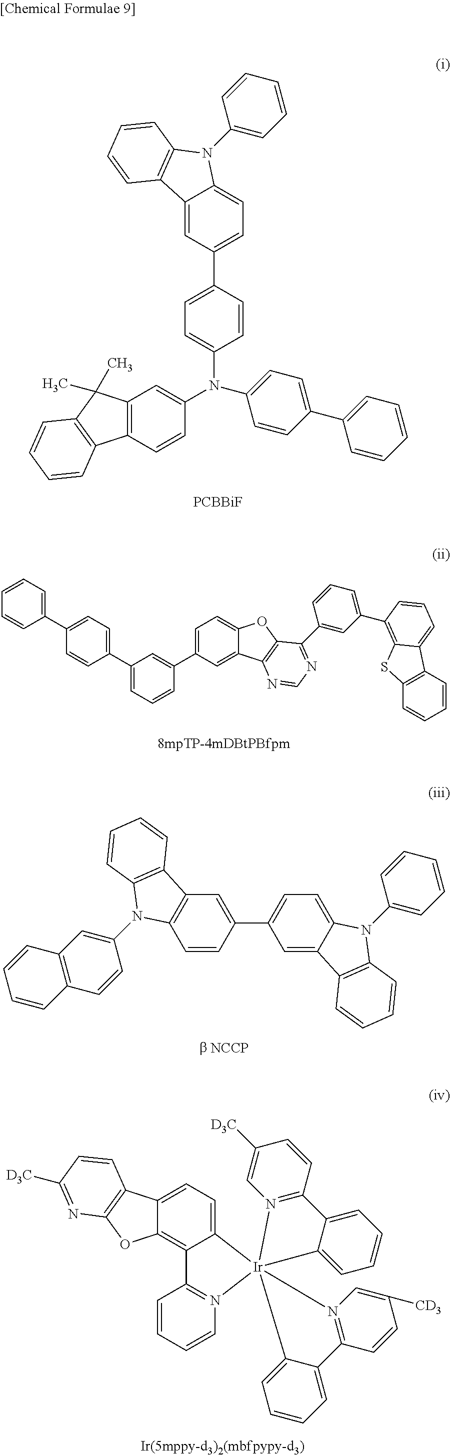

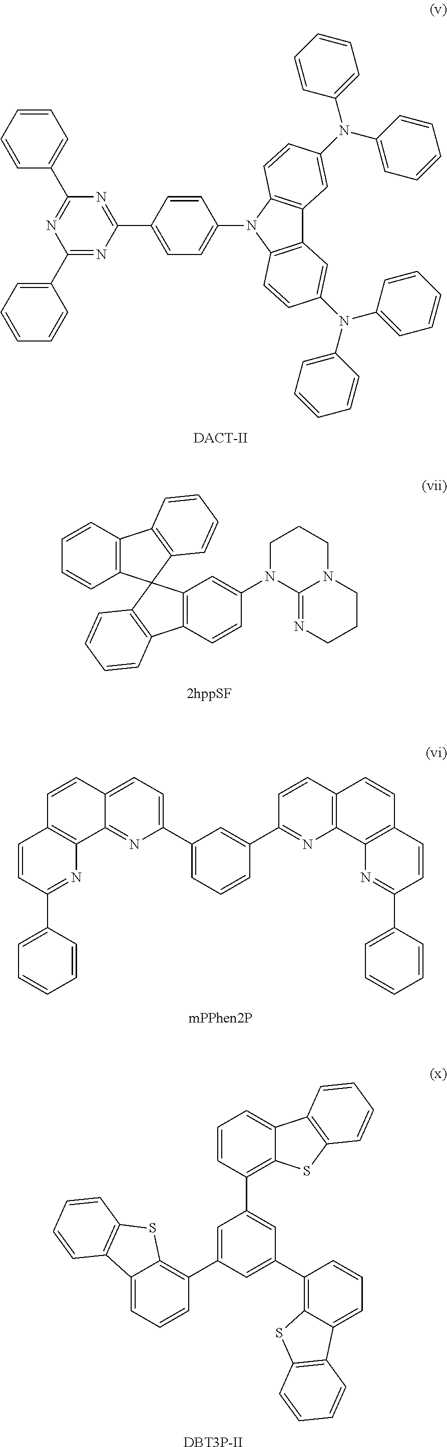 [SMILES: c1ccc(-c2nc(-c3ccccc3)nc(-c3ccc(-n4c5ccc(N(c6ccccc6)c6ccccc6)cc5c5cc(N(c6ccccc6)c6ccccc6)ccc54)cc3)n2)cc1 ; "DACT-II" ; c1ccc2c(c1)-c1ccccc1C21c2ccccc2-c2ccc(N3CCCN4CCCN=C43)cc21 ; c1ccc(-c2ccc3ccc4ccc(-c5cccc(-c6ccc7ccc8ccc(-c9ccccc9)nc8c7n6)c5)nc4c3n2)cc1 ; c1ccc2c(c1)sc1c(-c3cc(-c4cccc5c4sc4ccccc45)cc(-c4cccc5c4sc4ccccc45)c3)cccc12 ; "DBT3P-II"]

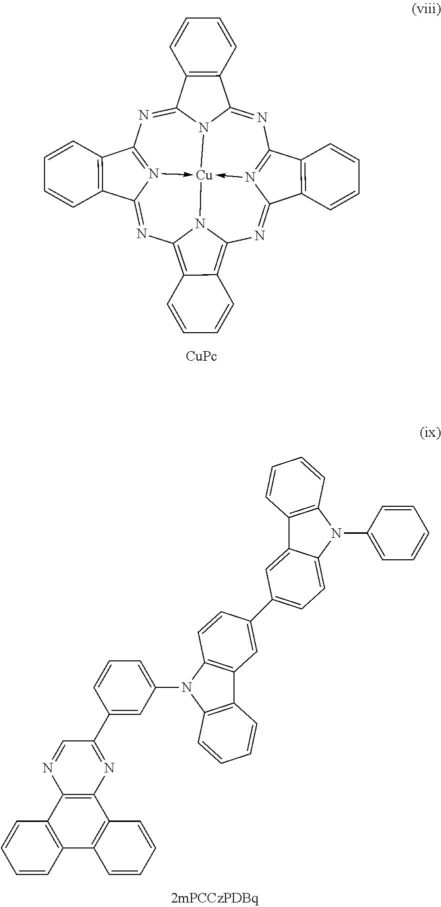

### (Method for Fabricating Light-Emitting Device 1)

First, a 100-nm-thick alloy of silver, palladium, and copper (APC: Ag—Pd—Cu) and 100-nm-thick indium tin oxide containing silicon oxide (JTSO) were stacked sequentially from the substrate side by a sputtering method as a reflective electrode and a transparent electrode, respectively, over a glass substrate. This stacked-layer film was patterned by a photolithography technique, whereby the anode 101 was formed. Note that the transparent electrode functions as an anode, and the transparent electrode and the reflective electrode are collectively also referred to as the first electrode.

Next, in pretreatment for forming the light-emitting device over a substrate, the surface of the substrate was washed with water, baking was performed at 200° C. for one hour, and then UV ozone treatment was performed for 370 seconds.

After that, the substrate was transferred into a vacuum evaporation apparatus where the pressure was reduced to approximately 1×10⁻⁴ Pa, and was subjected to vacuum baking at 170° C. for 60 minutes in a heating chamber of the vacuum evaporation apparatus, and then the substrate was cooled down for approximately 30 minutes.

Then, the substrate was fixed to a substrate holder provided in the vacuum evaporation apparatus such that the surface on which the anode 101 was formed faced downward. Over the inorganic insulating film and the anode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 60 nm, whereby a first hole-transport layer was formed.

Then, over the first hole-transport layer, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-9H,9′H-3,3′-bicarbazole (abbreviation: βNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm to βNCCP and Ir(5mppy-d₃)₂(mbfpypy-d₃) was 0.5:0.5:0.1, whereby a first light-emitting layer was formed.

Next, 3,6-bis(diphenylamino)-9-[4-(4,6-diphenyl-1,3,5-triazin-2-yl)phenyl]-9H-carbazole (abbreviation: DACT-II) represented by Structural Formula (v) above was deposited by evaporation to a thickness of 10 nm to form a first electron-transport layer.

After the first electron-transport layer was formed, 2,2′-(1,3-phenylene)bis(9-phenyl-1,10-phenanthroline) (abbreviation: mPPhen2P) represented by Structural Formula (vi) above and 1-(9,9′-spirobi[9H-fluoren]-2-yl)-1,3,4,6,7,8-hexahydro-2H-pyrimido[1,2-a]pyrimidine (abbreviation: 2hppSF) represented by Structural Formula (vii) above were deposited by co-evaporation to a thickness of 5 nm such that the weight ratio of mPPhen2P to 2hppSF was 1:1, copper phthalocyanine (abbreviation: CuPc) represented by Structural Formula (viii) above was deposited by evaporation to a thickness of 2 nm, and PCBBiF and OCHD-003 were deposited by co-evaporation to a thickness of 10 nm such that the weight ratio of PCBBiF to OCHD-003 was 1:0.15. Thus, an intermediate layer was formed.

Over the intermediate layer, PCBBiF was deposited by evaporation to a thickness of 55 nm, whereby a second hole-transport layer was formed.

Over the second hole-transport layer, 8mpTP-4mDBtPBfpm, βNCCP, and Ir(5mppy-d₃)₂(mbfpypy-d₃) were deposited by co-evaporation to a thickness of 40 nm such that the weight ratio of 8mpTP-4mDBtPBfpm to βNCCP and Ir(5mppy-d₃)₂(mbfpypy-d₃) was 0.5:0.5:0.1, whereby a second light-emitting layer was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (ix) above was deposited by evaporation to a thickness of 20 nm and mPPhen2P was further deposited by evaporation to a thickness of 20 nm, whereby a second electron-transport layer was formed.

Then, processing by a photolithography technique was performed. The sample was taken out from the vacuum evaporation apparatus and exposed to the atmosphere, and then aluminum oxide was deposited to a thickness of 30 nm by an ALD method using trimethylaluminum (abbreviation: TMA) as a precursor and water vapor as an oxidizer, whereby a first sacrificial layer was formed.

Over the first sacrificial layer, a composite oxide containing indium, gallium, zinc, and oxygen (IGZO) was deposited to a thickness of 50 nm by a sputtering method, whereby a second sacrificial layer was formed.

A photoresist was formed over the second sacrificial layer, and the second sacrificial layer was processed by a lithography technique so that a slit having a width of 3 μm was formed in a position 3.5 μm away from the anode 101.

Specifically, the second sacrificial layer was processed using the resist as a mask and using an etching gas containing CF₄, O₂, and He, and then the resist was removed using a solution containing tetramethylammonium hydroxide (abbreviation: TMAH).

Next, the first sacrificial layer was processed using the second sacrificial layer as a hard mask and an etching gas containing fluoroform (CHF₃) and helium (He) at a flow rate ratio of CHF₃:He=1:9. Then, the second electron-transport layer, the second light-emitting layer, the second hole-transport layer, the intermediate layer, the first electron-transport layer, the first light-emitting layer, the first hole-transport layer, and the hole-injection layer were processed using an etching gas containing oxygen (O₂).

After the processing, the second sacrificial layer was removed using an etching gas containing CF₄, O₂, and He, and then the first sacrificial layer was removed using a basic chemical solution, so that the second electron-transport layer was exposed.

The sample with the exposed second electron-transport layer was transferred into a vacuum evaporation apparatus where the pressure was reduced to approximately 1×10⁻⁴ Pa, and vacuum baking was performed at 110° C. for one hour in a heating chamber of the vacuum evaporation apparatus. Then, the sample was cooled down for approximately 30 minutes.

Next, lithium fluoride and ytterbium were deposited by evaporation to a thickness of 1.5 nm at a weight ratio of LiF:Yb=2:1, whereby the electron-injection layer 115 was formed. Then, silver (Ag) and magnesium (Mg) were deposited by co-evaporation to a thickness of 15 nm at a volume ratio of Ag:Mg=1:0.1, whereby the cathode 102 (the second electrode) was formed. Over the cathode 102, 4,4′,4″-(benzene-1,3,5-triyl)tri(dibenzothiophene) (abbreviation: DBT3P-II) represented by Structural Formula (x) above was deposited to a thickness of 70 nm as a cap layer to improve light extraction efficiency.

Then, the light-emitting device was sealed using a glass substrate in a glove box containing a nitrogen atmosphere so as not to be exposed to the atmosphere. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 1 was fabricated. The structure of the light-emitting device 1 is shown in the following table.

TABLE 4

| | thickness | |
|---|---|---|
| | (nm) | light-emitting device 1 |
| cap layer | 70 | DBT3P-II |
| second electrode | 15 | Ag:Mg (1:0.1) |
| | 1.5 | LiF:Yb (2:1) |

MML process

| second | | 2 | 20 | mPPhen2P |
|---|---|---|---|---|
| electron-transport layer | | 1 | 20 | 2mPCCzPDBq |
| second light-emitting layer | | | 40 | 8mpTP-4mDBtPBfpm:βNCCP:Ir(5mppy-d₃)₂(mbfpypy-d₃) |
| | | | | (0.5:0.5:0.1) |
| second hole-transport layer | | | 55 | PCBBiF |
| intermediate | P-type CGL | | 10 | PCBBiF:OCHD-003 |
| layer | | | | (1:0.15) |

| | | |
|---|---|---|
| electron-relay layer | 2 | CuPc |
| first layer | 5 | mPPhen2P:2hppSF |

| | | | (5:5) |
|---|---|---|---|
| first electron-transport layer | | 10 | DACT-II |
| (second layer) | | | |
| first light-emitting layer | | 40 | 8mpTP-4mDBtPBfpm:βNCCP:Ir(5mppy-d₃)₂(mbfpypy-d₃) |
| | | | (0.5:0.5:0.1) |
| first hole-transport layer | | 60 | PCBBiF |
| hole-injection layer | | 10 | PCBBiF:OCHD-003 |
| | | | (1:0.03) |
| first | transparent electrode | 100 | ITSO |
| electrode | reflective electrode | 100 | APC |

As listed above, in the light-emitting device 1, the organic compound used in the first electron-transport layer has a HOMO level greater than or equal to −5.9 eV and less than or equal to −5.0 eV. The first layer of mPPhen2P:2hppSF=1:1 formed in the intermediate layer is a film blocking holes. Furthermore, 2hppSF has an acid dissociation constant pKₐ of 13.95 and is a strongly basic organic compound with a pKₐof 8 or more. In addition, mPPhen2P, which is an electron-transport material with a LUMO level greater than or equal to −3.0 eV and less than or equal to −2.0 eV, is used in the first layer.

Here, an electron spin resonance spectrum of a thin film of mPPhen2P and 2hppSF that was deposited by co-evaporation to a thickness of 50 nm over a quartz substrate such that the weight ratio of mPPhen2P to 2hppSF was 1:1 was measured, revealing that no signal was observed at a g-factor of approximately 2.00 and the spin density was lower than 8×10¹⁶ spins/cm³, which is the measurement limit. Note that the measurement of the electron spin resonance spectrum using ESR spectroscopy was performed with an electron spin resonance spectrometer E500 (manufactured by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. This means that 2hppSF does not exhibit an electron-donating property with respect to mPPhen2P.

The P-type CGL is a layer including PCBBiF, which is a hole-transport organic compound, and OCHD-003 exhibiting an electron-acceptor property and is a charge-generation layer in which charge separation occurs by voltage application.

Here, an electron spin resonance spectrum of a thin film of PCBBiF and OCHD-003 that was deposited by co-evaporation to a thickness of 100 nm over a quartz substrate such that the weight ratio of PCBBiF to OCHD-003 was 1:0.1 was measured at room temperature, revealing that a signal was observed at a g-factor of approximately 2.00 and the spin density was 5×10¹⁹ spins/cm³. This means that OCHD-003 exhibits an electron-accepting property with respect to PCBBiF and the layer including PCBBiF and OCHD-003 has a function of a charge-generation layer.

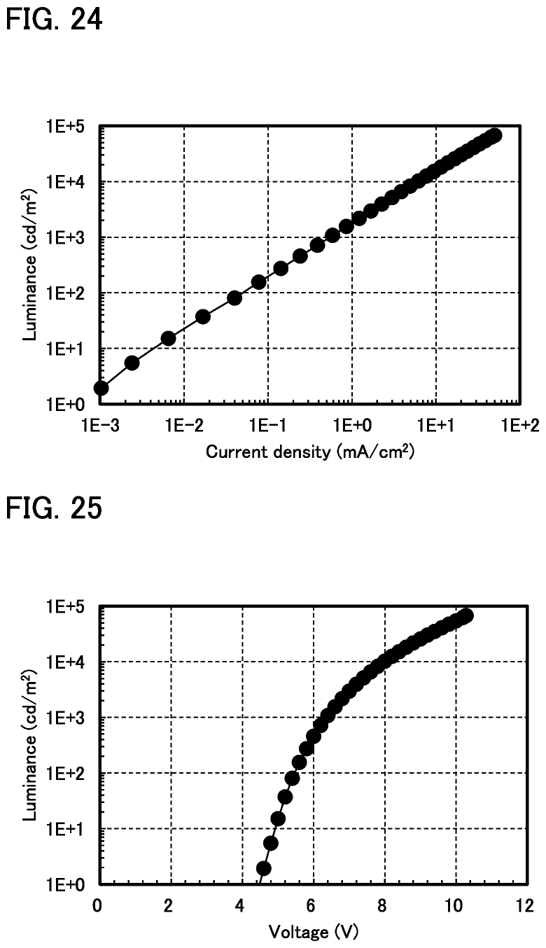

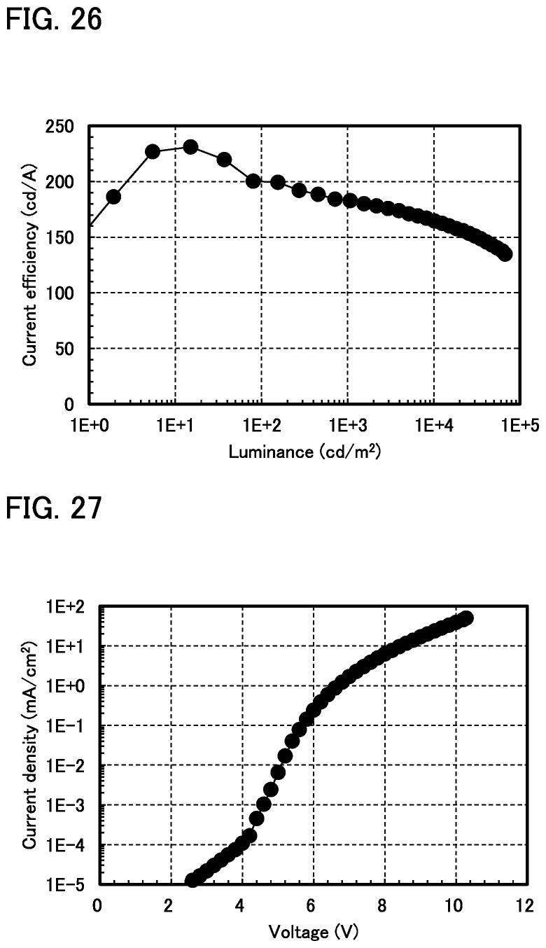

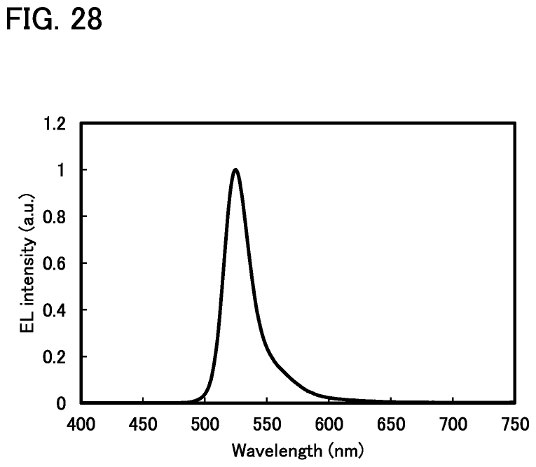

FIG. 24 shows luminance-current density characteristics of the light-emitting device 1. FIG. 25 shows luminance-voltage characteristics thereof. FIG. 26 shows current efficiency-luminance characteristics thereof. FIG. 27 shows current density-voltage characteristics thereof. FIG. 28 shows an electroluminescence spectrum thereof. Table 5 shows main characteristics at approximately 1000 cd/m². The luminance, CIE chromaticity, and electroluminescence spectrum were measured at normal temperature with a spectroradiometer (SR-UL1R manufactured by TOPCON TECHNOHOUSE CORPORATION).

TABLE 5

| | voltage | current | current density | chromaticity | chromaticity | current efficiency |
|---|---|---|---|---|---|---|
| | (V) | (mA) | (mA/cm²) | x | y | (cd/A) |
| light-emitting device 1 | 6.4 | 0.02 | 0.6 | 0.22 | 0.73 | 182.9 |

FIG. 28 (spectrum) shows that the light-emitting device 1 exhibits green light emission derived from Ir(5mppy-d₃)₂(mbfpypy-d₃). Furthermore, the large value in FIG. 26 (current efficiency) indicates that the light-emitting device 1 functions as a tandem light-emitting device.

FIG. 25 (luminance-voltage characteristics) revealed that the driving voltages of the light-emitting device 1 that is a tandem light-emitting device fabricated through a photolithography process are equivalent to those of a light-emitting device fabricated in a continuous vacuum process.

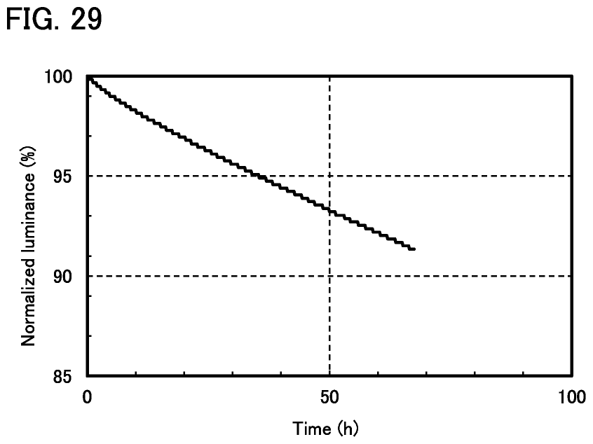

FIG. 29 shows the change in luminance of the light-emitting device 1 over driving time in constant-current driving at a current density of 50 mA/cm². It was found from FIG. 29 that the light-emitting device 1 has high reliability.

Thus, the use of the structure of the present invention can provide a light-emitting device having favorable characteristics such as high emission efficiency and low driving voltage.

Next, the results of calculating GSP_slope of the first layer are described. A measurement device having a structure in the following table was fabricated and GSP_slope of its first layer was calculated. Note that the thicknesses in Table 4 and the thicknesses of an anode, a hole-injection layer, an electron-injection layer, and a cathode in the following table are represented as design values. Meanwhile, the thicknesses of an electron-transport layer 1 and an electron-transport layer 2 in the following table are represented as values obtained using a spectroscopic ellipsometer (M-2000U, produced by J.A. Woollam Japan Corp.) because accurate values are required for measurement of GSP_slope.

TABLE 6

| | thickness | |
|---|---|---|
| | (nm) | material |
| cathode | 100 | Al |
| | 1 | LiF |
| electron-injection layer | 1 | Pyrrd-Phen |
| electron-transport layer 2 | 96.86 | 2hppSF:mPPhen2P |
| | | (20.4:79.6) |
| electron-transport layer 1 | 69.76 | Alq₃ |
| hole-injection layer | 10 | PCBBiF:p-dopant |
| | | (1:0.15) |
| anode | 70 | NITO |

The structural formulae of main organic compounds used in the measurement device are shown below.

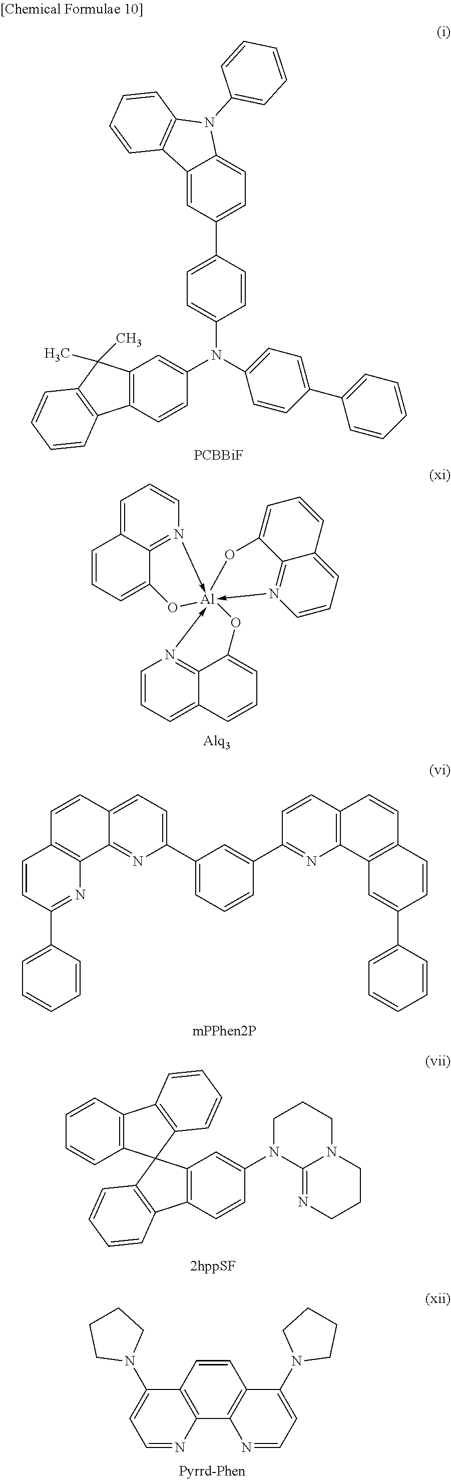

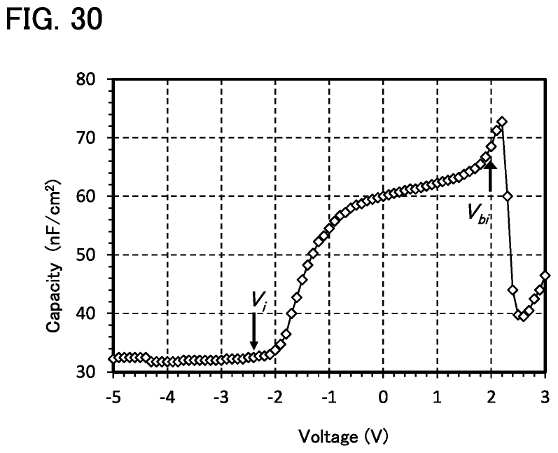

The measurement device was formed under the conditions where the substrate temperature was set to room temperature and the deposition rate was within the range from 0.2 nm/see to 0.4 nm/sec. One layer was formed without interruption of evaporation. In the measurement device, the electron-transport layer 1 corresponds to the thin film 1, the electron-transport layer 2 corresponds to the thin film 2, and the electron-transport layer 2 includes the same material as the first layer of the light-emitting device 1. FIG. 30 shows the capacity-voltage characteristics of the measurement device. Note that GSP_slope of Alq₃ is known (48 (mV/nm)).

Table 7 shows the ordinary refractive index nₒ of the electron-transport layer 2, the electron-injection voltage Vᵢ and the threshold voltage V_{bi} of the measurement device obtained from FIG. 30, and the interface charge density σ_{if_e} and GSP_slope respectively obtained from Formula (1) and Formula (2) in Embodiment 1.

TABLE 7

| | |
|---|---|
| electron-injection voltage Vᵢ | −2.60 |
| (V) | |
| threshold voltage V_{bi} | 2.00 |
| (V) | |
| interface charge density σ_{if}_{_{—}}ₑ | −1.71 |
| (mC/m²) | |
| ordinary refractive index nₒ | 1.79 |
| (@633 nm) | |
| GSP_slope | −16.3 |
| (mV/nm) | |

As described above, the first layer used in the intermediate layer of the light-emitting device 1 was found to have negative GSP_slope. Thus, the light-emitting device 1 of one embodiment of the present invention was found to be able to have favorable characteristics in which an increase in driving voltage is suppressed even when fabricated through a photolithography process.

### Example 2

Described in this example are a specific method for fabricating a light-emitting device 2 of one embodiment of the present invention, and characteristics of the light-emitting device. Structural formulae of main compounds used in this example are shown below.

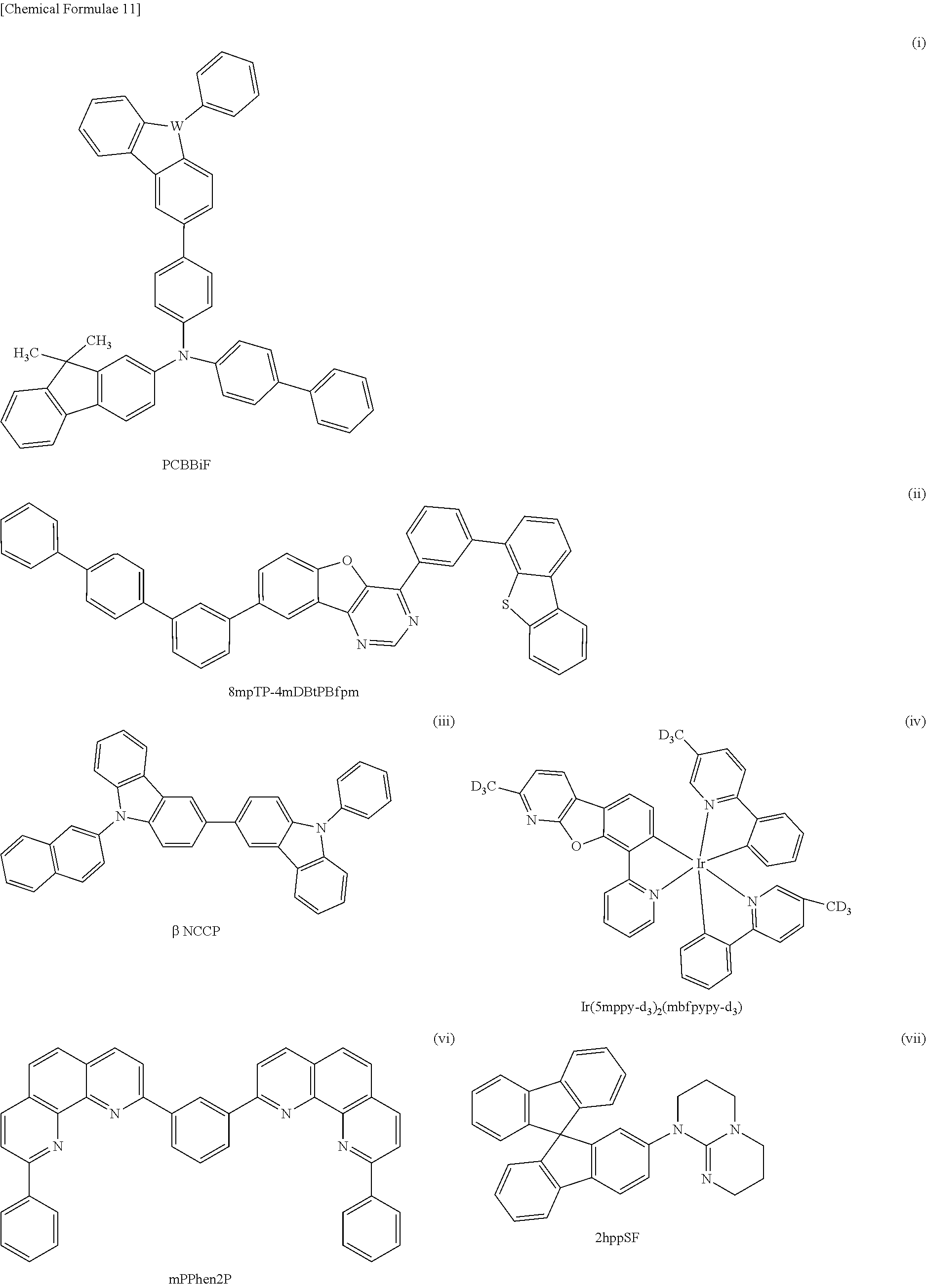

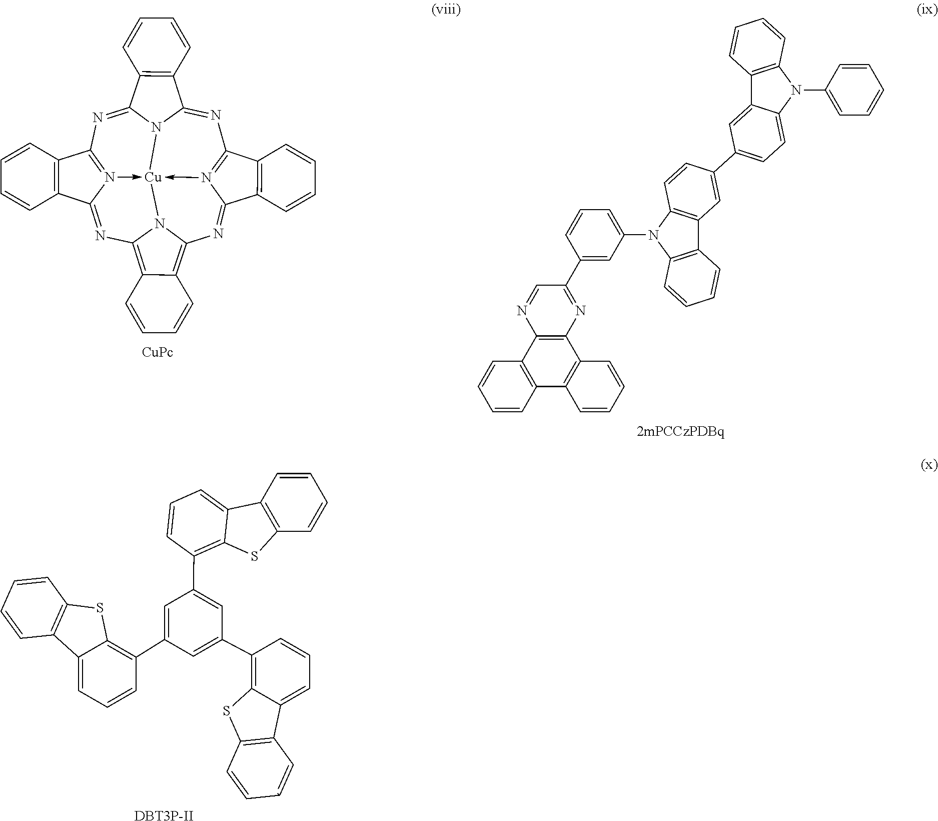

### (Method for Fabricating Light-Emitting Device 2)

First, 100-nm-thick silver and 10-nm-thick indium tin oxide containing silicon oxide (ITSO) were stacked sequentially from the substrate side by a sputtering method as a reflective electrode and a transparent electrode, respectively, over a glass substrate. This stacked-layer film was patterned by a photolithography technique, whereby the anode 101 was formed. Note that the transparent electrode functions as an anode, and the transparent electrode and the reflective electrode are collectively also referred to as the first electrode.

Next, in pretreatment for forming the light-emitting device over a substrate, the surface of the substrate was washed with water, and baking was performed at 200° C. for one hour.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface on which the anode 101 was formed faced downward. Over the inorganic insulating film and the anode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 20 nm, whereby a first hole-transport layer was formed.

Then, over the first hole-transport layer, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-9H,9′H-3,3′-bicarbazole (abbreviation: βNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm to βNCCP and Ir(5mppy-d₃)₂(mbfpypy-d₃) was 0.5:0.5:0.1, whereby a first light-emitting layer was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (ix) above was deposited by evaporation to a thickness of 10 nm to form a first electron-transport layer.

After the first electron-transport layer was formed, 2,2′-(1,3-phenylene)bis(9-phenyl-1,10-phenanthroline) (abbreviation: mPPhen2P) represented by Structural Formula (vi) above and 1-(9,9′-spirobi[9H-fluoren]-2-yl)-1,3,4,6,7,8-hexahydro-2H-pyrimido[1,2-a]pyrimidine (abbreviation: 2hppSF) represented by Structural Formula (vii) above were deposited by co-evaporation to a thickness of 5 nm such that the weight ratio of mPPhen2P to 2hppSF was 1:1, copper phthalocyanine (abbreviation: CuPc) represented by Structural Formula (viii) above was deposited by evaporation to a thickness of 2 nm, and PCBBiF and OCHD-003 were deposited by co-evaporation to a thickness of 10 nm such that the weight ratio of PCBBiF to OCHD-003 was 1:0.15. Thus, an intermediate layer was formed.

Over the intermediate layer, PCBBiF was deposited by evaporation to a thickness of 65 nm, whereby a second hole-transport layer was formed.

Over the second hole-transport layer, 8mpTP-4mDBtPBfpm, βNCCP, and Ir(5mppy-d₃)₂(mbfpypy-d₃) were deposited by co-evaporation to a thickness of 40 nm such that the weight ratio of 8mpTP-4mDBtPBfpm to βNCCP and Ir(5mppy-d₃)₂(mbfpypy-d₃) was 0.5:0.5:0.1, whereby a second light-emitting layer was formed.

Next, 2mPCCzPDBq was deposited by evaporation to a thickness of 20 nm and mPPhen2P was further deposited by evaporation to a thickness of 20 nm, whereby a second electron-transport layer was formed.

Next, lithium fluoride and ytterbium were deposited by evaporation to a thickness of 1.5 nm at a weight ratio of LiF:Yb=2:1, whereby the electron-injection layer 115 was formed. Then, silver (Ag) and magnesium (Mg) were deposited by co-evaporation to a thickness of 15 nm at a volume ratio of Ag:Mg=1:0.1, whereby the cathode 102 (the second electrode) was formed. Over the cathode 102, 4,4′,4″-(benzene-1,3,5-triyl)tri(dibenzothiophene) (abbreviation: DBT3P-II) represented by Structural Formula (x) above was deposited to a thickness of 70 nm as a cap layer to improve light extraction efficiency.

Then, the light-emitting device was sealed using a glass substrate in a glove box containing a nitrogen atmosphere so as not to be exposed to the atmosphere. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 2 was fabricated. The structure of the light-emitting device 2 is shown in the following table.

TABLE 8

| | | thickness | |
|---|---|---|---|
| | | (nm) | light-emitting device 2 |
| cap layer | | 70 | DBT3P-II |
| | | 15 | Ag:Mg (1:0.1) |
| second electrode | | 1.5 | LiF:Yb (2:1) |
| second | 2 | 20 | mPPhen2P |
| electron-transport layer | 1 | 20 | 2mPCCzPDBq |

| second light-emitting layer | | 40 | 8mpTP-4mDBtPBfpm:βNCCP:Ir(5mppy-d₃)₂(mbfpypy-d₃) |
|---|---|---|---|
| | | | (0.5:0.5:0.1) |
| second hole-transport layer | | 65 | PCBBiF |
| intermediate | P-type CGL | 10 | PCBBiF:OCHD-003 |
| layer | electron-relay layer | | (1:0.15) |
| | first layer | 2 | CuPc |
| | | 5 | mPPhen2P:2hppSF |
| | | | (5:5) |
| first electron-transport layer | | 10 | 2mPCCzPDBq |
| (second layer) | | | |
| first light-emitting layer | | 40 | 8mpTP-4mDBtPBfpm:βNCCP:Ir(5mppy-d₃)₂(mbfpypy-d₃) |
| | | | (0.5:0.5:0.1) |
| first hole-transport layer | | 20 | PCBBiF |
| hole-injection layer | | 10 | PCBBiF:OCHD-003 |
| | | | (1:0.03) |
| first | transparent electrode | 10 | ITSO |
| electrode | reflective electrode | 100 | Ag |

As listed above, in the light-emitting device 2, the organic compound used in the first electron-transport layer has a HOMO level greater than or equal to −5.9 eV and less than or equal to −5.0 eV. The first layer of mPPhen2P:2hppSF=1:1 formed in the intermediate layer is a film blocking holes. Furthermore, 2hppSF has an acid dissociation constant pKₐ of 13.95 and is a strongly basic organic compound with a pKₐof 8 or more. In addition, mPPhen2P, which is an electron-transport material with a LUMO level greater than or equal to −3.0 eV and less than or equal to −2.0 eV, is used in the first layer.

Here, an electron spin resonance spectrum of a thin film of mPPhen2P and 2hppSF that was deposited by co-evaporation to a thickness of 50 nm over a quartz substrate such that the weight ratio of mPPhen2P to 2hppSF was 1:1 was measured, revealing that no signal was observed at a g-factor of approximately 2.00 and the spin density was lower than 8×10¹⁶ spins/cm³, which is the measurement limit. Note that the measurement of the electron spin resonance spectrum using ESR spectroscopy was performed with an electron spin resonance spectrometer E500 (manufactured by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. This means that 2hppSF does not exhibit an electron-donating property with respect to mPPhen2P.

The P-type CGL is a layer including PCBBiF, which is a hole-transport organic compound, and OCHD-003 exhibiting an electron-acceptor property and is a charge-generation layer in which charge separation occurs by voltage application.

Here, an electron spin resonance spectrum of a thin film of PCBBiF and OCHD-003 that was deposited by co-evaporation to a thickness of 100 nm over a quartz substrate such that the weight ratio of PCBBiF to OCHD-003 was 1:0.1 was measured at room temperature, revealing that a signal was observed at a g-factor of approximately 2.00 and the spin density was 5×10¹⁹ spins/cm³. This means that OCHD-003 exhibits an electron-accepting property with respect to PCBBiF and the layer including PCBBiF and OCHD-003 has a function of a charge-generation layer.

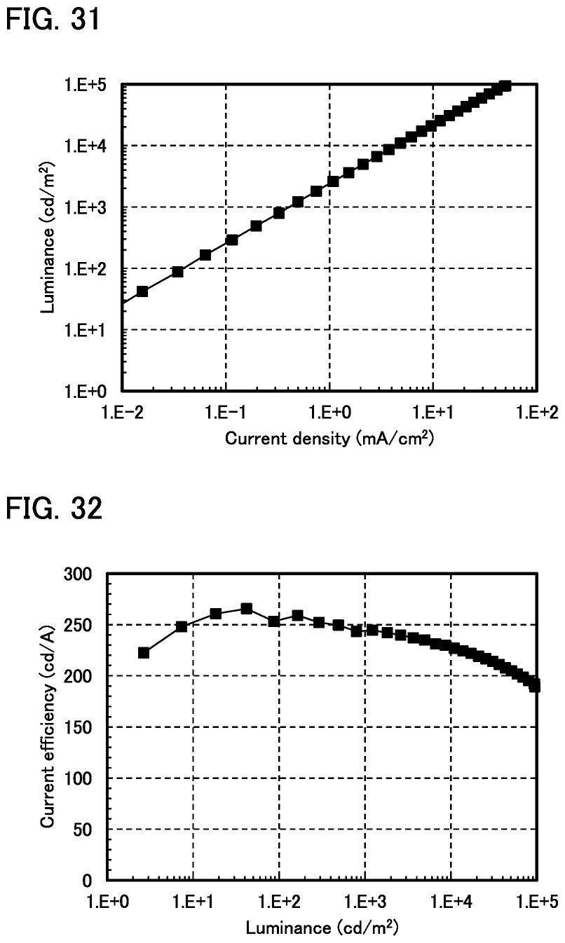

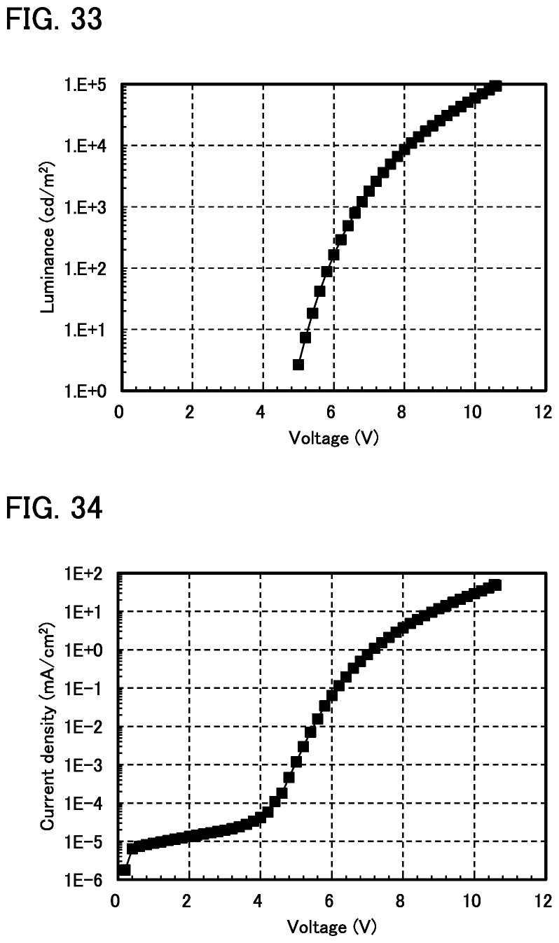

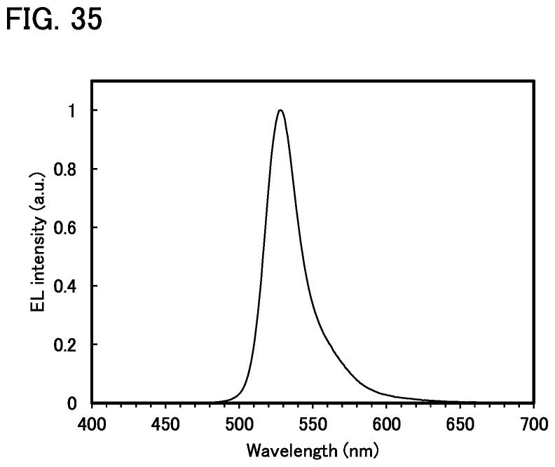

FIG. 31 shows luminance-current density characteristics of the light-emitting device 2. FIG. 32 shows current efficiency-luminance characteristics thereof. FIG. 33 shows luminance-voltage characteristics thereof. FIG. 34 shows current density-voltage characteristics thereof. FIG. 35 shows an electroluminescence spectrum thereof. Table 9 shows main characteristics at approximately 1000 cd/m². The luminance, CIE chromaticity, and electroluminescence spectrum were measured at normal temperature with a spectroradiometer (SR-UL1R manufactured by TOPCON TECHNOHOUSE CORPORATION).

TABLE 9

| | voltage | current | current density | chromaticity | chromaticity | current efficiency |
|---|---|---|---|---|---|---|
| | (V) | (mA) | (mA/cm²) | x | y | (cd/A) |
| light-emitting device 2 | 6.4 | 0.01 | 0.2 | 0.24 | 0.72 | 249.6 |

FIG. 35 (spectrum) shows that the light-emitting device 2 exhibits green light emission derived from Ir(5mppy-d₃)₂(mbfpypy-d₃). Furthermore, the large value in FIG. 32 (current efficiency) indicates that the light-emitting device 2 functions as a tandem light-emitting device.

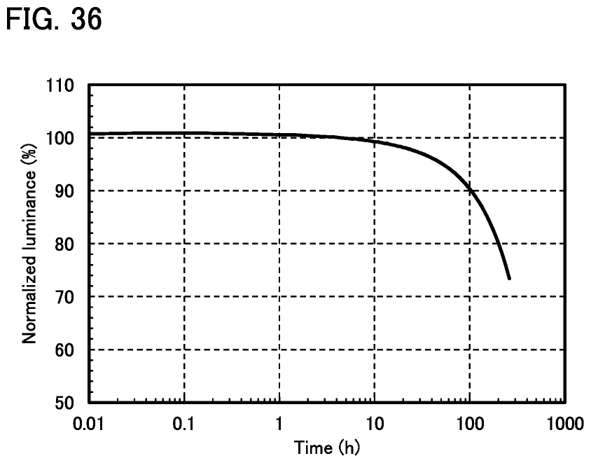

FIG. 36 shows the change in luminance of the light-emitting device 2 over driving time in constant-current driving at a current density of 50 mA/cm². It was found from FIG. 36 that the light-emitting device 2 has high reliability.

Thus, the use of the structure of the present invention can provide a light-emitting device having favorable characteristics such as a long lifetime, high emission efficiency, and low driving voltage.

Next, the results of calculating GSP_slope of the first layer are described. A measurement device having a structure in the following table was fabricated and GSP_slope of its first layer was calculated. Note that the thicknesses in Table 8 and the thicknesses of an anode, a hole-injection layer, an electron-injection layer, and a cathode in the following table (Table 10) are represented as design values. Meanwhile, the thicknesses of the electron-transport layer 1 and the electron-transport layer 2 in the following table are represented as values obtained using a spectroscopic ellipsometer (M-2000U, produced by J.A. Woollam Japan Corp.) because accurate values are required for measurement of GSP_slope.

TABLE 10

| | thickness | |
|---|---|---|
| | (nm) | material |
| cathode | 100 | Al |
| | 1 | LiF |
| electron-injection layer | 1 | Pyrrd-Phen |
| electron-transport layer 2 | 96.86 | 2hppSF:mPPhen2P |
| | | (20.4:79.6) |
| electron-transport layer 1 | 69.76 | Alq₃ |
| hole-injection layer | 10 | PCBBiF:p-dopant |
| | | (1:0.15) |
| anode | 70 | NITO |

The structural formulae of main organic compounds used in the measurement device are shown below.

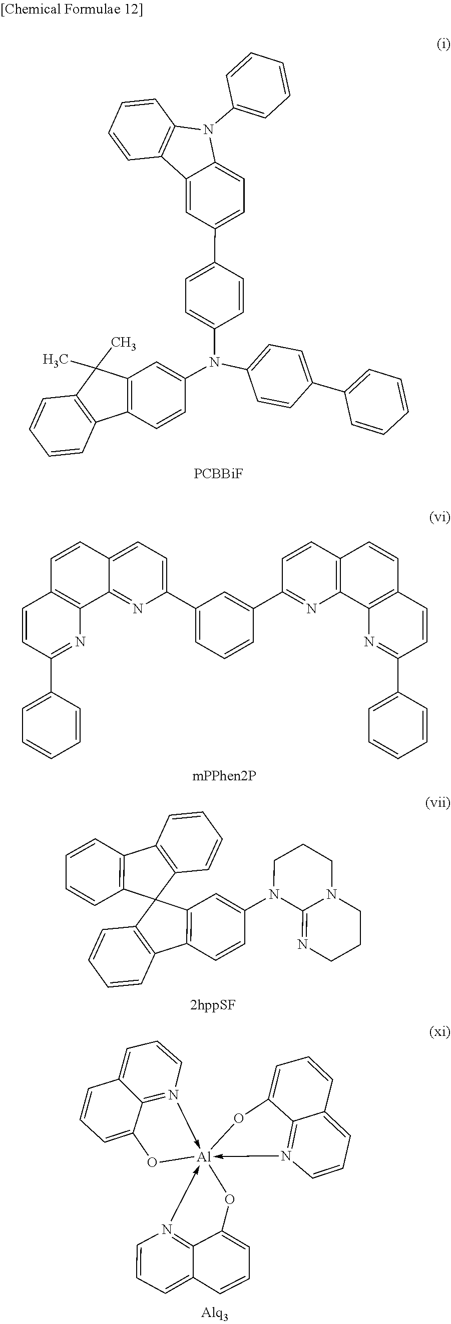

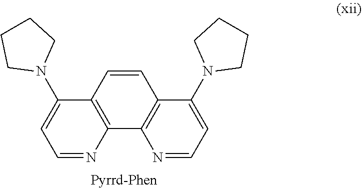 [SMILES: c1cc(N2CCCC2)c2ccc3c(N4CCCC4)ccnc3c2n1]

The measurement device was formed under the conditions where the substrate temperature was set to room temperature and the deposition rate was within the range from 0.2 nm/see to 0.4 nm/sec. One layer was formed without interruption of evaporation. In the measurement device, the electron-transport layer 1 corresponds to the thin film 1, the electron-transport layer 2 corresponds to the thin film 2, and the electron-transport layer 2 includes the same material as the first layer of the light-emitting device 1. FIG. 30 shows the capacity-voltage characteristics of the measurement device. Note that GSP_slope of Alq₃ is known (48 (mV/nm)).

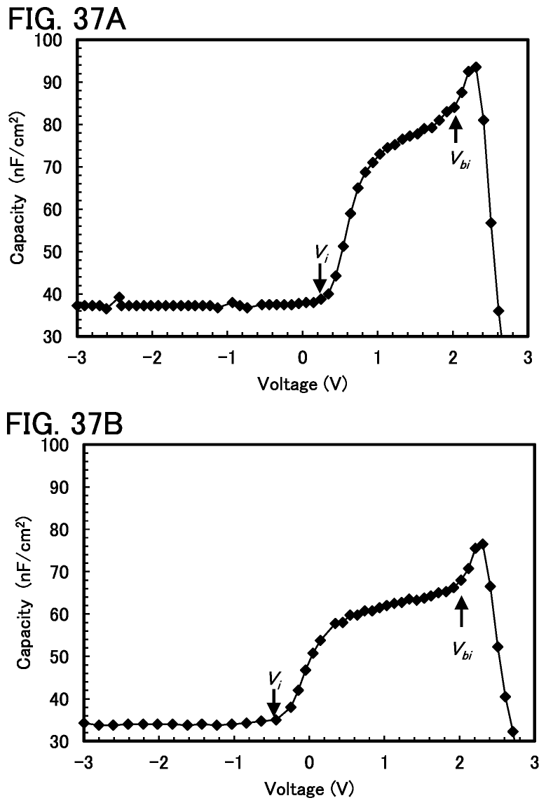

Table 11 shows the ordinary refractive index nₒ of the electron-transport layer 2, the electron-injection voltage Vᵢ and the threshold voltage V_{bi} of the measurement device obtained from FIGS. 37A and 37B, and the interface charge density σ_{if_e} and GSP_slope respectively obtained from Formula (1) and Formula (2) in Embodiment 1.

TABLE 11

| | |
|---|---|
| electron-injection voltage Vᵢ | −2.60 |
| (V) | |
| threshold voltage V_{bi} | 2.00 |
| (V) | |
| interface charge density σ_{if}_{_{—}}ₑ | −1.71 |
| (mC/m²) | |
| ordinary refractive index nₒ | 1.79 |
| (@633 nm) | |
| GSP_slope | −16.3 |
| (mV/nm) | |

As described above, the first layer used in the intermediate layer of the light-emitting device 2 was found to have negative GSP_slope. Thus, the light-emitting device 2 of one embodiment of the present invention was found to be able to have low driving voltage and favorable characteristics. Moreover, the light-emitting device having the structure of the present invention does not include Li in the first layer of the intermediate layer, and thus can be a light-emitting device having favorable characteristics in which an increase in driving voltage is suppressed even when fabricated through a photolithography process.

Next, the results of calculating GSP_slope of the second layer (the first electron-transport layer) of the light-emitting device 2 are described. Measurement devices each having a structure in the following table were fabricated and GSP_slope of each of their second layers (first electron-transport layers) was calculated. Note that the thicknesses of an anode, a hole-injection layer, the thin film 1, and a cathode in Table 12 are represented as design values. Meanwhile, the thicknesses of the thin films 2 in the following table are represented as values obtained using a spectroscopic ellipsometer (M-2000U, produced by J.A. Woollam Japan Corp.) because accurate values are required for measurement of GSP_slope.

TABLE 12

| | thickness | |
|---|---|---|
| | (nm) | material |
| cathode | 200 | Al |
| | 1 | LiF |
| thin film 2 | *1 | Alq₃ |
| thin film 1 | 80 | 2mPCCzPDBq |
| hole-injection layer | 10 | 2mPCCzPDBq:MoOx |
| | | (1:0.15) |
| anode | 70 | ITSO |

*1 measurement device L21: 54.63 nm
measurement device L22: 73.14 nm

The structural formulae of main organic compounds used in measurement devices L21 and L22 are shown below.

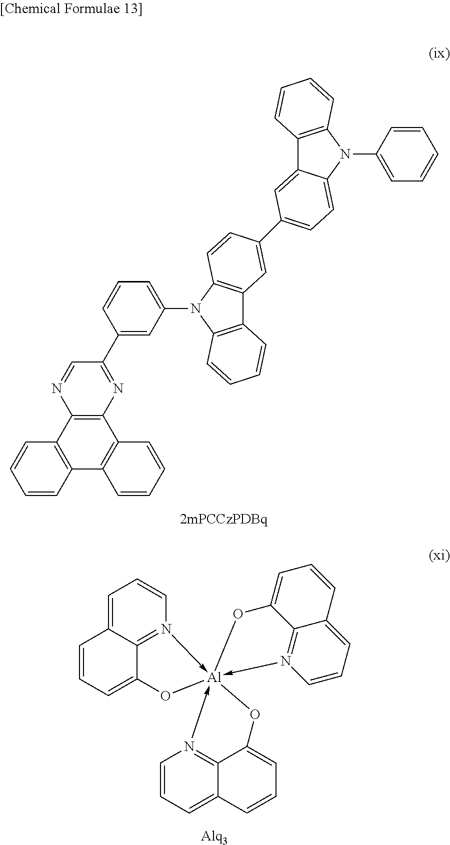

The measurement devices L21 and L22 were formed under the conditions where the substrate temperature was set to room temperature and the deposition rate was within the range from 0.2 nm/see to 0.4 nm/sec. One layer was formed without interruption of evaporation. In each of the measurement devices L21 and L22, the thin film 1 was formed using the same material as the second layer (the first electron-transport layer) of the light-emitting device 2, and the thin film 2 was formed using Alq₃. The measurement devices L21 and L22 each had a structure in which holes are accumulated as carriers in the thin film 2, and GSP_slope was obtained from Formulae (3) and (4) in Embodiment 1.

FIG. 37A and FIG. 37B show the capacity-voltage characteristics of the measurement device L21 and the measurement device L22, respectively. Note that GSP_slope of Alq₃ is known (48 (mV/nm)).

Table 13 shows the ordinary refractive index nₒ of the thin film 1, the electron-injection voltage Vᵢ and the threshold voltage V_{bi} of the measurement devices obtained from FIGS. 37A and 37B, and the interface charge density σ_{if_e} and GSP_slope respectively obtained from Formula (3) and Formula (4) in Embodiment 1.

TABLE 13

| | measurement | measurement |
|---|---|---|
| | device L21 | device L22 |
| electron-injection voltage Vᵢ | 0.25 | −0.44 |
| (V) | | |
| threshold voltage V_{bi} | 2.02 | 2.02 |
| (V) | | |
| interface charge density σ_{if}_{_{—}}ₑ | −0.84 | −0.87 |
| (mC/m²) | | |

| | |
|---|---|
| average | −0.86 |
| ordinary refractive index nₒ | 1.88 |

| | | |
|---|---|---|
| (@633 nm) | | |
| GSP_slope | 12.9 | 11.9 |
| (mV/nm) | | |

| | |
|---|---|
| average | 12.4 |

As described above, the second layer (the first electron-transport layer) of the light-emitting device 2 was found to have positive GSP_slope (12.4 mV/nm), that is, GSP_slope of the second layer (the first electron-transport layer) and GSP_slope of the first layer have opposite polarities. A difference between GSP_slope of the first layer and GSP_slope of the second layer was greater than or equal to 20 mV/nm.

Thus, the light-emitting device 2 of one embodiment of the present invention was found to be able to have low driving voltage and favorable characteristics. Moreover, the light-emitting device having the structure of the present invention does not include Li in the first layer of the intermediate layer, and thus can be a light-emitting device having favorable characteristics in which an increase in driving voltage is suppressed even when fabricated through a photolithography process.

Next, the results of calculating GSP_slope of the first light-emitting layer of the light-emitting device 2 are described. A measurement device 3 having a structure in the following table was fabricated and GSP_slope of its first light-emitting layer was calculated. Note that the thicknesses of a reflective electrode, an anode, a hole-injection layer, an electron-injection layer, a cathode, and a cap layer in Table 14 are represented as design values. Meanwhile, the thicknesses of the thin film 1 and the thin film 2 in the following table are represented as values obtained using a spectroscopic ellipsometer (M-2000U, produced by J.A. Woollam Japan Corp.).

TABLE 14

| | thickness | |
|---|---|---|
| | (nm) | material |
| cap layer | 70 | DBT3P-II |
| cathode | 15 | Ag:Mg (1:0.1) |
| electron- | 1 | Pyrrd-Phen |
| injection layer | | |
| thin film 2 | 51.57 | 8mpTP-4mDBtPBfpm:βNCCP:Ir(5mppy- |
| | | d₃)₂(mbfpypy-d₃) |
| | | (0.5:0.5:0.1) |
| thin film 1 | 84.80 | NPB |
| hole- | 10 | PCBBiF:OCHD-003 |
| injection layer | | (1:0.03) |
| anode | 85 | ITSO |
| reflective | 100 | Ag |
| electrode | | |

The structural formulae of main organic compounds used in the measurement device 3 are shown below.

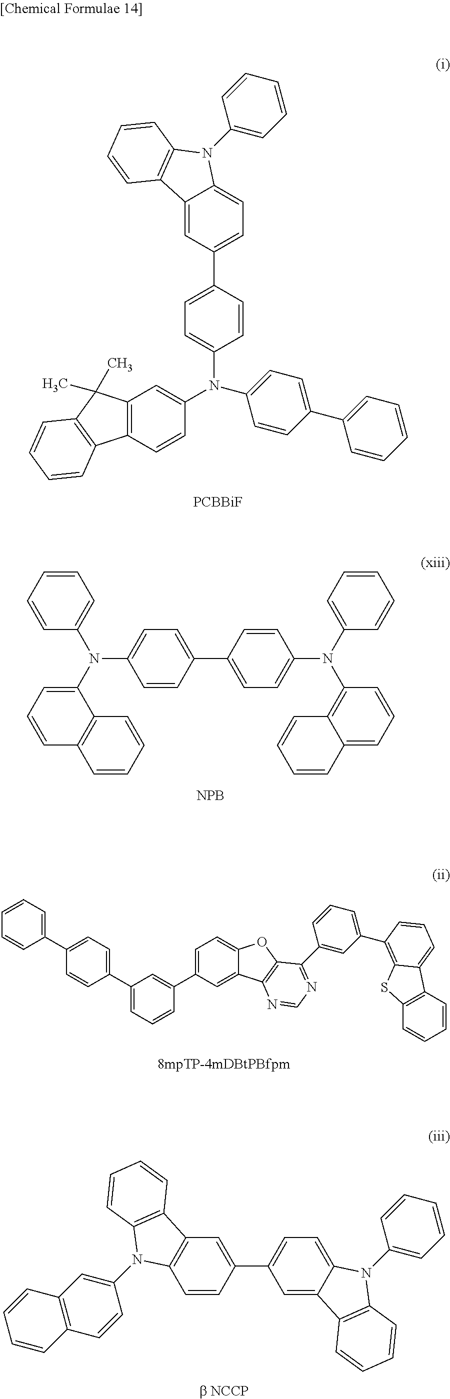

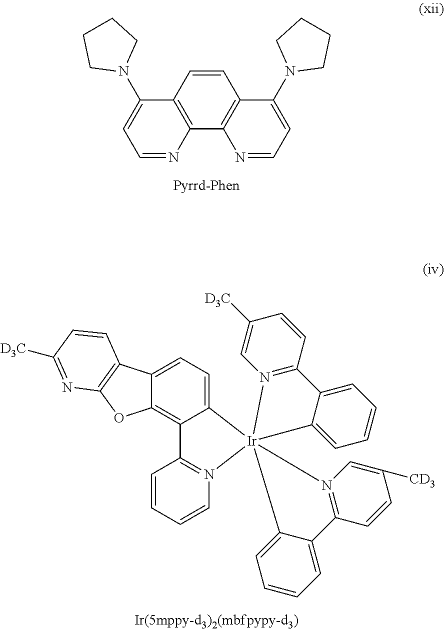

The measurement device 3 was formed under the conditions where the substrate temperature was set to room temperature and the deposition rate of films other than the thin film 2 was within the range from 0.2 nm/see to 0.4 nm/sec. The thin film 2 was deposited by co-evaporation using three evaporation sources, and the deposition rate of 8mpTP-4mDBtPBfpm, βNCCP, and Ir(5mppy-d₃)₂(mbfpypy-d₃) was 0.05 nm/see, 0.05 nm/see, and 0.01 nm/see, respectively. One layer was formed without interruption of evaporation.

In the measurement device 3, the thin film 2 was formed using the same material and the same deposition rate as the first light-emitting layer of the light-emitting device 2, and the thin film 1 was formed using 4,4′-bis[N-(1-naphthyl)-N-phenylamino]biphenyl (abbreviation: NPB). The measurement device had a structure in which holes are accumulated as carriers in the thin film 2, and GSP_slope was obtained from Formulae (3) and (4) in Embodiment 1.

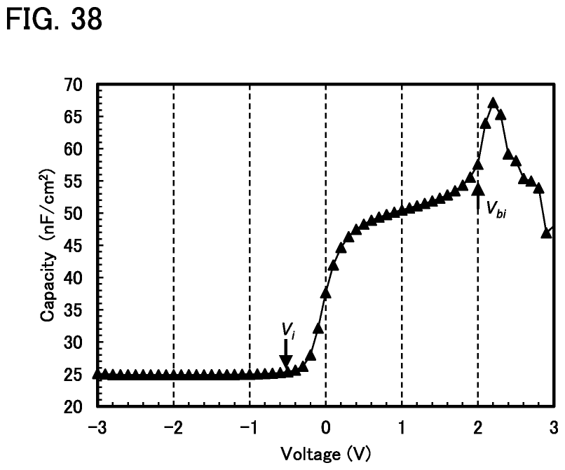

FIG. 38 shows the capacity-voltage characteristics of the measurement device 3. Note that GSP_slope of NPB is known (5.5 (mV/nm)).

Table 15 shows the ordinary refractive index n2ₒ of the thin film 2, the electron-injection voltage Vᵢ and the threshold voltage V_{bi} of the measurement device 3 obtained from FIG. 38, and the interface charge density σ_{if_e} and GSP_slope respectively obtained from Formula (3) and Formula (4) in Embodiment 1.

TABLE 15

| | |
|---|---|
| electron-injection voltage Vᵢ | −0.50 |
| (V) | |
| threshold voltage V_{bi} | 2.00 |
| (V) | |
| interface charge density σ_{if}_{_{—}}ₑ | −0.84 |
| (mC/m²) | |
| ordinary refractive index n2ₒ | 1.82 |
| (@633 nm) | |
| GSP_slope | 51.3 |
| (mV/nm) | |

As described above, the first light-emitting layer of the light-emitting device 2 was found to have positive GSP_slope (51.3 mV/nm), that is, GSP_slope of the second layer (the first electron-transport layer) and GSP_slope of the first layer have opposite polarities. A difference between GSP_slope of the first layer and GSP_slope of the first light-emitting layer was greater than or equal to 20 mV/nm.

Thus, the light-emitting device 2 of one embodiment of the present invention was found to be able to have low driving voltage and favorable characteristics. Moreover, the light-emitting device having the structure of the present invention does not include Li in the first layer of the intermediate layer, and thus can be a light-emitting device having favorable characteristics in which an increase in driving voltage is suppressed even when fabricated through a photolithography process.

This application is based on Japanese Patent Application Serial No. 2023-059114 filed with Japan Patent Office on Mar. 31, 2023, the entire contents of which are hereby incorporated by reference.

What is claimed is:

1. A light-emitting device comprising:
a first electrode;
a second electrode facing the first electrode;
a first light-emitting layer;
a second light-emitting layer; and
a first layer,
wherein the first light-emitting layer and the second light-emitting layer are between the first electrode and the second electrode,
wherein the first layer is between the first light-emitting layer and the second light-emitting layer,
wherein GSP_slope (mV/nm) of the first layer and GSP_slope (mV/nm) of the first light-emitting layer are denoted by signs of opposite polarities each other, and
wherein the GSP_slope (mV/nm) is a parameter represented by V/d when a surface potential and a thickness of a film are represented by V (mV) and d (nm), respectively.

2. The light-emitting device according to claim 1,
wherein the first layer is configured to block holes.

3. The light-emitting device according to claim 1,
wherein the first layer has a hole mobility lower than or equal to 1×10⁻⁸ cm²/Vs when a square root of electric field strength [V/cm] is 600.

4. The light-emitting device according to claim 1,
wherein the first layer comprises a first substance having any one of a pyrrolidine skeleton, a piperidine skeleton, and a hexahydropyrimidopyrimidine skeleton.

5. The light-emitting device according to claim 1,
wherein the first layer comprises a first substance and a second substance,
wherein the first substance is an organic compound having any one of a pyrrolidine skeleton, a piperidine skeleton, and a hexahydropyrimidopyrimidine skeleton, and
wherein the second substance is an electron-transport organic compound.

6. The light-emitting device according to claim 1,
wherein spin density of the first layer is lower than or equal to 1×10¹⁷ spins/cm³.

7. A light-emitting device comprising:
a first electrode over a substrate;
a second electrode facing the first electrode;
a first light-emitting layer;
a second light-emitting layer; and
a first layer,
wherein the first light-emitting layer and the second light-emitting layer are between the first electrode and the second electrode,
wherein the first layer is between the first light-emitting layer and the second light-emitting layer,
wherein the first layer has negative GSP_slope (mV/nm), and
wherein the GSP_slope (mV/nm) is a parameter represented by V/d when a surface potential and a thickness of a film are represented by V (mV) and d (nm), respectively.

8. The light-emitting device according to claim 7,
wherein the first layer is configured to block holes.

9. The light-emitting device according to claim 7,
wherein the first layer has a hole mobility lower than or equal to 1×10⁻⁸ cm²/Vs when a square root of electric field strength [V/cm] is 600.

10. The light-emitting device according to claim 7,
wherein the first layer comprises a first substance having any one of a pyrrolidine skeleton, a piperidine skeleton, and a hexahydropyrimidopyrimidine skeleton.

11. The light-emitting device according to claim 7,
wherein the first layer comprises a first substance and a second substance,
wherein the first substance is an organic compound having any one of a pyrrolidine skeleton, a piperidine skeleton, and a hexahydropyrimidopyrimidine skeleton, and
wherein the second substance is an electron-transport organic compound.

12. The light-emitting device according to claim 7,
wherein spin density of the first layer is lower than or equal to 1×10¹⁷ spins/cm³.

13. A light-emitting device comprising:
a first electrode;
a second electrode facing the first electrode;
a first light-emitting layer;
a second light-emitting layer;
an electron-transport layer; and
a first layer,
wherein the first light-emitting layer and the second light-emitting layer are between the first electrode and the second electrode,
wherein the electron-transport layer and the first layer are between the first light-emitting layer and the second light-emitting layer,
wherein GSP_slope (mV/nm) of the first layer and GSP_slope (mV/nm) of the electron-transport layer are denoted by signs of opposite polarities each other, and
wherein the GSP_slope (mV/nm) is a parameter represented by V/d when a surface potential and a thickness of a film are represented by V (mV) and d (nm), respectively.

14. The light-emitting device according to claim 13,
wherein the first layer is configured to block holes.

15. The light-emitting device according to claim 13,
wherein the first layer has a hole mobility lower than or equal to 1×10⁻⁸ cm²/Vs when a square root of electric field strength [V/cm] is 600.

16. The light-emitting device according to claim 13,
wherein the first layer comprises a first substance having any one of a pyrrolidine skeleton, a piperidine skeleton, and a hexahydropyrimidopyrimidine skeleton.

17. The light-emitting device according to claim 13,
wherein the first layer comprises a first substance and a second substance,
wherein the first substance is an organic compound having any one of a pyrrolidine skeleton, a piperidine skeleton, and a hexahydropyrimidopyrimidine skeleton, and
wherein the second substance is an electron-transport organic compound.

18. The light-emitting device according to claim 13,
wherein a difference between the GSP_slope (mV/nm) of the electron-transport layer and the GSP_slope (mV/nm) of the first layer is greater than or equal to 20 (mV/nm).

19. The light-emitting device according to claim 13,
wherein spin density of the first layer is lower than or equal to 1×10¹⁷ spins/cm³.
